(19) United States
(12) Patent Application Publication
(10) Pub. No.: US 2019/0354011 A1
(43) Pub. Date: Nov. 21, 2019

(54) RESIST COMPOSITION AND RESIST PATTERN FORMING METHOD

(71) Applicant: TOKYO OHKA KOGYO CO., LTD., Kawasaki-shi (JP)

(72) Inventors: Tomohiro OIKAWA, Kawasaki-shi (JP); Masafumi FUJISAKI, Kawasaki-shi (JP); Takashi NAGAMINE, Kawasaki-shi (JP); Daichi TAKAKI, Kawasaki-shi (JP)

(21) Appl. No.: 16/476,241

(22) PCT Filed: Jan. 12, 2018
(86) PCT No.: PCT/JP2018/000553

§ 371 Date: Jul. 5, 2019

(30) Foreign Application Priority Data
Jan. 16, 2017 (JP) 2017-005036

(51) Int. Cl. G03F 7/004; G03F 7/038; G03F 7/039

(52) U.S. Cl. CPC G03F 7/0045; G03F 7/162; G03F 7/0392; G03F 7/0382

(57) ABSTRACT

A resist composition which generates an acid upon exposure, and whose solubility in a developing solution is changed due to an action of the acid, the resist composition including a base material component whose solubility in the developing solution is changed due to the action of the acid, and an acid generator component which generates the acid upon exposure, in which the acid generator component contains two kinds of compounds.

### TECHNICAL FIELD

The present invention relates to a resist composition and a resist pattern forming method.

Priority is claimed on Japanese Patent Application No. 2017-005036, filed on Jan. 16, 2017, the content of which is incorporated herein by reference.

### BACKGROUND ART

In lithography technologies, for example, a resist film formed of a resist material is formed on a substrate, and the resist film is subjected to selective exposure to light or radiation such as electron beams through a mask on which a predetermined pattern has been formed and then subjected to a development treatment, thereby forming a resist pattern having a predetermined shape on the resist film.

A resist material in which the exposed portions become soluble in a developing solution is referred to as a positive type, and a resist material in which the exposed portions become insoluble in a developing solution is referred to as a negative type.

In recent years, in the production of semiconductor elements and liquid crystal display elements, advances in lithography technologies have led to rapid progress in pattern miniaturization.

Typically, these miniaturization techniques involve shortening the wavelength (increasing the energy) of the exposure light source. Specifically, ultraviolet rays typified by g-line and i-line have been used in the related art. In recent years, mass production of semiconductor elements using KrF excimer lasers and ArF excimer lasers has started. Furthermore, electron beams having a wavelength shorter (energy higher) than these excimer lasers, extreme ultraviolet radiation (EUV), and X-rays have been examined.

A chemically amplified resist composition contains an acid generator, and the solubility in a developing solution is changed due to an action of an acid generated from the acid generator. Since the behavior of an acid generated from an acid generator has a great impact on the lithography characteristics, various examinations have been performed on the acid generator. For example, PTLs 1 to 3 disclose a resist composition for which an acid generator obtained by using a compound having a predetermined structure is employed.

### CITATION LIST

### Patent Literature

[PTL 1] Japanese Unexamined Patent Application, First Publication No. 2014-209203

[PTL 2] Japanese Unexamined Patent Application, First Publication No. 2013-92618

[PTL 3] Japanese Unexamined Patent Application, First Publication No. 2012-83385

### SUMMARY OF INVENTION

### Technical Problem

With further progress in lithography technologies and expansion of the application fields, a resist composition has been required to have improved lithography characteristics.

However, for example, in each resist composition described in PTLs 1 to 3, there is room for improvement from the viewpoint of further improving lithography characteristics such as high sensitivity during formation of a resist pattern.

The present invention has been made in consideration of the above-described circumstances, and an object thereof is to provide a resist composition having excellent lithography characteristics, and a resist pattern forming method using the resist composition.

### Solution to Problem

The present inventors found that the lithography characteristics such as the sensitivity and the pattern dimension are improved by allowing an acid generator component contained in a resist composition to contain two specific compounds, thereby completing the present invention.

According to a first aspect of the present invention, a resist composition is provided which generates an acid upon exposure, and of which solubility in a developing solution is changed due to an action of the acid, the resist composition including: a base material component (A) of which solubility in the developing solution is changed due to the action of the acid; and an acid generator component (B) which generates the acid upon exposure, in which the acid generator component (B) contains a compound represented by Formula (b1) and a compound represented by Formula (b2).

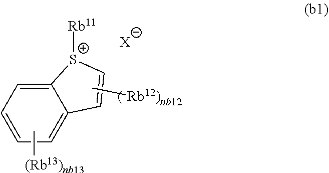

[In Formula (b1), Rb¹¹ represents an aryl group having a substituent, Rb¹² and Rb¹³ each independently represents an alkyl group having 1 to 10 carbon atoms which may have a substituent, an acetyl group, an alkoxy group having 1 to 10 carbon atoms, a carboxy group, or a hydroxyl group, nb12 represents an integer of 0 to 2, nb13 represents an integer of 0 to 4, and X⁻ represents a counter anion.]

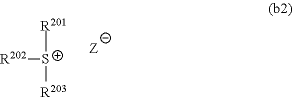

[In Formula (b2), R²⁰¹ to R²⁰³ each independently represents an aryl group which may have a substituent, and Z⁻ represents a counter anion.]

According to a second aspect of the present invention, a resist pattern-forming method is provided, including: a step of forming a resist film on a support using the resist composition according to the first aspect of the present invention; a step of exposing the resist film; and a step of developing the exposed resist film to form a resist pattern.

### Advantageous Effects of Invention

According to the present invention, it is possible to provide a resist composition having excellent lithography characteristics, and a resist pattern-forming method using the resist composition.

### DESCRIPTION OF EMBODIMENTS

In the present specification and claims, the term “aliphatic” is a relative concept used in relation to the term “aromatic”, and defines a group or compound that does not have aromaticity.

The term “alkyl group” includes linear, branched or cyclic, monovalent saturated hydrocarbon, unless otherwise specified.

The term “alkylene group” includes linear, branched or cyclic, divalent saturated hydrocarbon, unless otherwise specified. The same applies to the alkyl group in an alkoxy group.

A “halogenated alkyl group” is a group in which some or all hydrogen atoms of an alkyl group have been substituted with halogen atoms. Examples of the halogen atom include a fluorine atom, a chlorine atom, a bromine atom and an iodine atom.

A “fluorinated alkyl group” or a “fluorinated alkylene group” is a group in which some or all hydrogen atoms of an alkyl group or an alkylene group have been substituted with fluorine atoms.

The term “constitutional unit” indicates a monomer unit that contributes to the formation of a polymeric compound (a resin, a polymer, or a copolymer).

A “constitutional unit derived from acrylic acid ester” indicates a constitutional unit that is formed by the cleavage of the ethylenic double bond of acrylic acid ester.

The “acrylic acid ester” indicates a compound in which the terminal hydrogen atom of the carboxy group of acrylic acid (CH₂═CH—COOH) has been substituted with an organic group.

The acrylic acid ester may have the hydrogen atom bonded to the carbon atom at the α-position substituted with a substituent. The substituent (R^{α}) that substitutes the hydrogen atom bonded to the carbon atom at the α-position is an atom other than hydrogen or a group, and examples thereof include an alkyl group having 1 to 5 carbon atoms, a halogenated alkyl group having 1 to 5 carbon atoms, and a hydroxyalkyl group. A carbon atom at the α-position of acrylic acid ester indicates the carbon atom bonded to the carbonyl group, unless otherwise specified.

Hereinafter, acrylic acid ester in which the hydrogen atom bonded to the carbon atom at the α-position is substituted with a substituent is also referred to as α-substituted acrylic acid ester”. Further, acrylic acid ester and α-substituted acrylic acid ester are also collectively referred to as “(α-substituted) acrylic acid ester”.

A “constitutional unit derived from a hydroxystyrene derivative” indicates a constitutional unit that is formed by the cleavage of an ethylenic double bond of hydroxystyrene or a hydroxystyrene derivative.

The term “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxyl group has been substituted with an organic group and may have the hydrogen atom at the α-position substituted with a substituent; and hydroxystyrene which has a substituent other than a hydroxyl group bonded to the benzene ring and may have the hydrogen atom at the α-position substituted with a substituent. Here, the α-position (carbon atom at the α-position) indicates the carbon atom having the benzene ring bonded thereto, unless otherwise specified.

As the substituent which substitutes the hydrogen atom at the α-position of hydroxystyrene, the same substituents as those described above for the substituent at the α-position of the above-described α-substituted acrylic acid ester can be exemplified.

A “constitutional unit derived from vinylbenzoic acid or a vinylbenzoic acid derivative” indicates a constitutional unit that is formed by the cleavage of the ethylenic double bond of vinylbenzoic acid or a vinylbenzoic acid derivative.

The term “vinylbenzoic acid derivative” includes compounds in which the hydrogen atom at the α-position of vinylbenzoic acid has been substituted with another substituent such as an alkyl group or a halogenated alkyl group; and derivatives thereof. Examples of the derivatives thereof include vinylbenzoic acid in which the hydrogen atom of the carboxy group has been substituted with an organic group and may have the hydrogen atom at the α-position substituted with a substituent; and vinylbenzoic acid which has a substituent other than a hydroxyl group and a carboxy group bonded to the benzene ring and may have the hydrogen atom at the α-position substituted with a substituent. Here, the α-position (carbon atom at the α-position) indicates the carbon atom having the benzene ring bonded thereto, unless otherwise specified.

The term “styrene derivative” is a concept including those obtained by substitution of a hydrogen atom at the α-position of styrene with other substituents such as an alkyl group and a halogenated alkyl group.

The term “constitutional unit derived from styrene” or “constitutional unit derived from a styrene derivative” indicates a constitutional unit formed by cleavage of an ethylenic double bond of styrene or a styrene derivative.

As the alkyl group as a substituent at the α-position, a linear or branched alkyl group is preferable, and specific examples include alkyl groups of 1 to 5 carbon atoms, such as a methyl group, an ethyl group, a propyl group, an isopropyl group, an n-butyl group, an isobutyl group, a tert-butyl group, a pentyl group, an isopentyl group, and a neopentyl group.

Specific examples of the halogenated alkyl group as the substituent at the α-position include groups in which some or all hydrogen atoms of the above-described “alkyl group as the substituent at the α-position” are substituted with halogen atoms. Examples of the halogen atom include a fluorine atom, a chlorine atom, a bromine atom and an iodine atom, and a fluorine atom is particularly preferable.

Specific examples of the hydroxyalkyl group as the substituent at the α-position include groups in which some or all hydrogen atoms of the above-described “alkyl group as the substituent at the α-position” are substituted with a hydroxyl group. The number of hydroxyl groups in the hydroxyalkyl group is preferably 1 to 5, and most preferably 1.

The expression “may have a substituent” means that a case where a hydrogen atom (—H) is substituted with a monovalent group, or a case where a methylene (—CH₂—) group is substituted with a divalent group.

The term “exposure” is used as a general concept that includes irradiation with any form of radiation.

In the present specification and the scope of the present patent claims, asymmetric carbons may be present or enantiomers or diastereomers may be present depending on the structures of the chemical formulae. In this case, these isomers are represented by one formula. These isomers may be used alone or in the form of a mixture.

<Resist Composition>

The resist composition according to the present embodiment is a resist composition which generates an acid upon exposure and of which solubility in a developing solution is changed due to an action of the acid. The resist composition contains a base material component (A) of which solubility in a developing solution is changed due to the action of an acid, and an acid generator component (B) which generates an acid upon exposure.

Hereinafter, the resist composition for forming a resist pattern will be described.

The resist composition according to the present invention is a resist composition which generates an acid upon exposure and of which solubility in a developing solution is changed due to an action of the acid.

In the present invention, the resist composition contains a base material component (A) in which the solubility in a developing solution is changed due to an action of the acid (hereinafter, also referred to as “component (A)”) and an acid generator component (B) which generates an acid upon exposure.

In a case where a resist film is formed using such a resist composition and the formed resist film is subjected to a selective exposure, an acid is generated at exposed portions, and the acid acts on the component (A) to change the solubility of the component (A) in a developing solution, whereas the solubility of the component (A) in a developing solution is not changed at unexposed portions, thereby generating a difference in solubility in a developing solution between exposed portions and unexposed portions. Therefore, by performing development on the resist film, the exposed portions are dissolved and removed to form a positive type resist pattern in a case where the resist composition is of a positive type, whereas the unexposed portions are dissolved and removed to form a negative type resist pattern in a case where the resist composition is of a negative type.

In the present specification, a resist composition which forms a positive type resist pattern by dissolving and removing the exposed portions is called a positive type resist composition, and a resist composition which forms a negative type resist pattern by dissolving and removing the unexposed portions is called a negative type resist composition.

In the present invention, the resist composition may be a positive type resist composition or a negative type resist composition.

Further, the resist composition of the present invention can be applied to an alkali development process using an alkali developing solution in the development treatment at the time of formation of a resist pattern, or a solvent development process using a developing solution containing an organic solvent (organic developing solution) in the development treatment, but it is preferable that the resist composition be used for the solvent development process.

<<Component (A)>>

In the present invention, the term “base material component” indicates an organic compound capable of forming a film, and is preferably an organic compound having a molecular weight of 500 or greater. In a case where the organic compound has a molecular weight of 500 or greater, the film-forming ability is improved, and a photosensitive resin pattern at a nano level can be easily formed.

The organic compound used as the base material component is broadly classified into non-polymers and polymers.

In general, as a non-polymer, any of those which have a molecular weight in the range of 500 to less than 4,000 is used. Hereinafter, a “low molecular weight compound” indicates a non-polymer having a molecular weight in the range of 500 to less than 4,000.

As a polymer, any of those which have a molecular weight of 1,000 or greater is typically used. Hereinafter, a “resin” indicates a polymer having a molecular weight of 1,000 or greater.

As the molecular weight of the polymer, the weight-average molecular weight in terms of the polystyrene equivalent value determined by gel permeation chromatography (GPC) is used.

As the component (A), a resin or a low-molecular weight compound may be used or a combination of these may be used.

The component (A) may be a component of which solubility in a developing solution is increased due to the action of an acid.

Further, the component (A) in the present invention may generate an acid upon exposure.

In the present invention, it is preferable that the component (A) contain a polymer compound (A1) which has a constitutional unit (hereinafter, also referred to as a “constitutional unit (a1))” containing an acid-decomposable group of which polarity is increased due to an action of an acid and a constitutional unit (hereinafter, also referred to as a “constitutional unit (a2)”) containing a —SO₂-containing cyclic group, a lactone-containing cyclic group, a carbonate-containing cyclic group, or a heterocyclic group other than these.

(Constitutional Unit (a1))

The constitutional unit (a1) is a constitutional unit containing an acid-decomposable group of which polarity is increased due to the action of an acid.

The term “acid-decomposable group” indicates a group in which at least a part of a bond in the structure of the acid-decomposable group can be cleaved due to the action of an acid.

Examples of the acid-decomposable group of which polarity is increased due to the action of an acid include groups which are decomposed due to the action of an acid to form a polar group.

Examples of the polar group include a carboxy group, a hydroxyl group, an amino group, and a sulfo group (—SO₃H). Among these, a polar group containing —OH in the structure thereof (hereinafter, also referred to as an “OH-containing polar group”) is preferable, a carboxy group or a hydroxyl group is more preferable, and a carboxy group is particularly preferable.

More specific examples of the acid-decomposable group include a group in which the above-described polar group has been protected with an acid-dissociable group (such as a group in which a hydrogen atom of the OH-containing polar group has been protected with an acid-dissociable group).

Here, the “acid-dissociable group” indicates both (i) group in which a bond between the acid-dissociable group and an atom adjacent to the acid-dissociable group can be cleaved due to the action of an acid; and (ii) group in which some bonds are cleaved due to the action of an acid, and then a decarboxylation reaction occurs, thereby cleaving the bond between the acid-dissociable group and the atom adjacent to the acid-dissociable group.

It is necessary that the acid-dissociable group that constitutes the acid-decomposable group be a group which exhibits a lower polarity than the polar group generated by the dissociation of the acid-dissociable group. Thus, in a case where the acid-dissociable group is dissociated by the action of an acid, a polar group exhibiting a higher polarity than that of the acid-dissociable group is generated, thereby increasing the polarity. As a result, the polarity of the entire component (A1) is increased. By the increase in the polarity, relatively, the solubility in a developing solution changes, and the solubility is decreased in a case where the developing solution is an organic developing solution.

The acid-dissociable group is not particularly limited, and any of those which have been suggested as acid-dissociable groups of the base resin for a chemically amplified resist composition can be used.

Among the above-described polar groups, examples of the acid-dissociable group for protecting a carboxy group or a hydroxyl group include the acid-dissociable group represented by Formula (a1-r-1) shown below (hereinafter, also referred to as “acetal type acid-dissociable group”).

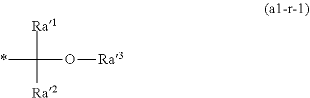

[In the formula, Ra′¹ and Ra′² represent a hydrogen atom or an alkyl group, Ra′³ represents a hydrocarbon group, and Ra′³ may be bonded to any of Ra′¹ and Ra′² to form a ring. The symbol “*” represents a bonding site.]

In Formula (a1-r-1), examples of the alkyl group as Ra′¹ and Ra′² include the same alkyl groups exemplified as the substituent which may be bonded to the carbon atom at the α-position in the description on α-substituted acrylic acid ester. Among these, a methyl group or an ethyl group is preferable, and a methyl group is particularly preferable.

As the hydrocarbon group as Ra′³, an alkyl group having 1 to 20 carbon atoms is preferable, an alkyl group having 1 to 10 carbon atoms is more preferable, and a linear or branched alkyl group is still more preferable. Specific examples thereof include a methyl group, an ethyl group, a propyl group, an isopropyl group, an n-butyl group, an isobutyl group, a tert-butyl group, a pentyl group, an isopentyl group, a neopentyl group, a 1,1-dimethylethyl group, a 1,1-diethylpropyl group, a 2,2-dimethylpropyl group, and a 2,2-dimethylbutyl group.

In a case where Ra′³ represents a cyclic hydrocarbon group, the cyclic hydrocarbon group may be an aliphatic hydrocarbon group or an aromatic hydrocarbon group, and may be polycyclic or monocyclic. As the monocyclic alicyclic hydrocarbon group, a group in which one hydrogen atom has been removed from a monocycloalkane is preferable. The monocycloalkane preferably has 3 to 8 carbon atoms, and specific examples thereof include cyclopentane, cyclohexane, and cyclooctane. As the polycyclic alicyclic hydrocarbon group, a group in which one hydrogen atom has been removed from a polycycloalkane is preferable. As the polycycloalkane, a group having 7 to 12 carbon atoms is preferable. Specific examples thereof include adamantane, norbomane, isobomane, tricyclodecane, and tetracyclododecane.

In a case where the cyclic hydrocarbon group becomes an aromatic hydrocarbon group, specific examples of the aromatic ring to be contained include aromatic hydrocarbon rings such as benzene, biphenyl, fluorene, naphthalene, anthracene, and phenanthrene; and aromatic hetero rings in which some carbon atoms constituting the above-described aromatic hydrocarbon rings have been substituted with heteroatoms. Examples of the heteroatom in the aromatic hetero rings include an oxygen atom, a sulfur atom, and a nitrogen atom.

Specific examples of the aromatic hydrocarbon group include a group in which one hydrogen atom has been removed from the above-described aromatic hydrocarbon ring (an aryl group); and a group in which one hydrogen atom of the aryl group has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group (the alkyl chain in an arylalkyl group) preferably has 1 to 4 carbon atoms, more preferably 1 or 2 carbon atoms, and particularly preferably 1 carbon atom.

In a case where Ra′³ is bonded to Ra′¹ or Ra′² to form a ring, the cyclic group is preferably a 4- to 7-membered ring, and more preferably a 4- to 6-membered ring. Specific examples of the cyclic group include a tetrahydropyranyl group and a tetrahydrofuranyl group.

Examples of the acid-dissociable group for protecting the carboxy group as a polar group include the acid-dissociable group represented by Formula (a1-r-2) shown below (among the acid-dissociable groups represented by Formula (a1-r-2), for convenience, a group which is constituted of alkyl groups is referred to as “tertiary alkyl ester type acid-dissociable group”).

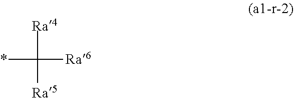

[In Formula (a1-r-2), Ra′⁴ to Ra′⁶ represent a hydrocarbon group, and Ra′⁵ and Ra′⁶ may be bonded to each other to form a ring. The symbol “*” represents a bonding site.]

Examples of the hydrocarbon groups as Ra′⁴ to Ra′⁶ include those represented by Ra′³ described above. It is preferable that Ra′⁴ represent an alkyl group having 1 to 5 carbon atoms. In a case where Ra′⁵ and Ra′⁶ are bonded to each other to form a ring, a group represented by Formula (a1-r2-1) shown below can be exemplified.

Further, in a case where Ra′⁴ to Ra′⁶ are not bonded to each other and independently represent a hydrocarbon group, a group represented by Formula (a1-r2-2) shown below can be exemplified.

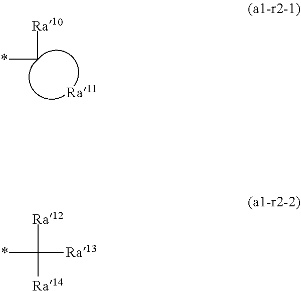

[In Formula (a1-r2-1) or (a1-r2-2), Ra′¹⁰ represents an alkyl group having 1 to 10 carbon atoms, Ra′¹¹ represents a group that forms an aliphatic cyclic group together with a carbon atom to which Ra′¹⁰ is bonded, and Ra′¹² to Ra′¹⁴ each independently represents a hydrocarbon group. The symbol “*” represents a bonding site.]

In Formula (a1-r2-1), as the alkyl group having 1 to 10 carbon atoms as Ra′¹⁰, the groups exemplified as the linear or branched alkyl group represented by Ra′³ in Formula (a1-r-1) are preferable. In Formula (a1-r2-1), as the aliphatic cyclic group that is formed by Ra′¹¹, the groups exemplified as the cyclic alkyl group represented by Ra′³ in Formula (a1-r-1) are preferable.

In Formula (a1-r2-2), it is preferable that Ra′¹² and Ra′¹⁴ each independently represents an alkyl group having 1 to 10 carbon atoms, and it is more preferable that the alkyl group be the same group as the described above for the linear or branched alkyl group as Ra′³ in Formula (a1-r-1), it is still more preferable that the alkyl group be a linear alkyl group having 1 to 5 carbon atoms, and it is particularly preferable that the alkyl group be a methyl group or an ethyl group.

In Formula (a1-r2-2), it is preferable that Ra′¹³ represent the linear, branched, or cyclic alkyl group exemplified as the hydrocarbon group represented by Ra′³ in Formula (a1-r-1). Among these examples, a group exemplified as the cyclic alkyl group represented by Ra′³ is more preferable.

Specific examples of the group represented by Formula (a1-r2-1) are shown below. In the formulae, the symbol “*” represents a bonding site.

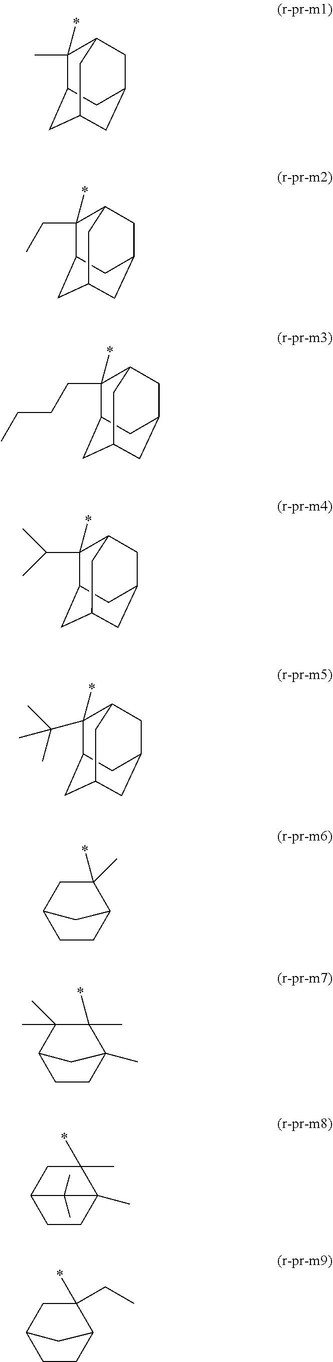

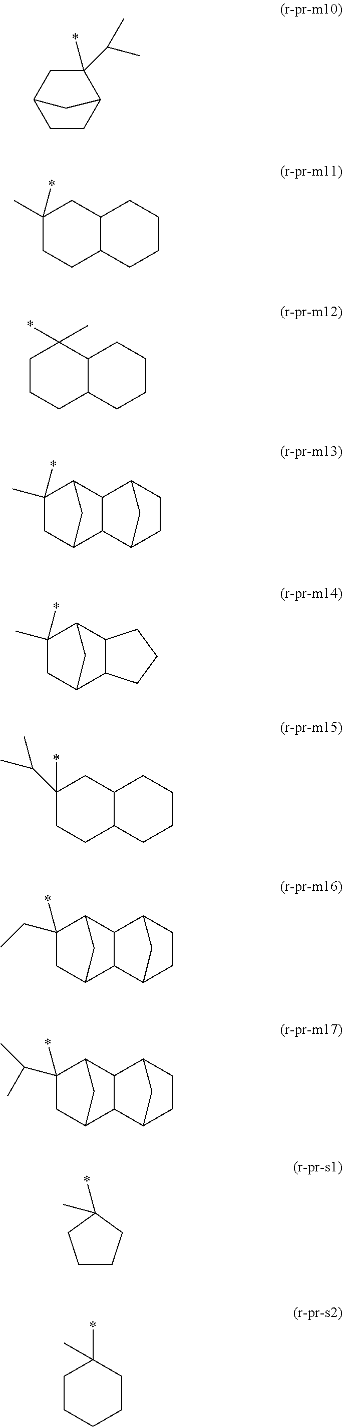

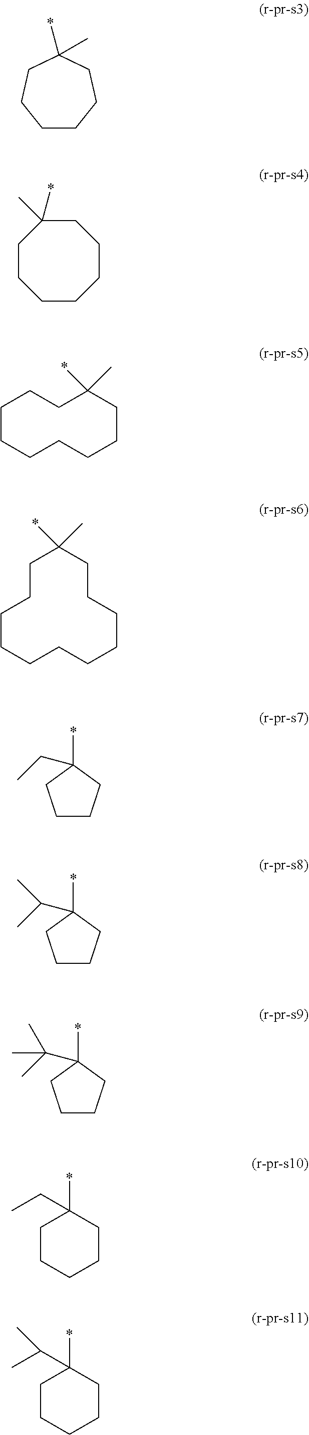

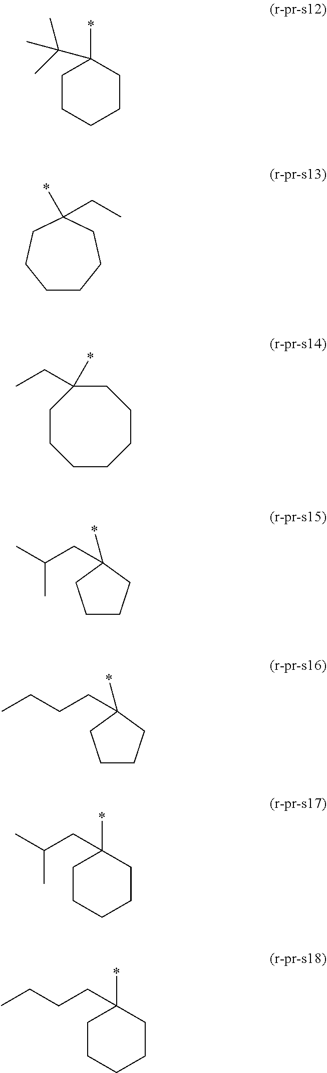

Specific examples of the group represented by Formula (a1-r2-2) are shown below.

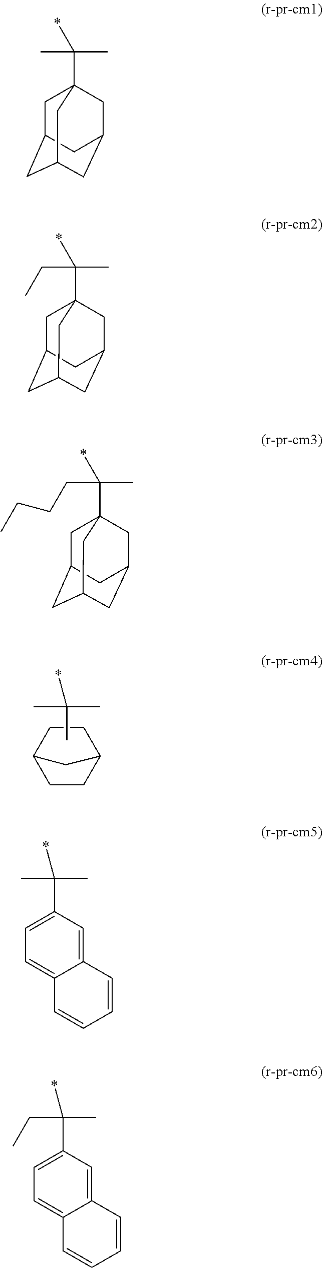

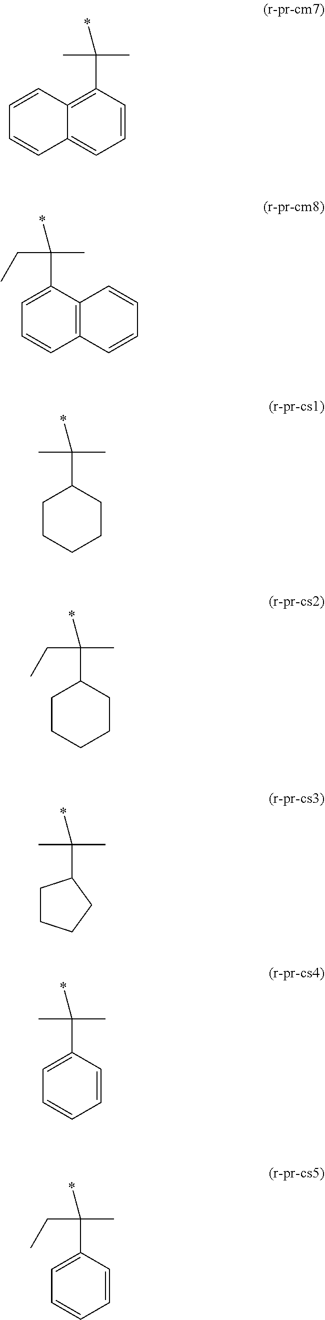

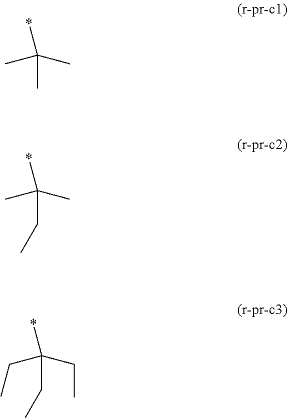

Examples of the acid-dissociable group for protecting a hydroxyl group among the above-described polar groups include an acid-dissociable group (hereinafter, for convenience, also referred to as “tertiary alkyloxycarbonyl acid-dissociable group”) represented by Formula (a1-r-3) shown below.

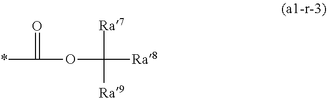

[In Formula (a1-r-3), Ra′⁷ to Ra′⁹ each independently represents an alkyl group. The symbol “*” represents a bonding site.]

In Formula (a1-r-3), Ra′⁷ to Ra′⁹ each independently represents preferably an alkyl group having 1 to 5 carbon atoms and more preferably an alkyl group having 1 to 3 carbon atoms.

Further, the total number of carbon atoms in each alkyl group is preferably in a range of 3 to 7, more preferably in a range of 3 to 5, and most preferably 3 or 4.

Examples of the constitutional unit (a1) include a constitutional unit derived from acrylic acid ester in which the hydrogen atom bonded to the carbon atom at the α-position may be substituted with a substituent; a constitutional unit which contains an acid-dissociable group of which polarity is increased due to the action of an acid; a constitutional unit in which at least some hydrogen atoms in a hydroxyl group of a constitutional unit derived from hydroxystyrene or a hydroxystyrene derivative are protected by a substituent containing the acid-decomposable group; and a constitutional unit in which some hydrogen atoms in —C(═O)—OH of a constitutional unit derived from vinylbenzoic acid or a vinylbenzoic acid derivative are protected by a substituent containing the acid-decomposable group.

Among the examples, as the constitutional unit (a1), a constitutional unit derived from acrylic acid ester in which the hydrogen atom bonded to the carbon atom at the α-position may be substituted with a substituent is preferable.

As the constitutional unit (a1), a constitutional unit represented by Formula (a1-1) or (a1-2) is preferable.

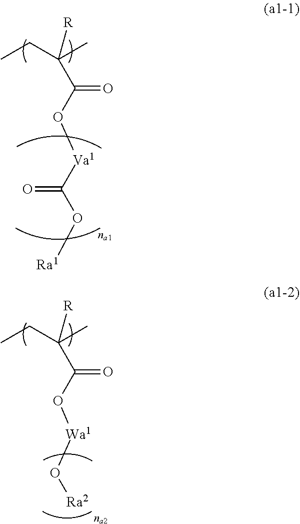

[In Formula (a1-1) or (a1-2), R represents a hydrogen atom, an alkyl group having 1 to 5 carbon atoms, or a halogenated alkyl group having 1 to 5 carbon atoms, Va¹ represents a divalent hydrocarbon group which may contain an ether bond, a urethane bond, or an amide bond, nₐ₁ represents an integer of 0 to 2, and Ra¹ represents an acid-dissociable group represented by Formula (a1-r-1) or (a1-r-2). Wa¹ represents a (nₐ₂+1)-valent hydrocarbon group, nₐ₂ represents an integer of 1 to 3, and Ra² represents an acid-dissociable group represented by Formula (a1-r-1) or (a1-r-3)].

In Formula (a1-1), as the alkyl group having 1 to 5 carbon atoms, a linear or branched alkyl group having 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which some or all hydrogen atoms of the above-described alkyl group having 1 to 5 carbon atoms have been substituted with halogen atoms. Examples of the halogen atom include a fluorine atom, a chlorine atom, a bromine atom, and an iodine atom, and a fluorine atom is particularly preferable.

As R, a hydrogen atom, an alkyl group having 1 to 5 carbon atoms, or a fluorinated alkyl group having 1 to 5 carbon atoms is preferable, a hydrogen atom or a methyl group is more preferable, and a methyl group is particularly preferable in terms of industrial availability.

The hydrocarbon group as Va¹ may be an aliphatic hydrocarbon group or an aromatic hydrocarbon group. The aliphatic hydrocarbon group indicates a hydrocarbon group that does not have aromaticity. The aliphatic hydrocarbon group as the divalent hydrocarbon group represented by Va¹ may be saturated or unsaturated. However, typically, it is preferable that the aliphatic hydrocarbon group be saturated.

More specific examples of the aliphatic hydrocarbon group include a linear or branched aliphatic hydrocarbon group and an aliphatic hydrocarbon group having a ring in the structure thereof.

Further, as Va¹, those in which the above-described divalent hydrocarbon groups are bonded through an ether bond, a urethane bond, or an amide bond are exemplified.

The linear or branched aliphatic hydrocarbon group preferably has 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

As the branched aliphatic hydrocarbon group, a branched alkylene group is preferred, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group in the alkylalkylene group, a linear alkyl group having 1 to 5 carbon atoms is preferable.

Examples of the aliphatic hydrocarbon group having a ring in the structure thereof include an alicyclic hydrocarbon group (a group in which two hydrogen atoms have been removed from an aliphatic hydrocarbon ring), a group in which the alicyclic hydrocarbon group is bonded to the terminal of the linear or branched aliphatic hydrocarbon group, and a group in which the alicyclic hydrocarbon group is interposed in the above-described linear or branched aliphatic hydrocarbon group. As the linear or branched aliphatic hydrocarbon group, the same groups as described above are exemplified.

The alicyclic hydrocarbon group preferably has 3 to 20 carbon atoms and more preferably 3 to 12 carbon atoms.

The alicyclic hydrocarbon group may be monocyclic or polycyclic. As the monocyclic alicyclic hydrocarbon group, a group in which two hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which two hydrogen atoms have been removed from a polycycloalkane is preferable. As the polycycloalkane, a group having 7 to 12 carbon atoms is preferable. Specific examples of the polycycloalkane include adamantane, norbornane, isobomane, tricyclodecane, and tetracyclododecane.

The aromatic hydrocarbon group is a hydrocarbon group having an aromatic ring.

The aromatic hydrocarbon group as the divalent hydrocarbon group represented by Va¹ preferably has 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring contained in the aromatic hydrocarbon group include aromatic hydrocarbon rings such as benzene, biphenyl, fluorene, naphthalene, anthracene, and phenanthrene; and aromatic hetero rings in which some carbon atoms constituting the above-described aromatic hydrocarbon rings have been substituted with heteroatoms. Examples of the heteroatom in the aromatic hetero rings include an oxygen atom, a sulfur atom, and a nitrogen atom.

Specific examples of the aromatic hydrocarbon group include a group in which two hydrogen atoms have been removed from the above-described aromatic hydrocarbon ring (an arylene group); and a group in which one hydrogen atom of a group (an aryl group) formed by removing one hydrogen atom from the aromatic hydrocarbon ring has been substituted with an alkylene group (a group formed by removing one more hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group (an alkyl chain in the arylalkyl group) preferably has 1 to 4 carbon atoms, more preferably 1 or 2 carbon atoms, and particularly preferably 1 carbon atom.

In Formula (a1-2), the (nₐ₂+1)-valent hydrocarbon group as Wa¹ may be an aliphatic hydrocarbon group or an aromatic hydrocarbon group. The aliphatic hydrocarbon group indicates a hydrocarbon group that does not have aromaticity, and may be saturated or unsaturated, but is preferably saturated. Examples of the aliphatic hydrocarbon group include a linear or branched aliphatic hydrocarbon group, an aliphatic hydrocarbon group having a ring in the structure thereof, and a combination of the linear or branched aliphatic hydrocarbon group and the aliphatic hydrocarbon group having a ring in the structure thereof, and specific examples thereof include the same groups represented by Va¹ in Formula (a1-1) as described above.

The valency of nₐ₂+1 is preferably divalent, trivalent or tetravalent, and divalent or trivalent is more preferable.

As the constitutional unit represented by Formula (a1-2), a constitutional unit represented by Formula (a1-2-01) is particularly preferable.

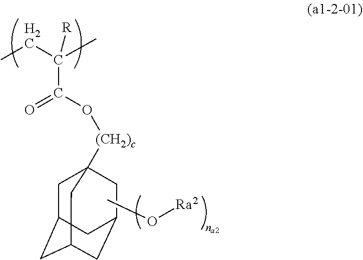

In Formula (a1-2-01), Ra² represents an acid-dissociable group represented by Formula (a1-r-1) or (a1-r-3). na² represents an integer of 1 to 3, preferably 1 or 2, and more preferably 1. c represents an integer of 0 to 3, preferably 0 or 1, and more preferably 1. R has the same definition as described above.

Specific examples of the constitutional unit represented by Formula (a1-1) or (a1-2) are shown below. In the formulae shown below, Ra represents a hydrogen atom, a methyl group, or a trifluoromethyl group.

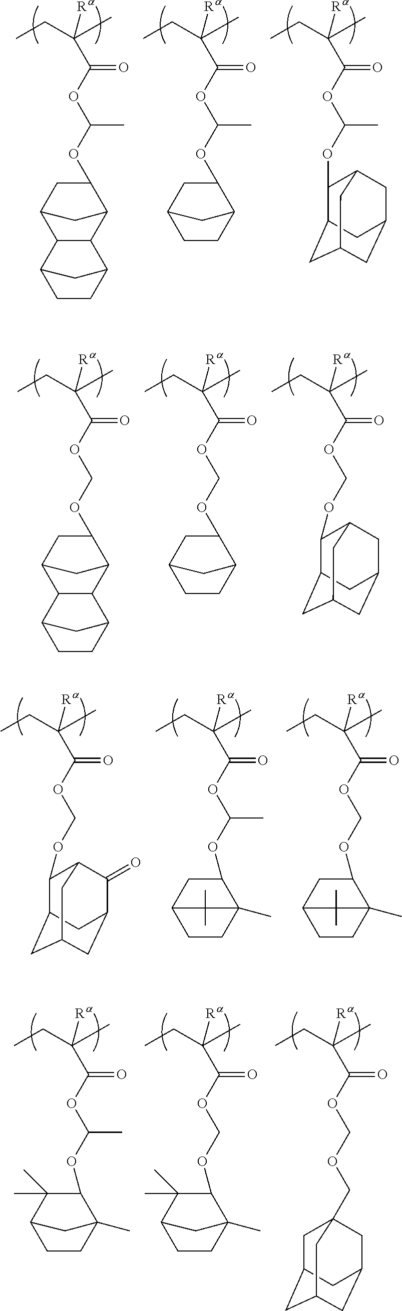

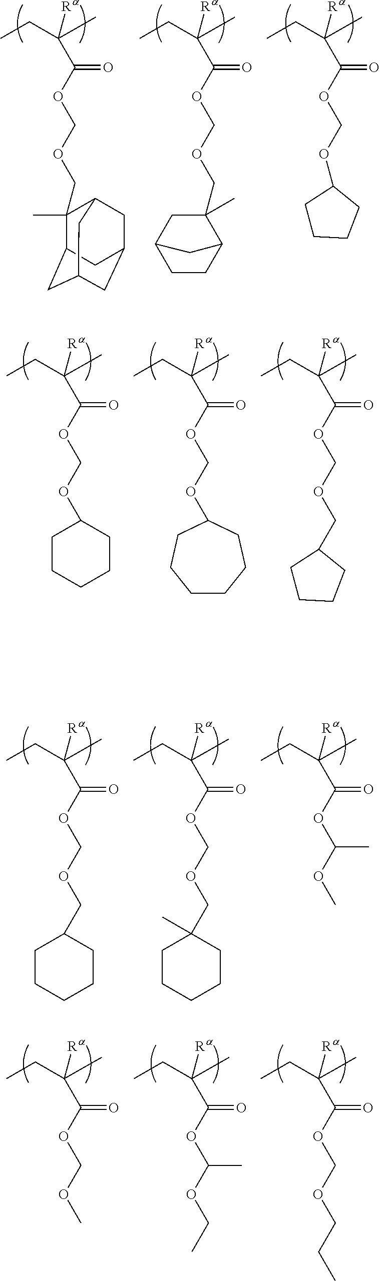

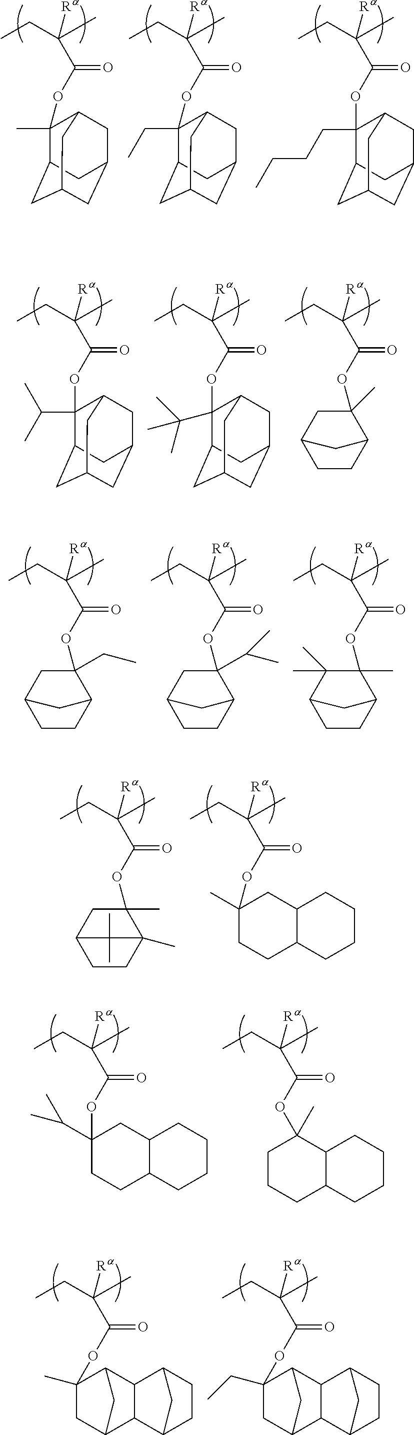

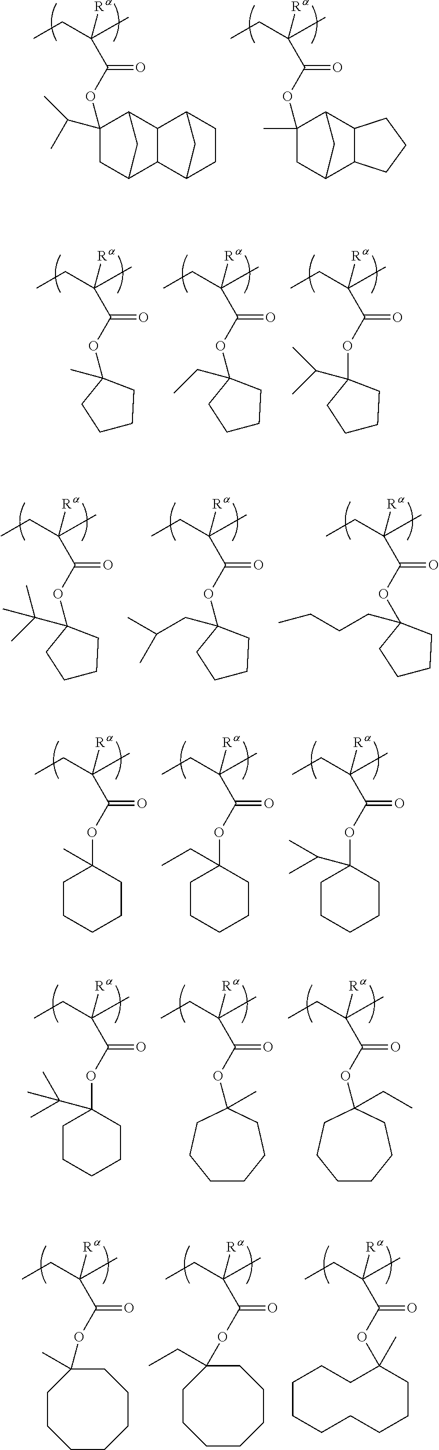

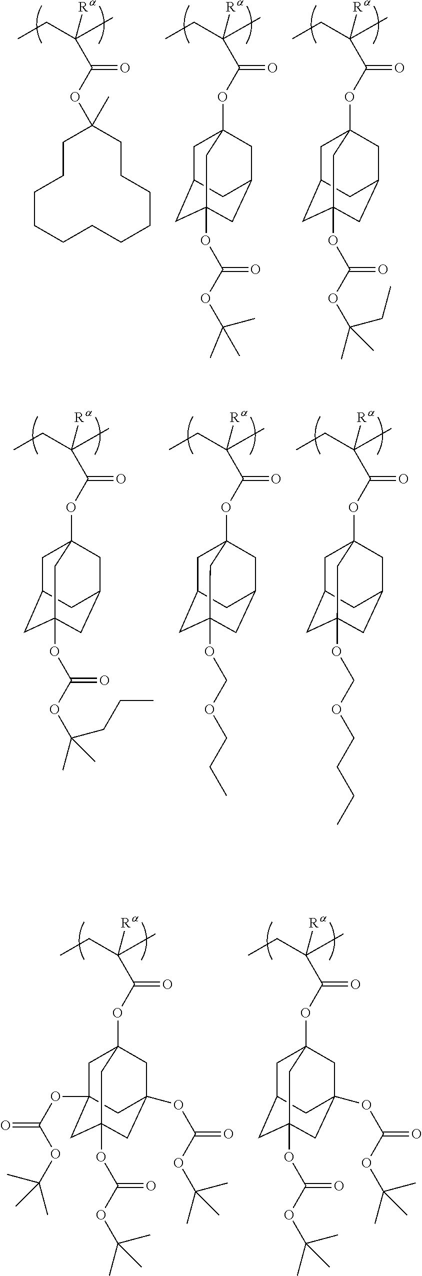

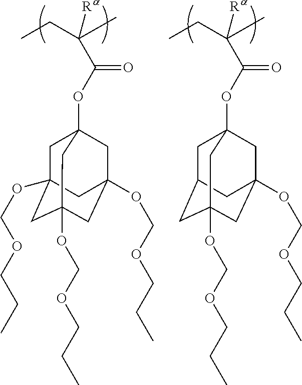

The proportion of the constitutional unit (a1) in the component (A) is preferably in a range of 20% to 80% by mole, more preferably in a range of 20% to 75% by mole, and still more preferably in a range of 25% to 70% by mole with respect to the total amount of all constitutional units constituting the component (A). By setting the proportion of the constitutional unit (a1) to be greater than or equal to the above-described lower limit, lithography characteristics such as the sensitivity, the resolution, and LWR, and the like are improved. Further, by setting the proportion of the constitutional unit (a1) to be lower than or equal to the above-described upper limit, the constitutional unit (a1) and other constitutional units can be balanced.

(Constitutional Unit (a2))

The constitutional unit (a2) is a constitutional unit containing a —SO₂-containing cyclic group, a lactone-containing cyclic group, or a carbonate-containing cyclic group.

In a case where the component (A) is used for forming a resist film, the —SO₂-containing cyclic group, the lactone-containing cyclic group, or the carbonate-containing cyclic group in the constitutional unit (a2) is effective for improving the adhesiveness of the resist film to the substrate.

Further, in a case where the constitutional unit (a1) contains a —SO₂-containing cyclic group, a lactone-containing cyclic group, or a carbonate-containing cyclic group in the structure thereof, the constitutional unit corresponds to the constitutional unit (a2), but such a constitutional unit corresponds to the constitutional unit (a1) and does not correspond to the constitutional unit (a2).

The “—SO₂-containing cyclic group” indicates a cyclic group having a ring containing —SO₂— in the ring structure thereof. Specifically, the —SO₂-containing cyclic group is a cyclic group in which the sulfur atom (S) in —SO₂— forms a part of the ring skeleton of the cyclic group. In a case where the ring containing —SO₂— in the ring skeleton thereof is counted as the first ring and the group contains only the ring, the group is referred to as a monocyclic group. Further, in a case where the group has other ring structures, the group is referred to as a polycyclic group regardless of the structures. The —SO₂-containing cyclic group may be a monocyclic group or a polycyclic group.

As the —SO₂-containing cyclic group, a cyclic group containing —O—SO₂— in the ring skeleton thereof, in other words, a cyclic group containing a sultone ring in which —O—S— in —O—SO₂— forms a part of the ring skeleton thereof is particularly preferable. More specific examples of the —SO₂-containing cyclic group include groups represented by Formulae (a5-r-1) to (a5-r-4) shown below.

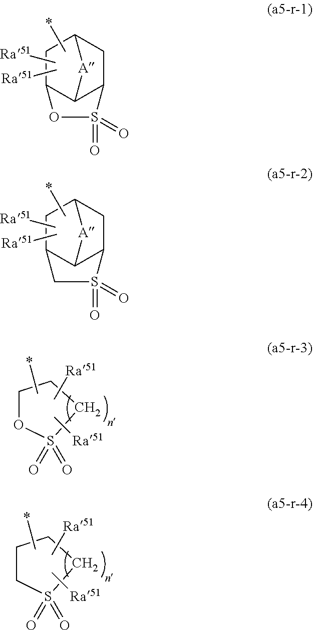

[In the formulae, each Ra′⁵¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group. R″ represents a hydrogen atom or an alkyl group. A″ represents an alkylene group having 1 to 5 carbon atoms which may contain an oxygen atom or a sulfur atom, an oxygen atom, or a sulfur atom. n′ represents an integer of 0 to 2.]

In Formulae (a5-r-1) to (a5-r-4), A″ has the same definition as that for A″ in Formulae (a2-r-1) to (a2-r-7). Examples of the alkyl group, the alkoxy group, the halogen atom, the halogenated alkyl group, —COOR″, —OC(═O)R″, and the hydroxyalkyl group as Ra′⁵¹ include the same groups as those described above in the section of Ra′²¹ in Formulae (a2-r-1) to (a2-r-7).

Specific examples of the groups represented by Formulae (a5-r-1) to (a5-r-4) are shown below. In the formulae shown below, “Ac” represents an acetyl group.

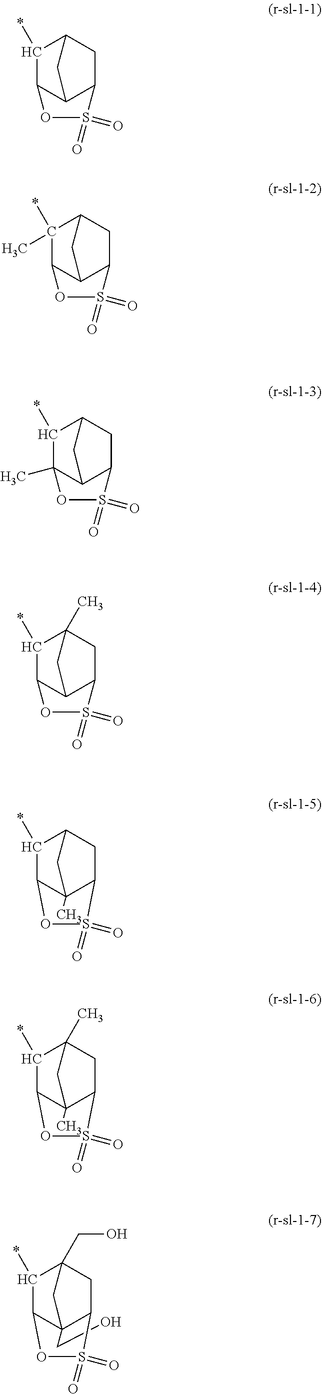

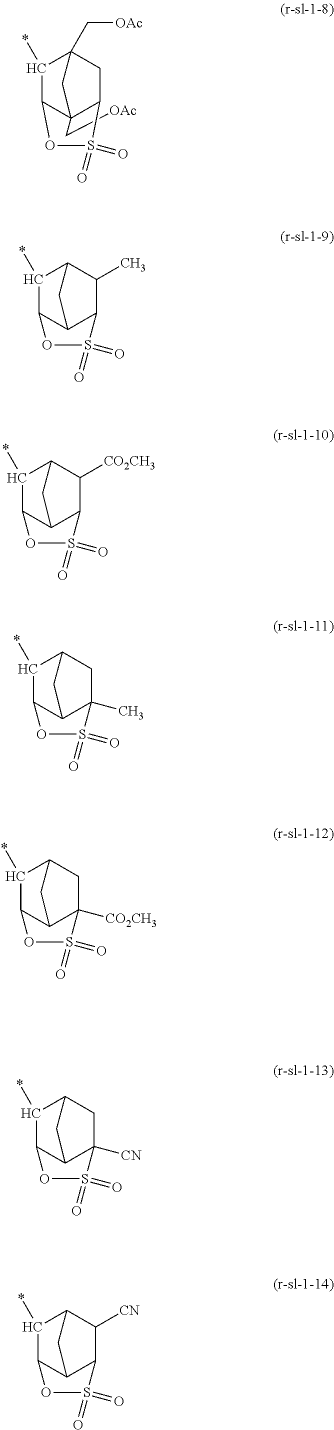

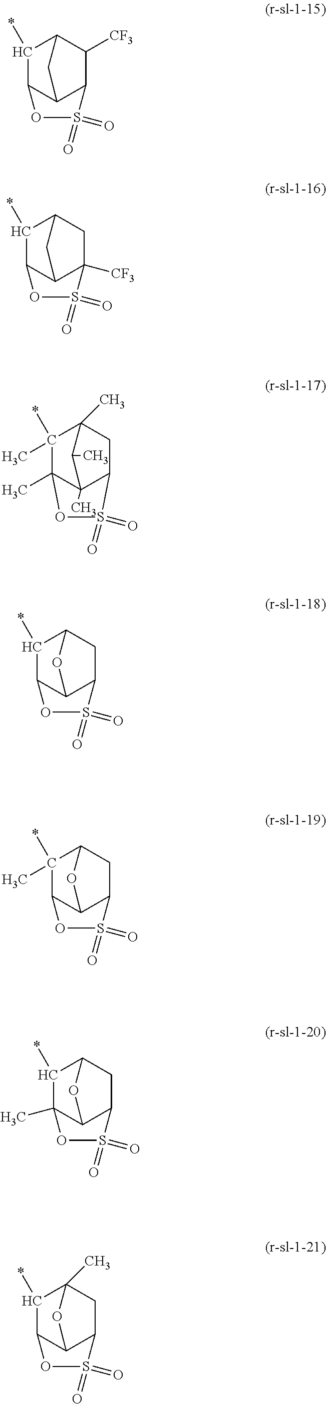

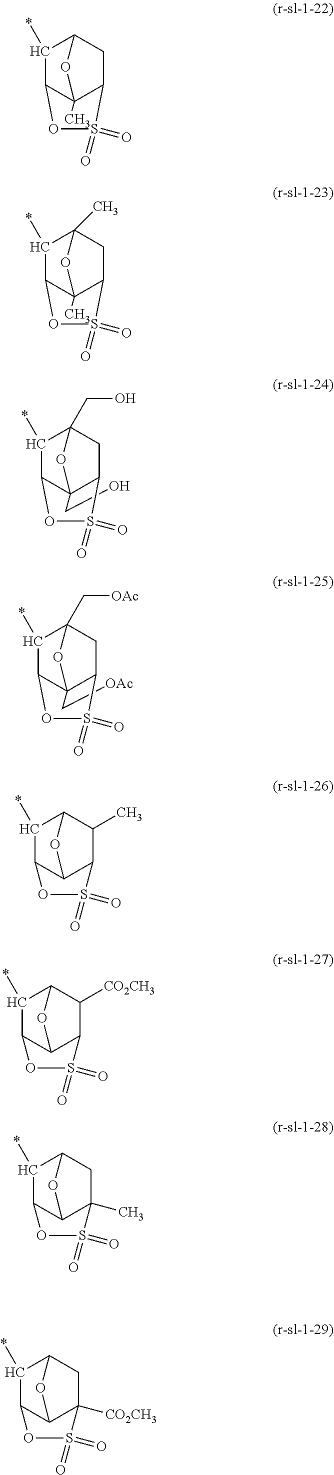

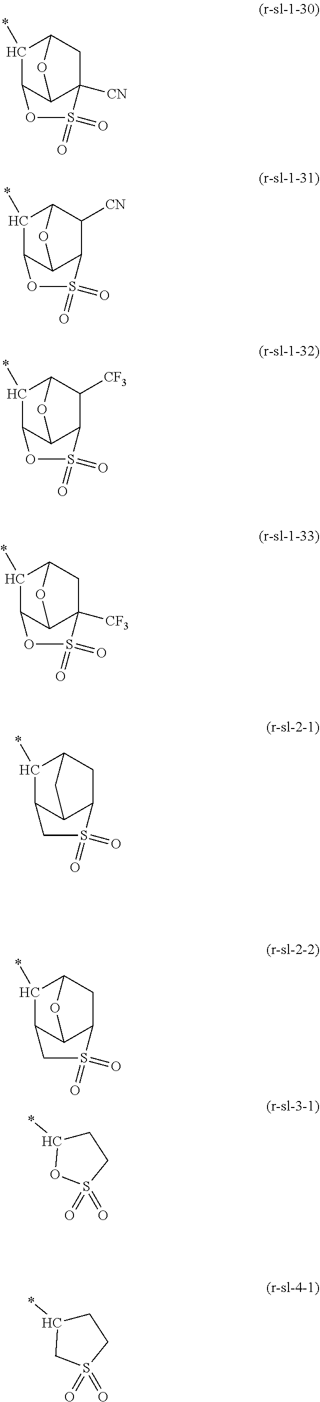

In the present embodiment, in a case where the constitutional unit (a2) contains a —SO₂-containing cyclic group, among the examples, a group represented by Formula (a5-r-1) is preferable, at least one selected from the group consisting of groups represented by Chemical formulae (r-s1-1-1), (r-s1-1-18), (r-s1-3-1), and (r-s1-4-1) is more preferable, and a group represented by Chemical Formula (r-s1-1-1) is most preferable.

The term “lactone-containing cyclic group” indicates a cyclic group that contains a ring (lactone ring) containing a —O—C(═O)— in the ring skeleton. In a case where the lactone ring is counted as the first ring and the group contains only the lactone ring, the group is referred to as a monocyclic group. Further, in a case where the group has other ring structures, the group is referred to as a polycyclic group regardless of the structures. The lactone-containing cyclic group may be a monocyclic group or a polycyclic group.

The lactone-containing cyclic group is not particularly limited, and an optional constitutional unit may be used.

Specific examples thereof include groups represented by Formulae (a2-r-1) to (a2-r-7) shown below. Hereinafter, the symbol “*” represents a bonding site.

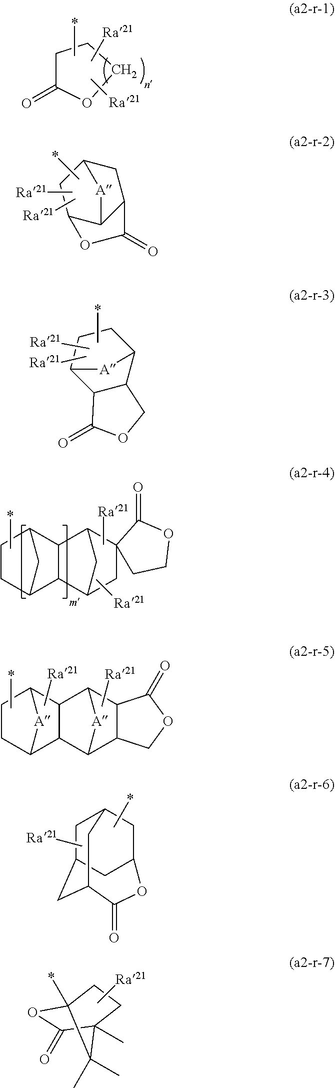

[In the formulae, each Ra′²¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group; and R″ represents a hydrogen atom or an alkyl group; A″ represents an oxygen atom, a sulfur atom or an alkylene group having 1 to 5 carbon atoms which may contain an oxygen atom or a sulfur atom; n′ represents an integer of 0 to 2; and m′ represents 0 or 1.]

In Formulae (a2-r-1) to (a2-r-7), A″ represents an alkylene group having 1 to 5 carbon atoms which may have an oxygen atom (—O—) or a sulfur atom (—S—), an oxygen atom, or a sulfur atom. As the alkylene group having 1 to 5 carbon atoms as A″, a linear or branched alkylene group is preferable, and examples thereof include a methylene group, an ethylene group, an n-propylene group, and an isopropylene group. In a case where the alkylene group has an oxygen atom or a sulfur atom, specific examples thereof include a group in which —O— or —S— is interposed in the terminal or between the carbon atoms of the alkylene group, and examples thereof include —O—CH₂—, —CH₂—O—CH₂—, —S—CH₂—, and —CH₂—S—CH₂—. As A″, an alkylene group having 1 to 5 carbon atoms or —O— is preferable, an alkylene group having 1 to 5 carbon atoms is more preferable, and a methylene group is most preferable. Each Ra′²¹ independently represents an alkyl group, an alkoxy group, a halogen atom, a halogenated alkyl group, —COOR″, —OC(═O)R″, a hydroxyalkyl group, or a cyano group.

The alkyl group as Ra′²¹ is preferably an alkyl group having 1 to 5 carbon atoms.

The alkoxy group as Ra′²¹ is preferably an alkoxy group having 1 to 6 carbon atoms.

Further, the alkoxy group is preferably a linear or branched alkoxy group. Specific examples of the alkoxy group include a group formed by linking an alkyl group exemplified as the alkyl group represented by Ra′²¹ to an oxygen atom (—O—).

Examples of the halogen atom as Ra′²¹ include a fluorine atom, a chlorine atom, a bromine atom, and an iodine atom. Among these, a fluorine atom is preferable.

Examples of the halogenated alkyl group as Ra′²¹ include groups in which some or all hydrogen atoms in the above-described alkyl group as Ra′²¹ have been substituted with the above-described halogen atoms. As the halogenated alkyl group, a fluorinated alkyl group is preferable, and a perfluoroalkyl group is particularly preferable.

R″ represents a hydrogen atom or an alkyl group, and an alkyl group having 1 to 5 carbon atoms is preferable as the alkyl group represented by R″.

Specific examples of the groups represented by Formulae (a2-r-1) to (a2-r-7) are shown below.

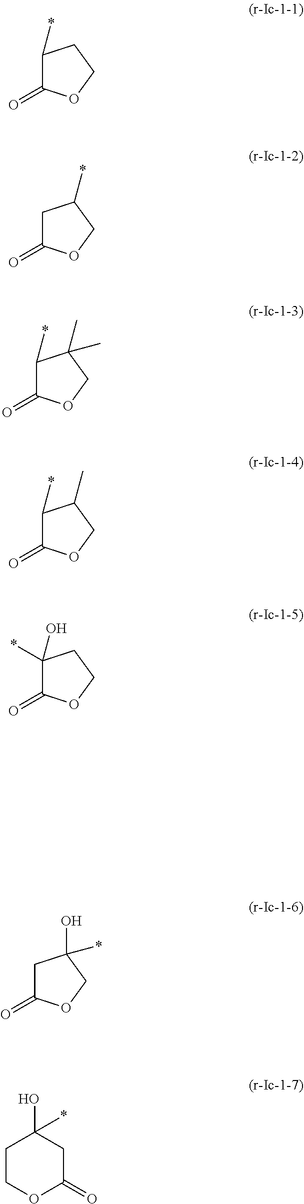

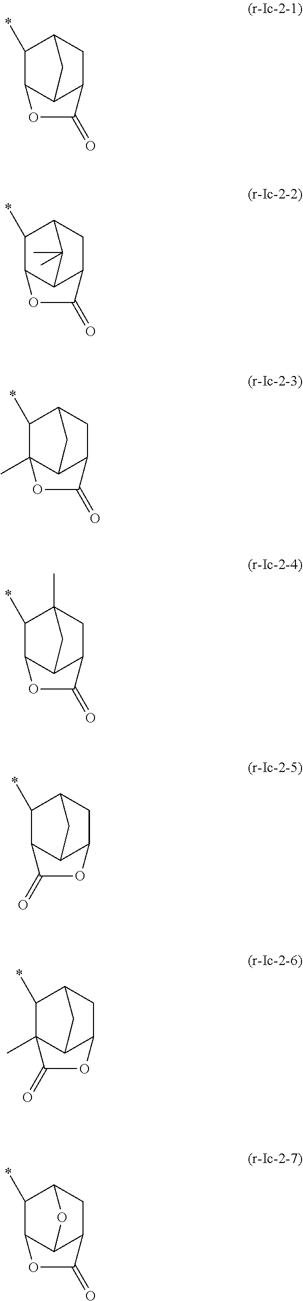

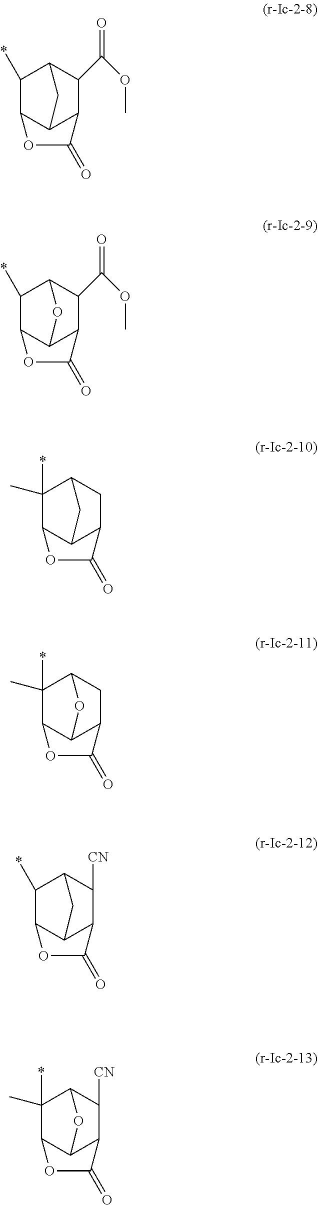

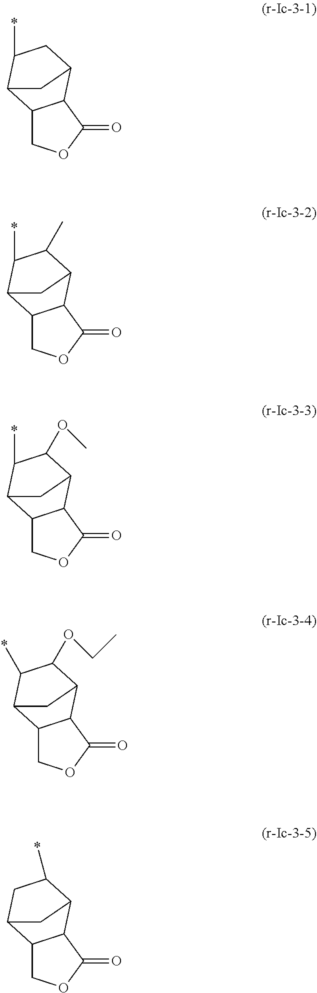 [SMILES: *C1CC2CC1C1COC(=O)C21 ; *C1C(C)C2CC1C1COC(=O)C21 ; *C1C2CC(C1OC)C1C(=O)OCC21 ; *C1C2CC(C1OCC)C1C(=O)OCC21 ; *C1CC2CC1C1C(=O)OCC21]

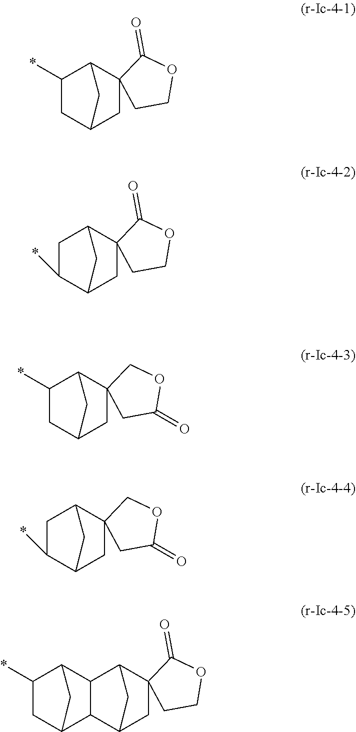 [SMILES: *C1CC2CC1C1(CCOC1=O)C2 ; *C1CC2CC1CC21CCOC1=O ; *C1CC2CC1C1(COC(=O)C1)C2 ; *C1CC2CC1CC21COC(=O)C1 ; *C1CC2CC1C1C2C2CC1C1(CCOC1=O)C2]

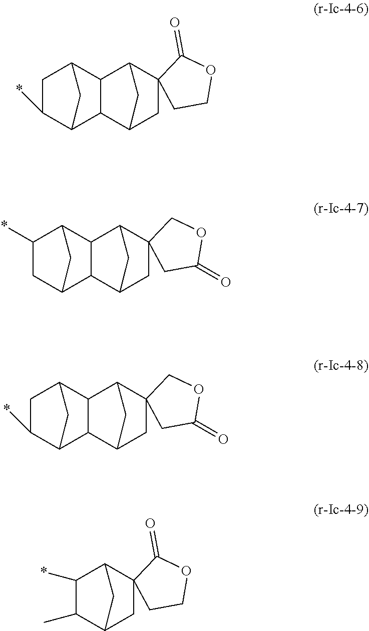 [SMILES: *C1CC2CC1C1C3CC(C21)C1(CCOC1=O)C3 ; *C1CC2CC1C1C2C2CC1C1(COC(=O)C1)C2 ; *C1CC2CC1C1C3CC(C21)C1(COC(=O)C1)C3 ; *C1C(C)C2CC1C1(CCOC1=O)C2]

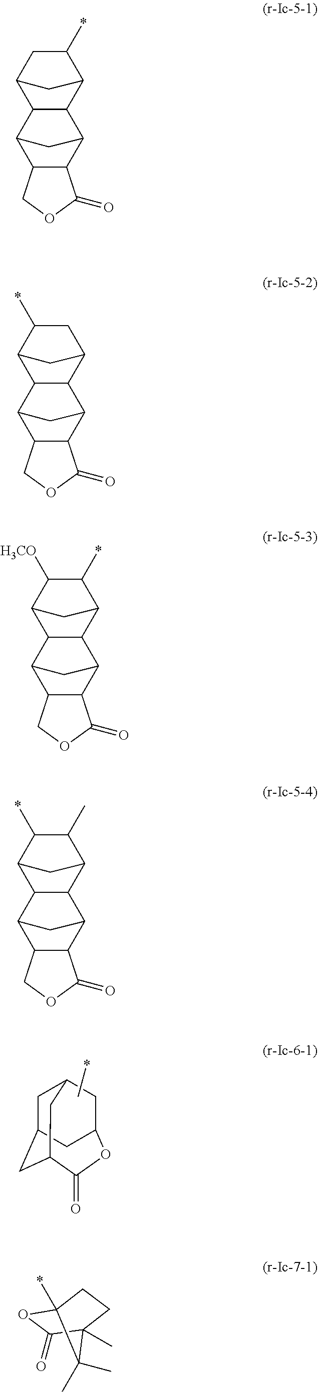

In the present embodiment, as the constitutional unit (a2), a group represented by Formula (a2-r-1) or (a2-r-2) is preferable, and a group represented by any of Chemical Formulae (r-lc-1-1) to (r-lc-2-7) is more preferable.

The “carbonate-containing cyclic group” indicates a cyclic group having a ring (a carbonate ring) containing —O—C(═O)—O—in the ring skeleton thereof. In a case where the carbonate ring is counted as the first ring and the group contains only the carbonate ring, the group is referred to as a monocyclic group. Further, in a case where the group has other ring structures, the group is referred to as a polycyclic group regardless of the structures. The carbonate-containing cyclic group may be a monocyclic group or a polycyclic group.

The carbonate ring-containing cyclic group is not particularly limited, and an optional group may be used. Specific examples thereof include groups represented by Formulae (ax3-r-1) to (ax3-r-3) shown below.

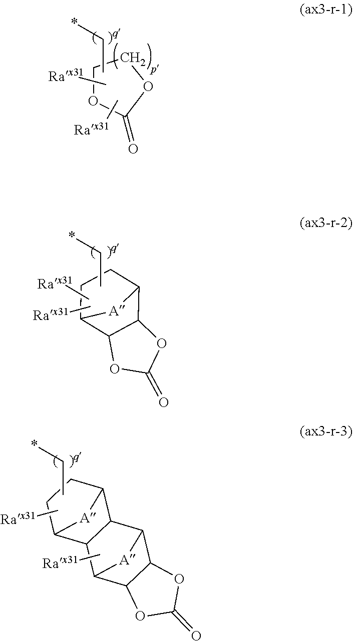

[In the formulae, each Ra′^{x31} independently represents a hydrogen atom, an alkyl group, an alkoxy group, a halogen atom, a halogenated alkyl group, a hydroxyl group, —COOR″, —OC(═O)R″, a hydroxyalkyl group, or a cyano group. R″ represents a hydrogen atom or an alkyl group. A″ represents an oxygen atom, a sulfur atom or an alkylene group having 1 to 5 carbon atoms which may contain an oxygen atom or a sulfur atom. q′ represents 0 or 1. p′ represents an integer of 0 to 3.]

In Formulae (ax3-r-1) and (ax3-r-3), A″ has the same definition as that for A″ in Formulae (a2-r-1).

Examples of the alkyl group, the alkoxy group, the halogen atom, the halogenated alkyl group, —COOR″, —OC(═O)R″, and the hydroxyalkyl group as Ra′³¹ include the same groups as those described above in the explanation of Ra′²¹ in Formulae (a2-r-1) to (a2-r-7).

Specific examples of the groups represented by Formulae (ax3-r-1) to (ax3-r-3) are shown below.

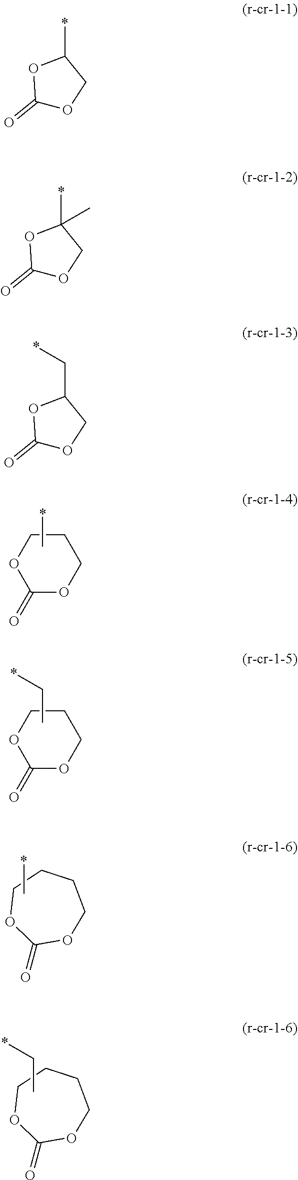

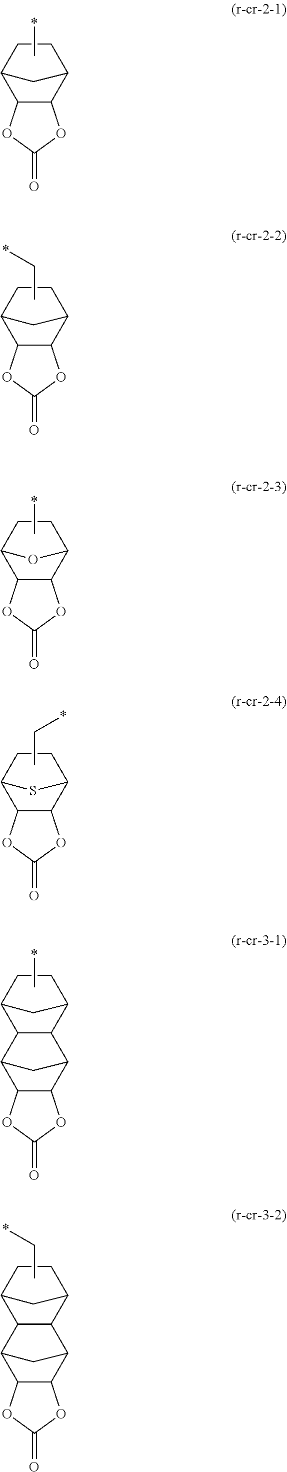

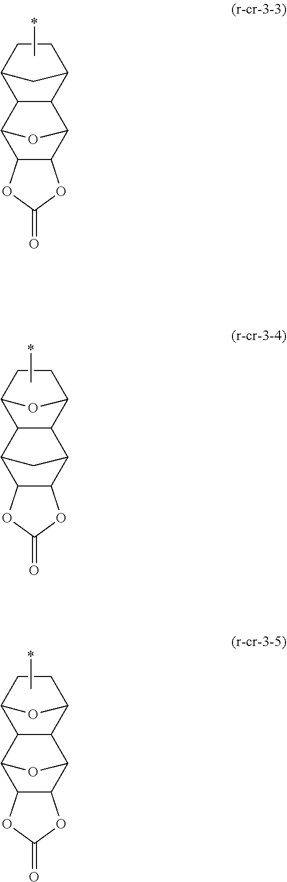

As the constitutional unit (a2), a constitutional unit represented by Formula (a2-1) is preferable.

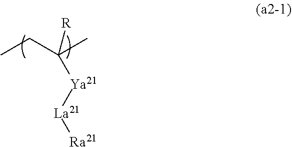

[In Formula (a2-1), R represents a hydrogen atom, an alkyl group having 1 to 5 carbon atoms, or a halogenated alkyl group having 1 to 5 carbon atoms. Ya²¹ represents a single bond or a divalent linking group. La²¹ represents —O—, —COO—, —CON(R′)—, —OCO—, —CONHCO— or —CONHCS—. R′ represents a hydrogen atom or a methyl group. Here, in a case where La²¹ represents —O—, Ya²¹ does not represents —CO—. Ra²¹ represents a —SO₂-containing cyclic group, a lactone-containing cyclic group, or a carbonate-containing cyclic group.]

The divalent linking group as Ya²¹ is not particularly limited, and suitable examples thereof include a divalent hydrocarbon group which may have a substituent and a divalent linking group having heteroatoms.

Divalent Hydrocarbon Group which May have Substituent:

The hydrocarbon group as the divalent linking group may be an aliphatic hydrocarbon group or an aromatic hydrocarbon group.

The aliphatic hydrocarbon group indicates a hydrocarbon group that does not have aromaticity. The aliphatic hydrocarbon group may be saturated or unsaturated. Typically, the aliphatic hydrocarbon group is preferably saturated.

Examples of the aliphatic hydrocarbon group include a linear or branched aliphatic hydrocarbon group and an aliphatic hydrocarbon group having a ring in the structure thereof. Specific examples thereof include the groups exemplified as Va¹ in Formula (a1-1) above.

The linear or branched aliphatic hydrocarbon group may or may not have a substituent. Examples of the substituent include a fluorine atom, a fluorinated alkyl group having 1 to 5 carbon atoms which has been substituted with a fluorine atom, and a carbonyl group.

Examples of the aliphatic hydrocarbon group having a ring in the structure thereof include a cyclic aliphatic hydrocarbon group which may have a substituent containing a heteroatom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in a linear or branched aliphatic hydrocarbon group. As the linear or branched aliphatic hydrocarbon group, the same groups as those described above can be used.

The cyclic aliphatic hydrocarbon group preferably has 3 to 20 carbon atoms and more preferably 3 to 12 carbon atoms.

Specific examples of the cyclic aliphatic hydrocarbon group include groups exemplified as Va¹ in Formula (a1-1) above.

The cyclic aliphatic hydrocarbon group may or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and a methyl group, an ethyl group, a propyl group, an n-butyl group, or a tert-butyl group is particularly preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom as the substituent include a fluorine atom, a chlorine atom, a bromine atom, and an iodine atom, and a fluorine atom is preferable.

Examples of the halogenated alkyl group as the substituent include groups in which some or all hydrogen atoms in the above-described alkyl groups have been substituted with the above-described halogen atoms.

In the cyclic aliphatic hydrocarbon group, some carbon atoms constituting the ring structure thereof may be substituted with a substituent containing a heteroatom. As the substituent containing a heteroatom, —O—, —C(═O)—O—, —S—, —S(═O)₂—, or —S(═O)₂—O— is preferable.

Specific examples of the aromatic hydrocarbon group as a divalent hydrocarbon group include groups exemplified as Va¹ in Formula (a1-1) above.

With respect to the aromatic hydrocarbon group, the hydrogen atom in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group having 1 to 5 carbon atoms, and a methyl group, an ethyl group, a propyl group, an n-butyl group, or a tert-butyl group is more preferable.

As the alkoxy group, the halogen atom, and the halogenated alkyl group as the substituents, the same groups as the above-described substituent groups for substituting a hydrogen atom in the cyclic aliphatic hydrocarbon group can be exemplified.

Divalent Linking Group Having Heteroatom

The heteroatom in a divalent linking group having a heteroatom is an atom other than a carbon atom and a hydrogen atom, and examples thereof include an oxygen atom, a nitrogen atom, a sulfur atom, and a halogen atom.

In a case where Ya²¹ represents a divalent linking group containing a heteroatom, preferred examples of the linking group include —O—, —C(═O)—O—, —C(═O)—, —O—C(═O)—O—, —C(═O)—NH—, —NH—, —NH—C(═NH)— (H may be substituted with a substituent such as an alkyl group, an acyl group, or the like), —S—, —S(═O)₂—, —S(═O)₂—O—, and a group represented by Formula: —Y²¹—O—Y²²—, —Y²¹—O—, —Y²¹—C(═O)—O—, —C(═O)—O—Y²¹—, [Y²¹—C(═O)—O]_{m′}—Y²²—, or —Y²¹—O—C(═O)—Y²²— [in the formulae, Y²¹ and Y²² each independently represents a divalent hydrocarbon group which may have a substituent, O represents an oxygen atom, and m″ represents an integer of 0 to 3].

In a case where the divalent linking group containing a heteroatom is —C(═O)—NH—, —NH—, or —NH—C(═NH)—, H may be substituted with a substituent such as an alkyl group, an acyl group, or the like. The substituent (an alkyl group, an acyl group, or the like) preferably has 1 to 10 carbon atoms, more preferably 1 to 8 carbon atoms, and most preferably 1 to 5 carbon atoms.

In Formulae —Y²¹—O—Y²²—, —Y²¹—O—, —Y²¹—C(═O)—O—, —C(═O)—O—Y²¹—, —[Y²¹—C(═O)—O]_{m′}—Y²²—, or —Y²¹—O—C(═O)—Y²²—, Y²¹ and Y²² each independently represents a divalent hydrocarbon group which may have a substituent. Examples of the divalent hydrocarbon group include the same groups as those described above as the “divalent hydrocarbon group which may have a substituent” in the explanation of the above-described divalent linking group.

As Y²¹, a linear aliphatic hydrocarbon group is preferable, a linear alkylene group is more preferable, a linear alkylene group having 1 to 5 carbon atoms is still more preferable, and a methylene group or an ethylene group is particularly preferable.

As Y²², a linear or branched aliphatic hydrocarbon group is preferable, and a methylene group, an ethylene group, or an alkylmethylene group is more preferable. The alkyl group in the alkylmethylene group is preferably a linear alkyl group having 1 to 5 carbon atoms, more preferably a linear alkyl group having 1 to 3 carbon atoms, and most preferably a methyl group.

In the group represented by Formula —[Y²¹—C(═O)—O]_{m′}—Y²²—, m′ represents an integer of 0 to 3, preferably an integer of 0 to 2, more preferably 0 or 1, and particularly preferably 1. In other words, it is particularly preferable that the group represented by Formula —[Y²¹—C(═O)—O]_{m′}—Y²²— be a group represented by Formula —Y²¹—C(═O)—O—Y²²—. Among these, a group represented by Formula —(CH₂)_{a′}—C(═O)—O—(CH₂)_{b′}— is preferable. In the formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

In the present embodiment, as Ya²¹, a single bond, an ester bond [—C(═O)—O—], an ether bond (—O—), a linear or branched alkylene group, or a combination of these is preferable.

In Formula (a2-1), Ra²¹ represents the —SO₂-containing cyclic group, the lactone-containing cyclic group, or the carbonate-containing cyclic group.

The constitutional unit (a2) included in the component (A) may be used alone or in combination of two or more kinds thereof.

In a case where the component (A) has the constitutional unit (a2), the proportion of the constitutional unit (a2) in the component (A) is preferably in a range of 1% to 80% by mole, more preferably in a range of 5% to 70% by mole, still more preferably in a range of 10% to 65% by mole, and particularly preferably in a range of 10% to 60% by mole with respect to the total amount of all constitutional units constituting the component (A). In a case where the proportion of the constitutional unit (a2) is greater than or equal to the above-described lower limit, the effect obtained by allowing the component (A) to contain the constitutional unit (a2) can be satisfactorily achieved. On the contrary, in a case where the proportion of the constitutional unit (a2) is less than or equal to the above-described upper limit, the constitutional unit (a2) and other constitutional units can be balanced, and various lithography characteristics and the pattern shape can be improved.

The component (A1) may have the following constitutional unit (a3) and/or constitutional unit (a4) in addition to the above-described constitutional units (a1) and (a2).

(Constitutional Unit (a3))

The component (a3) is a constitutional unit (here, a constitutional unit corresponding to the above-described constitutional unit (a1) or (a2) is excluded) containing a polar group-containing aliphatic hydrocarbon group.

It is considered that, in a case where the component (A1) includes the constitutional unit (a3), the hydrophilicity of the component (A) is enhanced, and this contributes to improvement of the resolution.

Examples of the polar group include a hydroxyl group, a cyano group, a carboxyl group, or a hydroxyalkyl group in which some hydrogen atoms of the alkyl group have been substituted with fluorine atoms. Among these, a hydroxyl group is particularly preferable.

Examples of the aliphatic hydrocarbon group include linear or branched hydrocarbon groups (preferably alkylene groups) having 1 to 10 carbon atoms, and cyclic aliphatic hydrocarbon groups (cyclic groups). The cyclic group may be a monocyclic group or a polycyclic group. For example, these cyclic groups can be selected appropriately from the multitude of groups that have been suggested for the resins of resist compositions for ArF excimer lasers. The cyclic group is preferably a polycyclic group and more preferably a polycyclic group having 7 to 30 carbon atoms.

Among the examples, constitutional units derived from acrylic acid ester that includes an aliphatic polycyclic group containing a hydroxyl group, cyano group, carboxyl group, or a hydroxyalkyl group in which some hydrogen atoms of the alkyl group have been substituted with fluorine atoms are particularly preferable. Examples of the polycyclic group include groups in which two or more hydrogen atoms have been removed from a bicycloalkane, tricycloalkane, tetracycloalkane or the like. Specific examples thereof include groups in which two or more hydrogen atoms have been removed from a polycycloalkane such as adamantane, norbomane, isobomane, tricyclodecane or tetracyclododecane. Among these polycyclic groups, groups in which two or more hydrogen atoms have been removed from adamantane, groups in which two or more hydrogen atoms have been removed from norbomane or groups in which two or more hydrogen atoms have been removed from tetracyclododecane are preferred industrially.

The constitutional unit (a3) is not particularly limited as long as the constitutional unit contains a polar group-containing aliphatic hydrocarbon group, and an optional constitutional unit may be used.

The constitutional unit (a3) is a constitutional unit derived from acrylic acid ester in which the hydrogen atom bonded to the carbon atom at the α-position may be substituted with a substituent, and a constitutional unit containing a polar group-containing aliphatic hydrocarbon group is preferable.

In a case where the hydrocarbon group in the polar group-containing aliphatic hydrocarbon group is a linear or branched hydrocarbon group having 1 to 10 carbon atoms, the constitutional unit (a3) is preferably a constitutional unit derived from hydroxyethyl ester of acrylic acid. On the other hand, in a case where the hydrocarbon group is a polycyclic group, a constitutional unit represented by Formula (a3-1), a constitutional unit represented by Formula (a3-2), and a constitutional unit represented by Formula (a3-3) shown below are preferable.

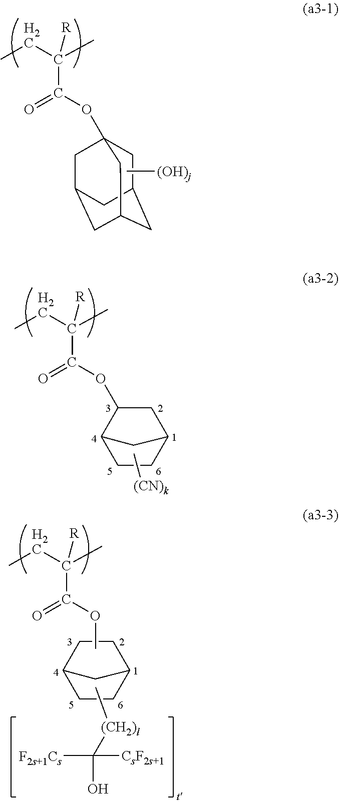

[In Formulae (a3-1) to (a3-3), R represents a hydrogen atom, an alkyl group having 1 to 5 carbon atoms, or a halogenated alkyl group having 1 to 5 carbon atoms, j represents an integer of 1 to 3, k represents an integer of 1 to 3, t′ represents an integer of 1 to 3, 1 represents an integer of 1 to 5, and s represents an integer of 1 to 3.]

In Formulae (a3-1) to (a3-3), R has the same definition as described above.

In Formula (a3-1), j preferably represents 1 or 2 and more preferably 1. In a case where j represents 2, it is preferable that the hydroxyl groups be bonded to the 3rd and 5th positions of the adamantyl group. In a case where j represents 1, it is preferable that the hydroxyl group be bonded to the 3rd position of the adamantyl group.

j preferably represents 1, and it is particularly preferable that the hydroxyl group be bonded to the 3rd position of the adamantyl group.

In Formula (a3-2), k preferably represents 1. The cyano group is preferably bonded to the 5th or 6th position of the norbornyl group.

In Formula (a3-3), t′ preferably represents 1. 1 preferably represents 1. s preferably represents 1. Further, it is preferable that a 2-norbornyl group or 3-norbornyl group be bonded to the terminal of the carboxy group of the acrylic acid. The fluorinated alkyl alcohol is preferably bonded to the 5th or 6th position of the norbornyl group.

The constitutional unit (a3) included in the component (A1) may be used alone or in combination of two or more kinds thereof.

The proportion of the constitutional unit (a3) in the component (A1) is preferably in a range of 5% to 50% by mole, more preferably in a range of 5% to 40% by mole, and still more preferably in a range of 5% to 25% by mole with respect to the total amount of all constitutional units constituting the component (A1).

By setting the proportion of the constitutional unit (a3) to be greater than or equal to the above-described lower limit, the effects obtained by allowing the constitutional unit (a3) to be contained in the component (A1) can be sufficiently obtained. Further, by setting the proportion of the constitutional unit (a3) to be lower than or equal to the above-described upper limit, the constitutional unit (a3) and other constitutional units can be balanced.

(Constitutional Unit (a4))

The constitutional unit (a4) is a constitutional unit containing an acid undissociable cyclic group. In a case where the component (A1) includes the constitutional unit (a4), the dry etching resistance of the resist pattern to be formed is improved. Further, the hydrophobicity of the component (A1) is improved. It is considered that an increase in the hydrophobicity contributes to improvement of the resolution, the shape of the resist pattern, and the like particularly in a case of the organic solvent development.

The “acid undissociable aliphatic cyclic group” in the constitutional unit (a4) indicates a cyclic group which remains in the constitutional unit without being dissociated even at the time of an action of an acid in a case where an acid is generated from the component (B) described below upon exposure.

As the constitutional unit (a4), a constitutional unit which contains an acid undissociable aliphatic cyclic group and is also derived from acrylic acid ester is preferable. As the cyclic group, the groups exemplified in the case of the constitutional unit (a1) can be exemplified and any of those which have been known in the related art as being used in the resin component of resist compositions for ArF excimer lasers or KrF excimer lasers (preferably for ArF excimer lasers) can be used.

From the viewpoint of the industrial availability and the like, at least one polycyclic group selected from among a tricyclodecyl group, an adamantyl group, a tetracyclododecyl group, an isobornyl group, and a norbornyl group is particularly preferable. These polycyclic groups may include a linear or branched alkyl group having 1 to 5 carbon atoms as a substituent.

Specific examples of the constitutional unit (a4) include constitutional units represented by any of Formulae (a4-1) to (a4-7) shown below.

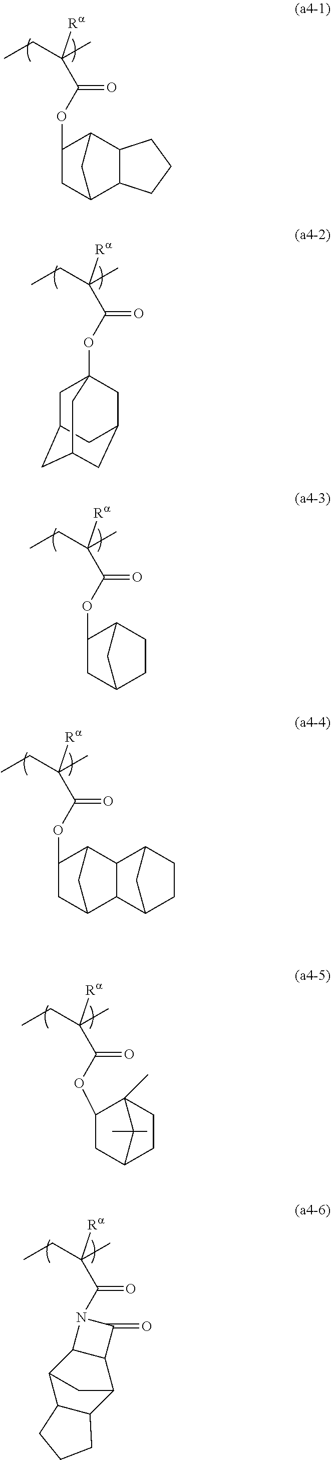

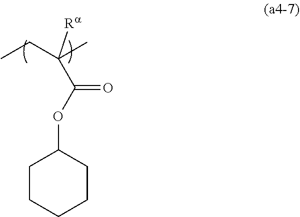

[In Formulae (a4-1) to (a4-7), R^{α} represents a hydrogen atom, a methyl group, or a trifluoromethyl group.]

The constitutional unit (a4) included in the component (A1) may be used alone or in combination of two or more kinds thereof.

In a case where the component (A1) has the constitutional unit (a4), the proportion of the constitutional unit (a4) is preferably in a range of 1% to 30% by mole and more preferably in a range of 10% to 20% by mole with respect to the total amount of all constitutional units constituting the component (A1).

It is preferable that the component (A1) be a copolymer having constitutional units (a1) and (a2) and more preferable that the component (A1) be a copolymer having constitutional units (a1), (a2), and (a3).

The component (A1) can be obtained by polymerizing a monomer from which each constitutional unit is derived through known radical polymerization performed using a radical polymerization initiator such as azobisisobutylonitrile (AIBN) or dimethyl azobisisobutyrate.

Further, a —C(CF₃)₂—OH group may be introduced into the terminal of the component (A1) during the polymerization using a chain transfer agent such as HS—CH₂—CH₂—CH₂—C(CF₃)₂—OH together. As described above, a copolymer into which a hydroxyalkyl group, formed by substitution of some hydrogen atoms in the alkyl group with fluorine atoms, has been introduced is effective for reducing development defects and reducing line edge roughness (LER: uneven irregularities of a line side wall).

In the present embodiment, the weight-average molecular weight (Mw) (in terms of polystyrene determined by gel permeation chromatography) of the component (A1) is not particularly limited, but is preferably in a range of 1,000 to 50,000, more preferably in a range of 1,500 to 30,000, and most preferably in a range of 2,000 to 20,000. In a case where the weight-average molecular weight thereof is less than or equal to the upper limit of the above-described range, the resist composition exhibits a satisfactory solubility in a solvent for a resist enough to be used as a resist. Meanwhile, in a case where the weight-average molecular weight is greater than or equal to the lower limit of the above-described range, dry etching resistance and the cross-sectional shape of the resist pattern become excellent.

The dispersity (Mw/Mn) thereof is not particularly limited, but is preferably in a range of 1.0 to 5.0, more preferably in a range of 1.0 to 4.0, and most preferably in a range of 1.0 to 3.0. Further, Mn indicates the number-average molecular weight.

The component (A1) may be used alone or in combination of two or more kinds thereof.

The proportion of the component (A1) in the base material component (A) is preferably 25% by mass or greater, more preferably 50% by mass or greater, still more preferably 75% by mass or greater, or may be 100% by mass with respect to the total mass of the base material component (A). In a case where the proportion thereof is 25% by mass or greater, the lithography characteristics are further improved.

In the present embodiment, the component (A) may be used alone or in combination of two or more kinds thereof.

In the present embodiment, the content of the component (A) may be adjusted according to the thickness of the resist film to be formed and the like.

<<Acid Generator Component: Component (B)>>

In the present embodiment, the acid generator component contained in the resist composition contains a compound (hereinafter, also referred to as a “compound (b1)”) represented by Formula (b1) and a compound (hereinafter, also referred to as a “compound (b2)”) represented by formula (b2).

[Compound (b1)]

The compound (b1) is a compound represented by Formula (b1).

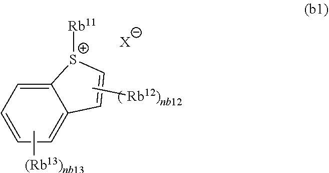

[In Formula (b1), Rb¹¹ represents an aryl group having a substituent, and Rb¹² and Rb¹³ each independently represents an alkyl group having 1 to 10 carbon atoms which may have a substituent, an acetyl group, an alkoxy group having 1 to 10 carbon atoms, a carboxy group, or a hydroxyl group. nb12 represents an integer of 0 to 2, and nb13 represents an integer of 0 to 4. X⁻ represents a counter anion.]

Cationic Moiety

(Rb11)

In Formula (b1), Rb¹¹ represents an aryl group having a substituent. As the aryl group represented by Rb¹¹, an aryl group having 6 to 20 carbon atoms is exemplified. As the aryl group represented by Rb¹¹, a phenyl group or a naphthyl group is preferable, and a phenyl group is more preferable.

Examples of the substituent included in Rb¹¹ include an alkyl group, an alkoxy group, a halogen atom, a halogenated alkyl group, a hydroxyalkyl group, a hydroxyl group, a carbonyl group, and a nitro group.

As the alkyl group as the substituent, an alkyl group having 1 to 20 carbon atoms is preferable, an alkyl group having 1 to 15 carbon atoms is preferable, and an alkyl group having 2 to 5 carbon atoms is particularly preferable. The alkyl group may be linear or branched.

Specific examples of the alkyl group include a methyl group, an ethyl group, a propyl group, an n-butyl group, a tert-butyl group, an n-pentyl group, an n-hexyl group, an n-heptyl group, an n-octyl group, an n-nonyl group, an n-decyl group, an n-undecyl group, and an n-dodecyl group. Among these, a methyl group, an ethyl group, a propyl group, an n-butyl group, or a tert-butyl group is preferable, and a tert-butyl group is most preferable.

As the alkoxy group as the substituent, an alkoxy group having 1 to 5 carbon atoms is preferable, a methoxy group, an ethoxy group, an n-propoxy group, an iso-propoxy group, an n-butoxy group, or a tert-butoxy group is more preferable, and a methoxy group or an ethoxy group is most preferable.

Examples of the halogen atom as the substituent include a fluorine atom, a chlorine atom, a bromine atom, and an iodine atom, and a fluorine atom is preferable.

Example of the halogenated alkyl group as the substituent includes a group in which some or all hydrogen atoms in an alkyl group having 1 to 5 carbon atoms such as a methyl group, an ethyl group, a propyl group, an n-butyl group, or a tert-butyl group have been substituted with the above-described halogen atoms.

Examples of the hydroxyalkyl group as the substituent include a group in which some or all hydrogen atoms in an alkyl group having 1 to 5 carbon atoms have been substituted with a hydroxyl group. Examples of the alkyl group having 1 to 5 carbon atoms include a methyl group, an ethyl group, a propyl group, an n-butyl group, and a tert-butyl group.

In a case of a resist composition for an alkali development process, from the viewpoint of improving the solubility in an alkali developing solution, among the above-described substituents, a hydroxyl group or a hydroxyalkyl group is preferable.

Further, in a case of a resist composition for a solvent development process, from the viewpoint of improving the solubility in an organic solvent developing solution, among the above-described substituents, an alkyl group is preferable. Among examples of the alkyl group, an alkyl group having 1 to 10 carbon atoms is preferable, an alkyl group having 3 to 5 carbon atoms is more preferable, and an n-butyl group or a tert-butyl group is particularly preferable.

The number of substituents in the aryl group as Rb¹¹ may be 1 or greater and can be appropriately selected depending on the type of the aryl group. For example, in a case where a phenyl group is used as the aryl group, the number of substituents can be set to be in a range of 1 to 5, preferably 1 or 2, and more preferably 2. In a case where the aryl group as Rb¹¹ has a plurality of substituents, the plurality of substituents may be the same as or different from one another.

(Rb¹² and Rb¹³)

In Formula (b1), Rb12 and Rb13 each independently represents an alkyl group having 1 to 10 carbon atoms which may have a substituent, an acetyl group, an alkoxy group having 1 to 10 carbon atoms, a carboxy group, or a hydroxyl group.

The alkyl group having 1 to 10 carbon atoms as Rb¹² and Rb¹³ may be linear or branched.

Specific examples of the linear alkyl group include a methyl group, an ethyl group, a propyl group, an n-butyl group, a pentyl group, a hexyl group, an octyl group, a nonyl group, and a decyl group.

Examples of the branched alkyl group include an isopropyl group, an isobutyl group, a tert-butyl group, an isopentyl group, a neopentyl group, a 1,1-dimethylethyl group, a 1,1-diethylpropyl group, a 2,2-dimethylpropyl group, and a 2,2-dimethylbutyl group.

Examples of the substituent which may be included in the alkyl group as Rb¹² and Rb¹³ include a hydroxyl group and a carbonyl group.

Further, some carbon atoms constituting the alkyl group as Rb¹² and Rb¹³ may be substituted with a substituent containing a heteroatom. As the substituent containing a heteroatom, —O—, —C(═O)—O—, —S—, —S(═O)₂—, or —S(═O)₂—O— is preferable.

It is preferable that the alkoxy group as Rb¹² and Rb¹³ be an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among these, a methoxy group and an ethoxy group are preferable.

In a case of the resist composition for an alkali development process, from the viewpoint of improving the solubility in an alkali developing solution, as Rb¹² and Rb¹³ a hydroxyl group, an acetyl group, a carboxy group, or an alkyl group having a hydroxyl group as a substituent is preferable.

Further, in a case of the resist composition for a solvent development process, from the viewpoint of improving the solubility in an organic solvent developing solution, as Rb¹² and Rb¹³, an alkyl group is preferable. Among examples of the alkyl group, an alkyl group having 3 to 5 carbon atoms is preferable, and an n-butyl group or a tert-butyl group is particularly preferable.

(nb12 and nb13)

In Formula (b1), nb12 represents an integer of 0 to 2, and nb13 represents an integer of 0 to 4.

nb12 preferably represents 0 or 1 and particularly preferably 0. nb13 preferably represents 0 to 2 and particularly preferably 0 or 1.

In a case where nb12 represents 2, a plurality of Rb¹²'s may be the same as or different from one another. In a case where nb13 represents 2 to 4, a plurality of Rb¹³'s may be the same as or different from one another.

Specific examples of the cationic moiety in the compound represented by Formula (b1) will be described.

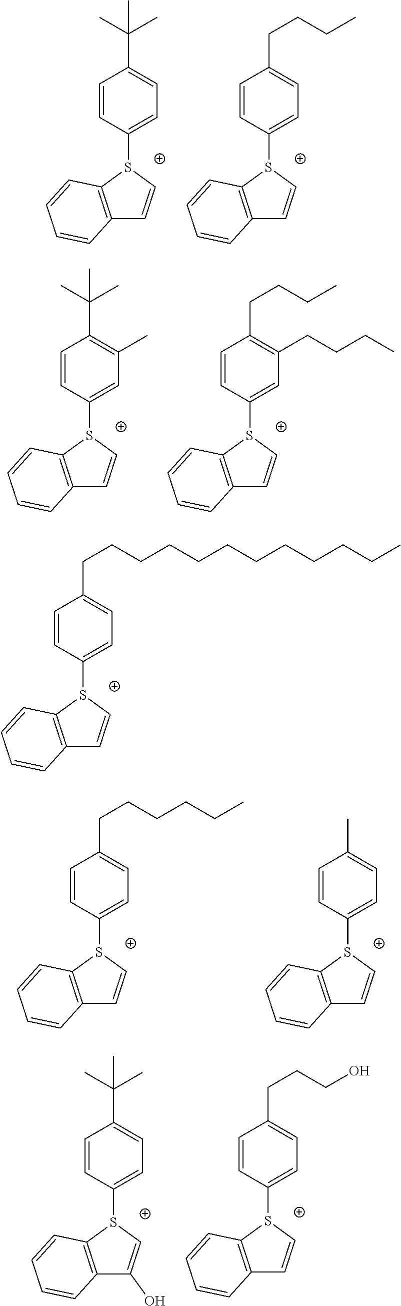

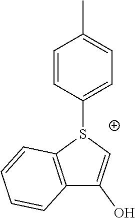

It is preferable that the compound (b1) represented by Formula (b1) be a compound having a cationic moiety represented by Formula (b1)-1 or (b1)-2. Among these, a compound represented by Formula (b1)-1 is preferable.

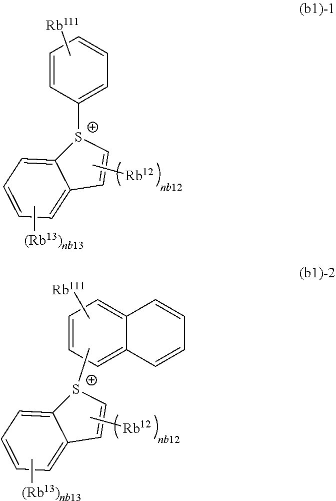

[In Formula (b1)-1 or (b1)-2, Rb¹¹¹ represents an alkyl group having 1 to 20 carbon atoms, Rb¹² and Rb¹³ each independently represents an alkyl group having 1 to 10 carbon atoms which may have a substituent, an acetyl group, an alkoxy group having 1 to 10 carbon atoms, a carboxy group, or a hydroxyl group, nb12 represents an integer of 0 to 2, and nb13 represents an integer of 0 to 4.]

In Formula (b1)-1 or (b1)-2, Rb¹¹¹ represents an alkyl group having 1 to 20 carbon atoms. The alkyl group having 1 to 20 carbon atoms as Rb¹¹¹ has the same definition as that for the alkyl group having 1 to 20 carbon atoms described in the section of Rb¹¹ in Formula (b1).

In Formula (b1)-1 or (b1)-2, Rb¹², Rb¹³, nb12, and nb13 each have the same definition as that for Rb¹², Rb¹³, nb12, and nb13 in Formula (b1).

Anionic Moiety

In Formula (b1), X⁻ represents a counter anion.

As the counter anion represented by X⁻, those which have been suggested as an anionic structure of an acid generator for a chemically amplified resist can be used.

In the present embodiment, it is preferable that X⁻ represent an anion represented by any of Formulae (b-1) to (b-3).

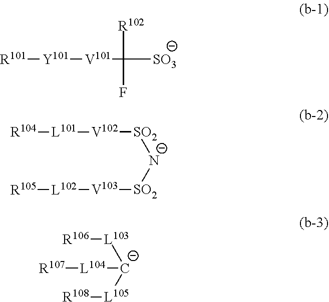

[In the formulae, R¹⁰¹ and R¹⁰⁴ to R¹⁰⁸ each independently represents a cyclic group which may have a substituent, a chain-like alkyl group which may have a substituent, or a chain-like alkenyl group which may have a substituent. R¹⁰⁴ and R¹⁰⁵ may be bonded to each other to form a ring. Any two of R¹⁰⁶ and R¹⁰⁷ may be bonded to form a ring. R¹⁰² represents a fluorine atom or a fluorinated alkyl group having 1 to 5 carbon atoms. Y¹⁰¹ represents a single bond or a divalent linking group containing an oxygen atom. V¹⁰¹ to V¹⁰³ each independently represents a single bond, an alkylene group, or a fluorinated alkylene group. L¹⁰¹ and L¹⁰² each independently represents a single bond or an oxygen atom. L¹⁰³ to L¹⁰⁵ each independently represents a single bond, —CO—, or —SO₂—.]

In Formula (b-1), R¹⁰¹ represents a cyclic group which may have a substituent, a chain-like alkyl group which may have a substituent, or a chain-like alkenyl group which may have a substituent.

(Cyclic Group which May have Substituent as R¹⁰¹)

The cyclic group is preferably a cyclic hydrocarbon group, and the cyclic hydrocarbon group may be an aromatic hydrocarbon group or an aliphatic hydrocarbon group.

Examples of the aromatic hydrocarbon group as R¹⁰¹ include an aromatic hydrocarbon ring exemplified in the section of the divalent aromatic hydrocarbon group represented by Va¹ in Formula (a1-1) and an aryl group in which one hydrogen atom has been removed from an aromatic compound having two or more aromatic rings. Among these, a phenyl group or a naphthyl group is preferable.

Examples of the cyclic aliphatic hydrocarbon group as R¹⁰¹ include a group in which one hydrogen atom has been removed from the monocycloalkane or polycycloalkane described in the section of the divalent aliphatic hydrocarbon group represented by Va1 in Formula (a1-1). Among these, an adamantyl group or a norbornyl group is preferable.

The cyclic hydrocarbon group as R¹⁰¹ may contain a heteroatom such as a hetero ring. Specific examples thereof include lactone-containing cyclic groups represented by Formulae (a2-r-1) to (a2-r-7), the —SO₂-containing cyclic group represented by Formulae (a5-r-1) to (a5-r-4), and other heterocyclic groups represented by Formulae (r-hr-1) to (r-hr-16).

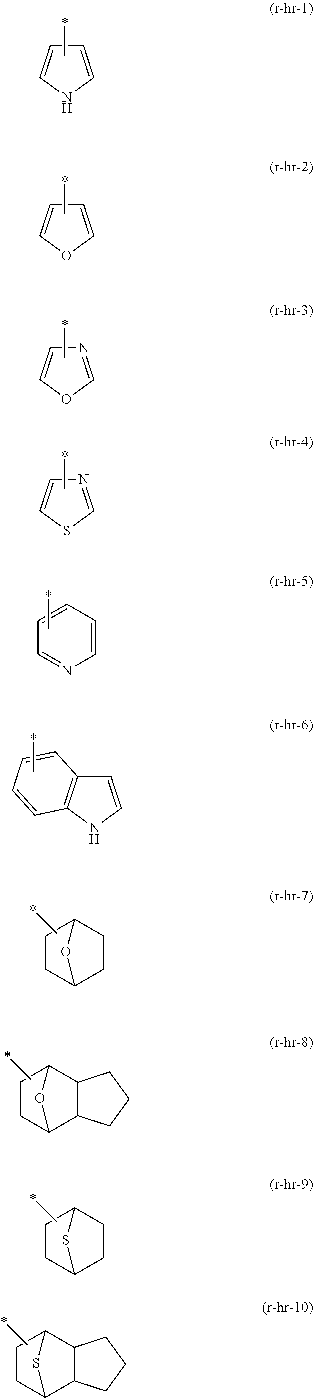

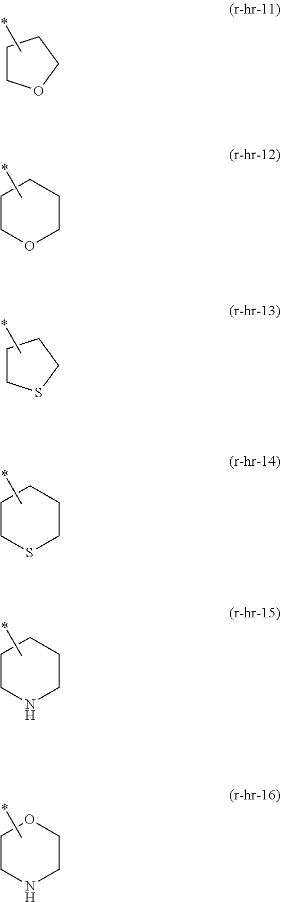

Examples of the substituent for the cyclic hydrocarbon group as R¹⁰¹ include an alkyl group, an alkoxy group, a halogen atom, a halogenated alkyl group, a hydroxyl group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom for the substituent include a fluorine atom, a chlorine atom, a bromine atom, and an iodine atom, and a fluorine atom is preferable.

Example of the above-described halogenated alkyl group as the substituent includes a group in which some or all hydrogen atoms in an alkyl group having 1 to 5 carbon atoms such as a methyl group, an ethyl group, a propyl group, an n-butyl group, or a tert-butyl group have been substituted with the above-described halogen atoms.

(Chain-Like Alkyl Group which May have Substituent as R¹⁰¹)

The chain-like alkyl group as R¹⁰¹ may be linear or branched.

The linear alkyl group preferably has 1 to 20 carbon atoms, more preferably 1 to 15 carbon atoms, and most preferably 1 to 10 carbon atoms. Specific examples thereof include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group.

The branched alkyl group preferably has 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

(Chain-Like Alkenyl Group which May have Substituent as R¹⁰¹)

Such a chain-like alkenyl group as R¹⁰¹ may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylpropenyl group and a 2-methylpropenyl group.

Among the examples, as the chain-like alkenyl group, a propenyl group is particularly preferable.

As the substituent for the chain-like alkyl group or alkenyl group as R¹⁰¹, an alkoxy group, a halogen atom, a halogenated alkyl group, a hydroxyl group, a carbonyl group, a nitro group, an amino group, a cyclic group as R¹⁰¹ or the like can be used.

Among the examples, as R¹⁰¹, a cyclic group which may have a substituent is preferable, and a cyclic hydrocarbon group which may have a substituent is more preferable. More specific preferred examples thereof include a phenyl group, a naphthyl group, a group in which one or more hydrogen atoms have been removed from a polycycloalkane, a lactone-containing cyclic group represented by any of Formulae (a2-r-1) to (a2-r-7), and a —SO₂-containing cyclic group represented by any of Formulae (a5-r-1) to (a5-r-4).

In Formula (b-1), Y¹⁰¹ represents a single bond or a divalent linking group containing an oxygen atom.

In a case where Y¹⁰¹ represents a divalent linking group containing an oxygen atom, Y¹⁰¹ may contain an atom other than an oxygen atom. Examples of atoms other than an oxygen atom include a carbon atom, a hydrogen atom, a sulfur atom, and a nitrogen atom.

Examples of divalent linking groups containing an oxygen atom include non-hydrocarbon oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and combinations of the above-described non-hydrocarbon oxygen atom-containing linking groups with an alkylene group. Furthermore, a sulfonyl group (—SO₂—) may be linked to the combination. Examples of the combination include linking groups represented by Formulae (y-al-1) to (y-al-7) shown below.

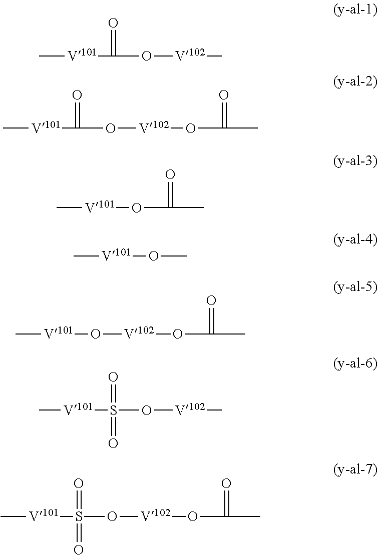

[In the formulae, V′¹⁰¹ represents a single bond or an alkylene group having 1 to 5 carbon atoms, and V′¹⁰² represents a divalent saturated hydrocarbon group having 1 to 30 carbon atoms.]

The divalent saturated hydrocarbon group as V′¹⁰² is preferably an alkylene group having 1 to 30 carbon atoms.

The alkylene group as V′¹⁰¹ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂—, —CH₂CH(CH₃)CH₂CH₂—; and a pentamethylene group [—CH₂CH₂CH₂CH₂CH₂—].

Further, a part of methylene group in the alkylene group as V′¹⁰¹ and V′¹⁰² may be substituted with a divalent aliphatic cyclic group having 5 to 10 carbon atoms. The aliphatic cyclic group is preferably a divalent group in which one hydrogen atom has been removed from the cyclic aliphatic hydrocarbon group as Ra′³ in Formula (a1-r-1), and a cyclohexylene group, a 1,5-adamantylene group, or a 2,6-adamantylene group is more preferable.

Y¹⁰¹ preferably represents a divalent linking group having an ester bond or an ether bond and preferably linking groups represented by Formulae (y-al-1) to (y-al-5).

In Formula (b-1), V¹⁰¹ represents a single bond, an alkylene group, or a fluorinated alkylene group. The alkylene group and the fluorinated alkylene group as V¹⁰¹ preferably have 1 to 4 carbon atoms. Examples of the fluorinated alkylene group as V¹⁰¹ include a group in which some or all hydrogen atoms in the alkylene group as V¹⁰¹ have been substituted with fluorine atoms. Among these examples, as V¹⁰¹, a single bond or a fluorinated alkylene group having 1 to 4 carbon atoms is preferable.

In Formula (b-1), R¹⁰² represents a fluorine atom or a fluorinated alkyl group having 1 to 5 carbon atoms. R¹⁰² preferably represents a fluorine atom or a perfluoroalkyl group having 1 to 5 carbon atoms and more preferably a fluorine atom.

As a specific example of the anionic moiety for the component (b-1), in a case where Y¹⁰¹ represents a single bond, a fluorinated alkylsulfonate anion such as a trifluoromethanesulfonate anion or a perfluorobutanesulfonate anion can be exemplified; and in a case where Y¹⁰¹ represents a divalent linking group containing an oxygen atom, anions represented by Formulae (an-1) to (an-3) shown below can be exemplified.

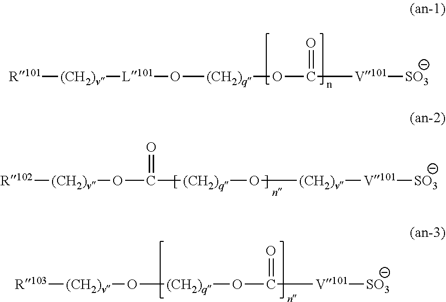

[In the formulae R″¹⁰¹ represents an aliphatic cyclic group which may have a substitutent, a group represented by any of Formulae (r-hr-1) to (r-hr-6), or a chain-like alkyl group which may have a substituent; R″¹⁰² represents an aliphatic cyclic group which may have a substituent, a lactone-containing cyclic group represented by any of Formulae (a2-r-1) to (a2-r-7), or a —SO₂-containing cyclic group represented by any of Formulae (a5-r-1) to (a5-r-4); R″¹⁰³ represents an aromatic cyclic group which may have a substituent, an aliphatic cyclic group which may have a substituent, or a chain-like alkenyl group which may have a substituent; V″¹⁰¹ represents a fluorinated alkylene group; L″¹⁰¹ represents —C(═O) or —SO₂—; each v″ independently represents an integer of 0 to 3; each q″ independently represents an integer of 1 to 20; and n″ represents 0 or 1.]

As the aliphatic cyclic group as R″¹⁰¹, R″¹⁰², and R″¹⁰³ which may have a substituent, the same groups as the cyclic aliphatic hydrocarbon group as R¹⁰¹ described above are preferable. As the substituent, the same groups as the substituents which may substitute the cyclic aliphatic hydrocarbon group as R¹⁰¹ can be exemplified.

As the aromatic cyclic group as R″¹⁰³ which may have a substituent, the same groups as the aromatic hydrocarbon group for the cyclic hydrocarbon group represented by R¹⁰¹ described above are preferable. As the substituent, the same groups as the substituents which may substitute the aromatic hydrocarbon group as R¹⁰¹ can be exemplified.

As the chain-like alkyl group as R″¹⁰¹ which may have a substituent, the same groups exemplified as the chain-like alkyl groups represented by R¹⁰¹ are preferable. As the chain-like alkenyl group as R″¹⁰³ which may have a substituent, the same groups exemplified as the chain-like alkenyl groups represented by R¹⁰¹ are preferable. V″¹⁰¹ represents a fluorinated alkylene group, and a carbon atom bonded to —SO₃ has at least one fluorine atom as a substituent. V″¹⁰¹ preferably represents a fluorinated alkylene group having 1 to 3 carbon atoms and particularly preferably —CF₂—, —CF₂CF₂—, —CHFCF₂—, —CF(CF₃)CF₂—, or —CH(CF₃)CF₂—.

Specific examples of the anion represented by Formula (b-1) are as follows.

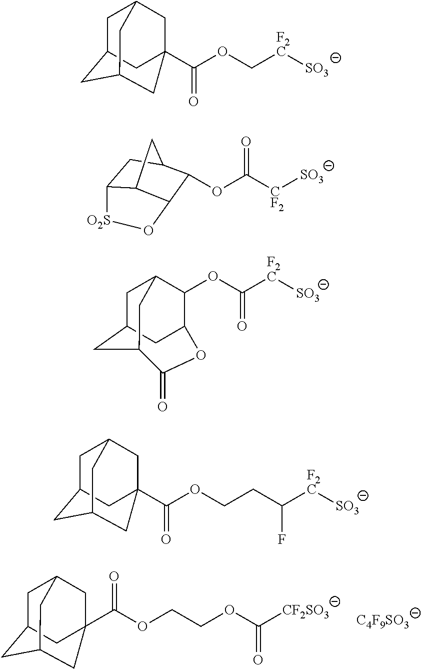

In Formula (b-2), R¹⁰⁴ and R¹⁰⁵ each independently represents a cyclic group which may have a substituent, a chain-like alkyl group which may have a substituent or a chain-like alkenyl group which may have a substituent, and has the same definition as that for R¹⁰¹ in Formula (b-1). Here, R¹⁰⁴ and R¹⁰⁵ may be bonded to each other to form a ring.

As R¹⁰⁴ and R¹⁰⁵, a chain-like alkyl group which may have a substituent is preferable, and a linear or branched alkyl group or a linear or branched fluorinated alkyl group is more preferable.

The chain-like alkyl group preferably has 1 to 10 carbon atoms, more preferably 1 to 7 carbon atoms, and still more preferably 1 to 3 carbon atoms. It is preferable that the number of carbon atoms in the chain-like alkyl group as R¹⁰⁴ and R¹⁰⁵ be small because the solubility in a solvent for a resist is also excellent in the range of the number of carbon atoms. Further, in the chain-like alkyl group as R¹⁰⁴ and R¹⁰⁵, it is preferable that the number of hydrogen atoms substituted with fluorine atoms be as large as possible because the acid strength increases and the transparency to high energy radiation of 200 nm or less or electron beams is improved.

The proportion of fluorine atoms in the chain-like alkyl group, that is, the fluorination ratio is preferably in a range of 70% to 100% and more preferably in a range of 90% to 100%, and it is most preferable that the chain-like alkyl group be a perfluoroalkyl group in which all hydrogen atoms are substituted with fluorine atoms.

In Formula (b-2), V¹⁰² and V¹⁰³ each independently represents a single bond, an alkylene group, or a fluorinated alkylene group, and has the same definition as that for V¹⁰¹ in Formula (b-1).

In Formula (b-2), L¹⁰¹ and L¹⁰² each independently represents a single bond or an oxygen atom.

Specific examples of the anion represented by Formula (b-2) are as follows.

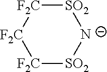 [SMILES: O=S1(=O)[N-]S(=O)(=O)C(F)(F)C(F)(F)C1(F)F]

In Formula (b-3), R¹⁰⁶ to R¹⁰⁸ each independently represents a cyclic group which may have a substituent or a chain-like alkyl group which may have a substituent or a chain-like alkenyl group which may have a substituent, and has the same definition as that for R¹⁰¹ in Formula (b-1).

L¹⁰³ to L¹⁰⁵ each independently represents a single bond, —CO—, or —SO₂—.

Specific examples of the anion represented by Formula (b-3) are as follows.

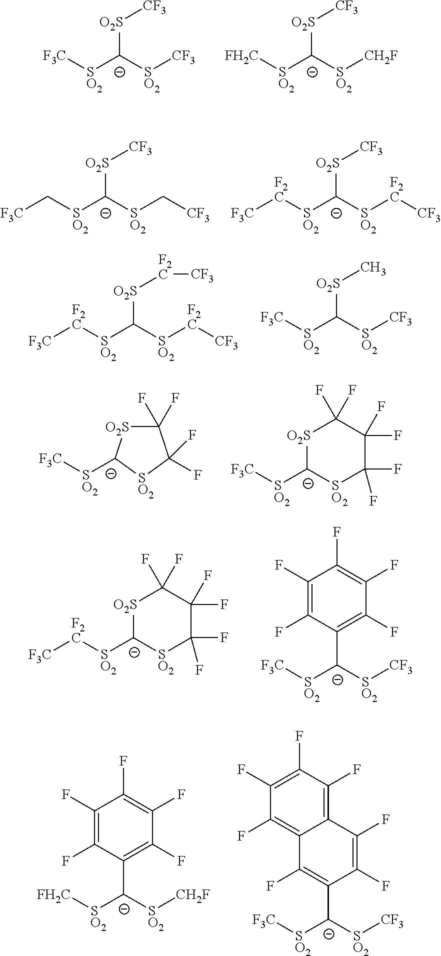

In the present invention, as the anionic moiety of the compound (b1) represented by Formula (b1), among the examples described above, an anionic moiety represented by Formula (b-1) or (b-2) is preferable.

Hereinafter, specific examples of the compound (b1) will be described.

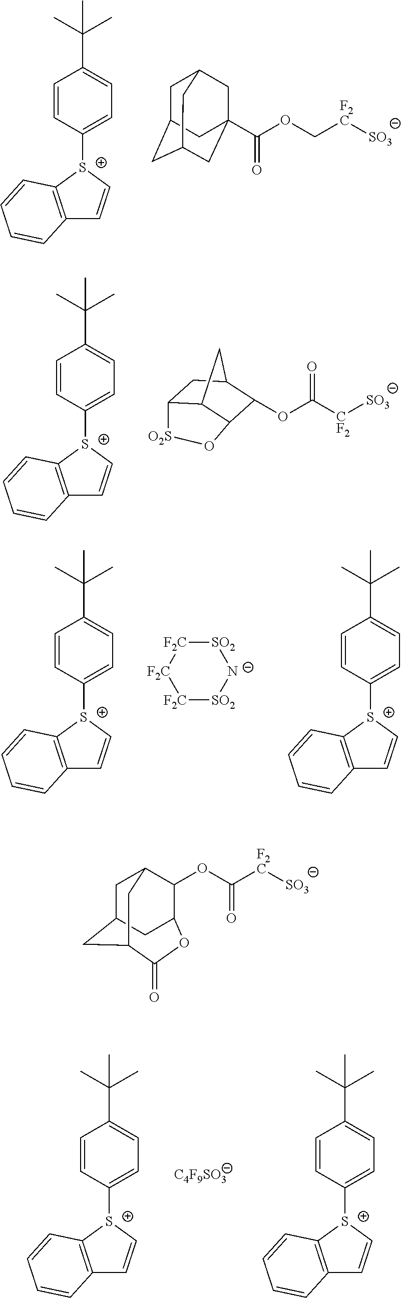

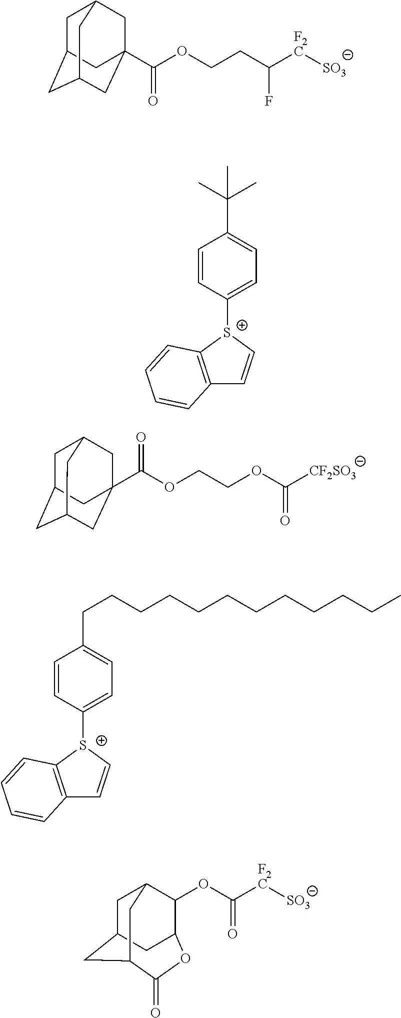

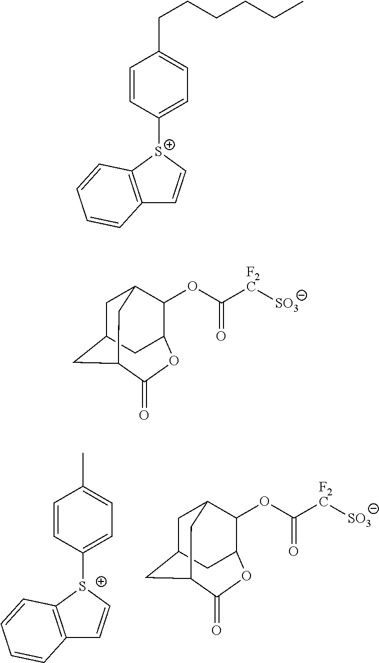

The compound (b1) may be used alone or in combination of two or more selected from the compounds (b1) described above.

The content of the compound (b1) is preferably in a range of 0.5 to 10 parts by mass, more preferably in a range of 0.5 to 8 parts by mass, and still more preferably in a range of 1 to 8 parts by mass with respect to 100 parts by mass of the component (A).

[Compound (b2)]

The compound (b2) is a compound represented by Formula (b2).

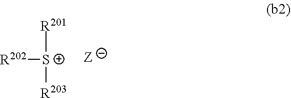

[In Formula (b2), R²⁰¹ to R²⁰³ each independently represents an aryl group which may have a substituent. Z⁻ represents a counter anion.]

Cationic Moiety

(R²⁰¹ to R²⁰³)

In Formula (b2), R²⁰¹ to R²⁰³ each independently represents an aryl group which may have a substituent.

Examples of the aryl group as R²⁰¹ to R²⁰³ include an unsubstituted aryl group having 6 to 20 carbon atoms, and a phenyl group or a naphthyl group is preferable.

Examples of the substituent which R²⁰¹ to R²⁰³ may have include an alkyl group, a halogen atom, a halogenated alkyl group, a carbonyl group, a cyano group, an amino group, an aryl group, an arylthio group, and groups represented by Formulae (ca-r-1) to (ca-r-7) shown below.

Specific examples of the aryl group in the arylthio group as the substituent include a phenylthio group and a biphenylthio group.

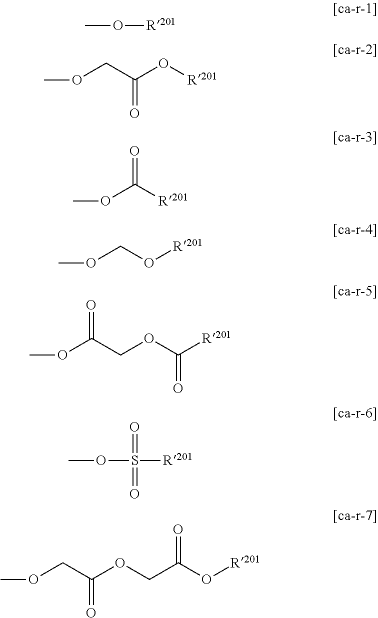

[In Formulae (ca-r-1) to (ca-r-7), each R′²⁰¹ independently represents a hydrogen atom, a cyclic group which may have a substituent, a chain-like alkyl group which may have a substituent, or a chain-like alkenyl group which may have a substituent.]

(Cyclic Group which May have Substituent as R′²⁰¹)

The cyclic group as R′201 is preferably a cyclic hydrocarbon group, and the cyclic hydrocarbon group may be an aromatic hydrocarbon group or an aliphatic hydrocarbon group.

Examples of the aromatic hydrocarbon group as R′²⁰¹ include an aromatic hydrocarbon ring exemplified in the section of the divalent aromatic hydrocarbon group represented by Va¹ in Formula (a1-1) and an aryl group in which one hydrogen atom has been removed from an aromatic compound having two or more aromatic rings. Among these, a phenyl group or a naphthyl group is preferable.

Examples of the cyclic aliphatic hydrocarbon group as R′²⁰¹ include a group in which one hydrogen atom has been removed from the monocycloalkane or polycycloalkane described in the section of the divalent aliphatic hydrocarbon group represented by Va¹ in Formula (a1-1). Among these, an adamantyl group or a norbornyl group is preferable.

Further, the cyclic hydrocarbon group as R′²⁰¹ may contain a heteroatom such as a hetero ring. Specific examples thereof include lactone-containing cyclic groups represented by Formulae (a2-r-1) to (a2-r-7), the —SO₂-containing cyclic group represented by Formulae (a5-r-1) to (a5-r-4), and other heterocyclic groups represented by Formulae (r-hr-1) to (r-hr-16).

Examples of the substituent for the cyclic hydrocarbon group as R′²⁰¹ include an alkyl group, an alkoxy group, a halogen atom, a halogenated alkyl group, a hydroxyl group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom as the substituent include a fluorine atom, a chlorine atom, a bromine atom, and an iodine atom, and a fluorine atom is preferable.

Example of the above-described halogenated alkyl group as the substituent includes a group in which some or all hydrogen atoms in an alkyl group having 1 to 5 carbon atoms such as a methyl group, an ethyl group, a propyl group, an n-butyl group, or a tert-butyl group have been substituted with the above-described halogen atoms.

(Chain-Like Alkyl Group which May have Substituent as R′²⁰¹)

The chain-like alkyl group as R′²⁰¹ may be linear or branched.

The linear alkyl group preferably has 1 to 20 carbon atoms, more preferably 1 to 15 carbon atoms, and most preferably 1 to 10 carbon atoms. Specific examples thereof include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group.

The branched alkyl group preferably has 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

(Chain-Like Alkenyl Group which May have Substituent as R′²⁰¹)

Such a chain-like alkenyl group as R′²⁰¹ may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylpropenyl group and a 2-methylpropenyl group.

Among the examples, as the chain-like alkenyl group, a propenyl group is particularly preferable.

Specific suitable examples of the cation of the compound (b2) include cations represented by Formulae (ca-1-1) to (ca-1-43).

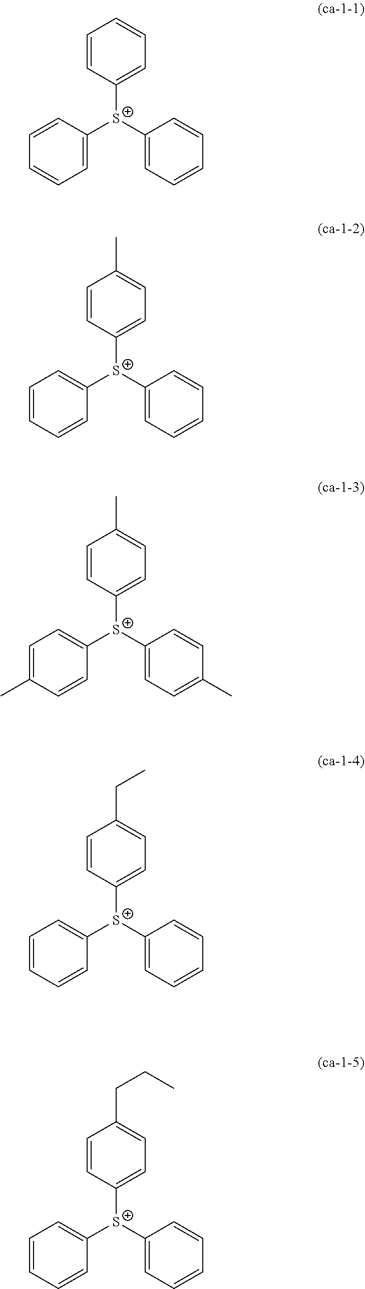

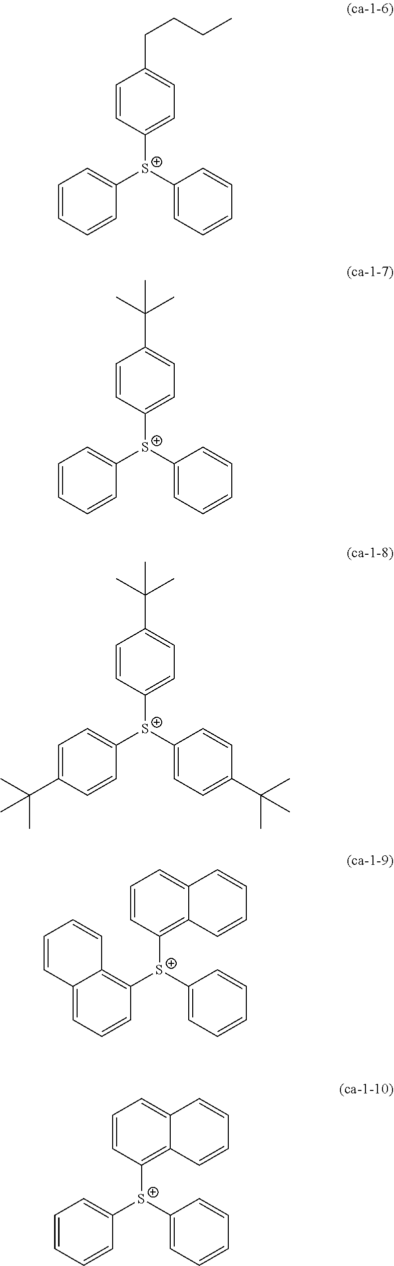 [SMILES: CCCCc1ccc([S+](c2ccccc2)c2ccccc2)cc1 ; CC(C)(C)c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; c1ccc([S+](c2cccc3ccccc23)c2cccc3ccccc23)cc1 ; c1ccc([S+](c2ccccc2)c2cccc3ccccc23)cc1]

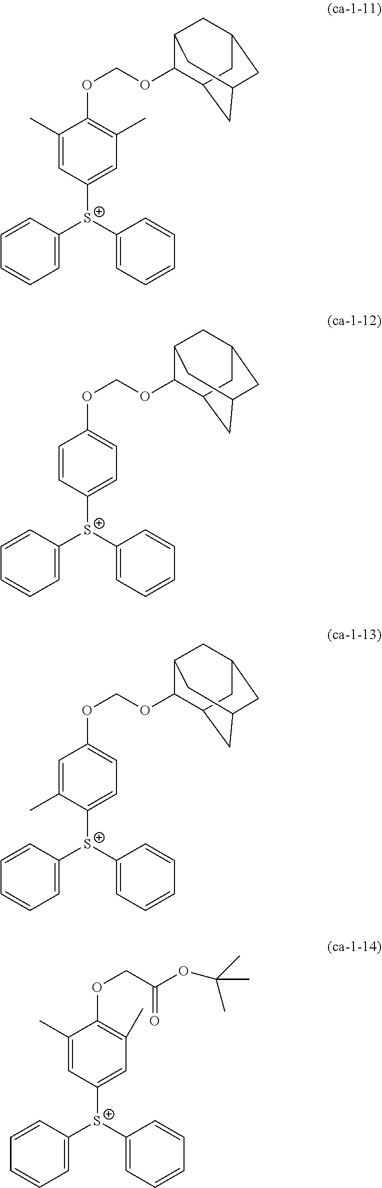 [SMILES: Cc1cc([S+](c2ccccc2)c2ccccc2)cc(C)c1OCOC1C2CC3CC(C2)CC1C3 ; c1ccc([S+](c2ccccc2)c2ccc(OCOC3C4CC5CC(C4)CC3C5)cc2)cc1 ; Cc1cc(OCOC2C3CC4CC(C3)CC2C4)ccc1[S+](c1ccccc1)c1ccccc1 ; Cc1cc([S+](c2ccccc2)c2ccccc2)cc(C)c1OCC(=O)OC(C)(C)C]

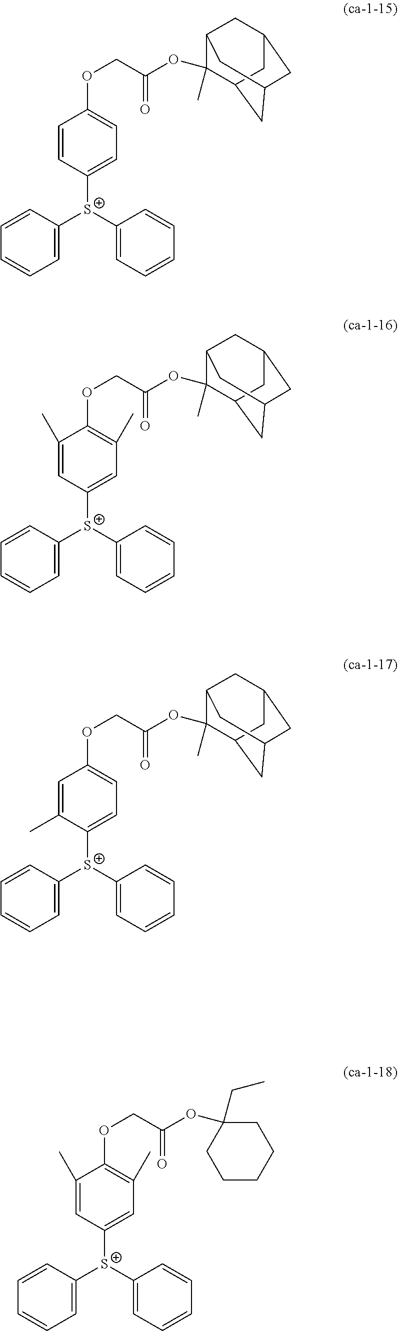 [SMILES: CC1(OC(=O)COc2ccc([S+](c3ccccc3)c3ccccc3)cc2)C2CC3CC(C2)CC1C3 ; Cc1cc([S+](c2ccccc2)c2ccccc2)cc(C)c1OCC(=O)OC1(C)C2CC3CC(C2)CC1C3 ; Cc1cc(OCC(=O)OC2(C)C3CC4CC(C3)CC2C4)ccc1[S+](c1ccccc1)c1ccccc1 ; CCC1(OC(=O)COc2c(C)cc([S+](c3ccccc3)c3ccccc3)cc2C)CCCCC1]

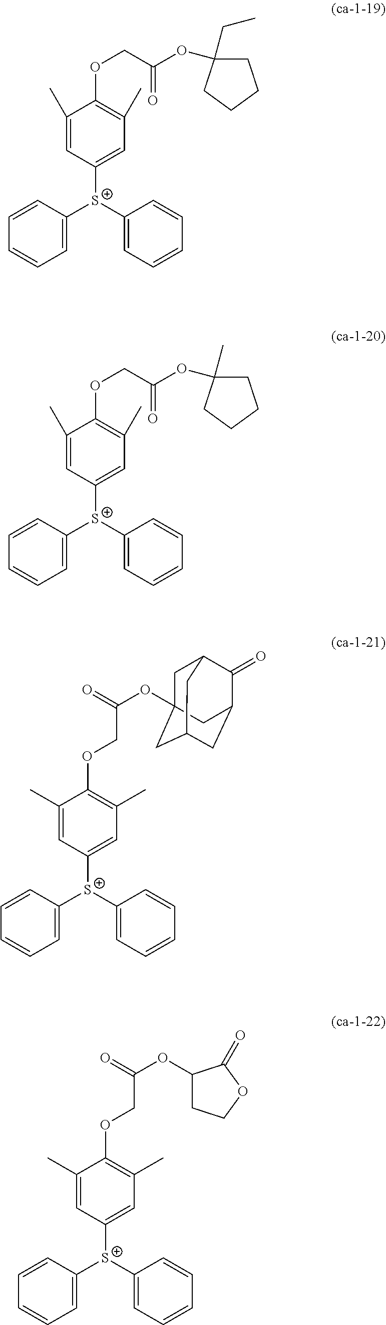 [SMILES: CCC1(OC(=O)COc2c(C)cc([S+](c3ccccc3)c3ccccc3)cc2C)CCCC1 ; Cc1cc([S+](c2ccccc2)c2ccccc2)cc(C)c1OCC(=O)OC1(C)CCCC1 ; Cc1cc([S+](c2ccccc2)c2ccccc2)cc(C)c1OCC(=O)OC12CC3CC(C1)C(=O)C(C3)C2 ; Cc1cc([S+](c2ccccc2)c2ccccc2)cc(C)c1OCC(=O)OC1CCOC1=O]

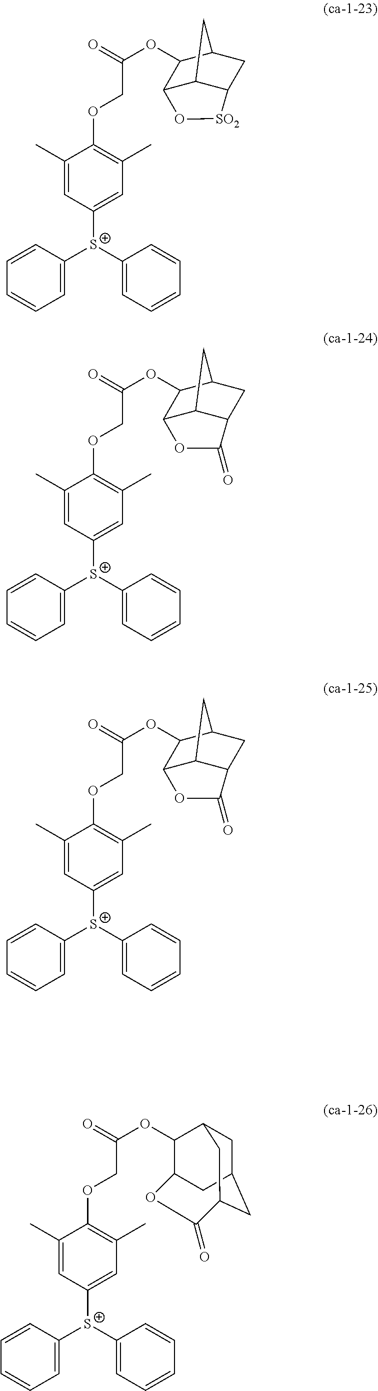 [SMILES: Cc1cc([S+](c2ccccc2)c2ccccc2)cc(C)c1OCC(=O)OC1C2CC3C1OS(=O)(=O)C3C2 ; Cc1cc([S+](c2ccccc2)c2ccccc2)cc(C)c1OCC(=O)OC1C2CC3C(=O)OC1C3C2 ; Cc1cc([S+](c2ccccc2)c2ccccc2)cc(C)c1OCC(=O)OC1C2CC3C(=O)OC1C3C2 ; Cc1cc([S+](c2ccccc2)c2ccccc2)cc(C)c1OCC(=O)OC1C2CC3CC(C2)C(=O)OC1C3]

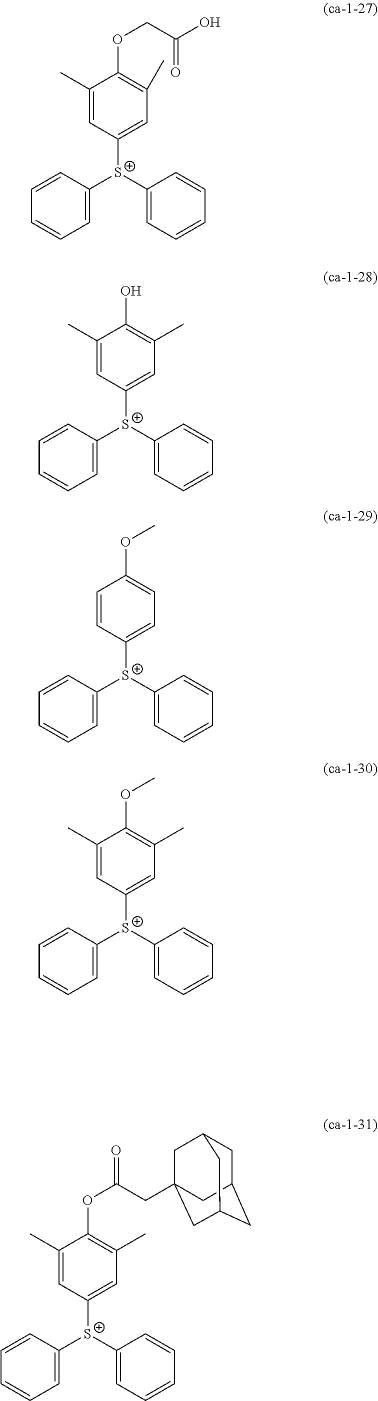 [SMILES: Cc1cc([S+](c2ccccc2)c2ccccc2)cc(C)c1OCC(=O)O ; Cc1cc([S+](c2ccccc2)c2ccccc2)cc(C)c1O ; COc1ccc([S+](c2ccccc2)c2ccccc2)cc1 ; COc1c(C)cc([S+](c2ccccc2)c2ccccc2)cc1C ; Cc1cc([S+](c2ccccc2)c2ccccc2)cc(C)c1OC(=O)CC12CC3CC(CC(C3)C1)C2]

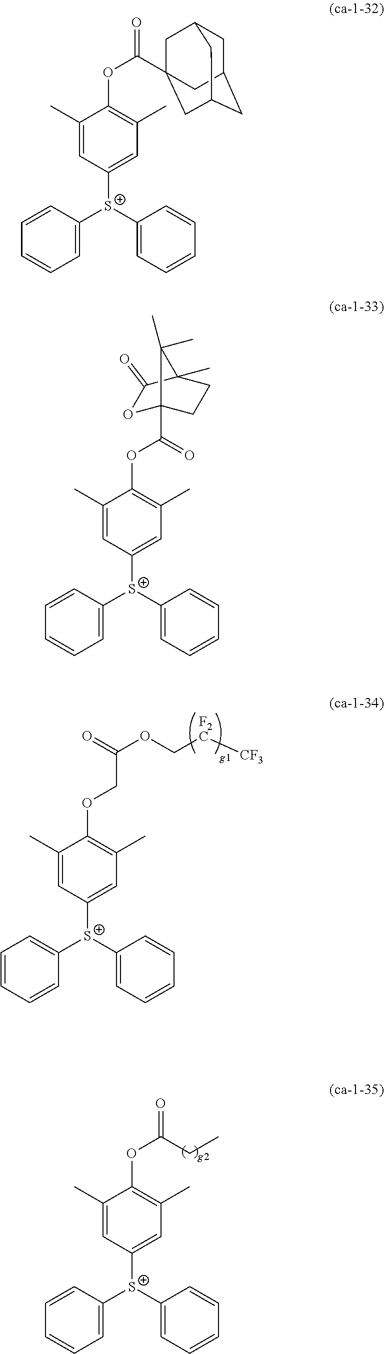

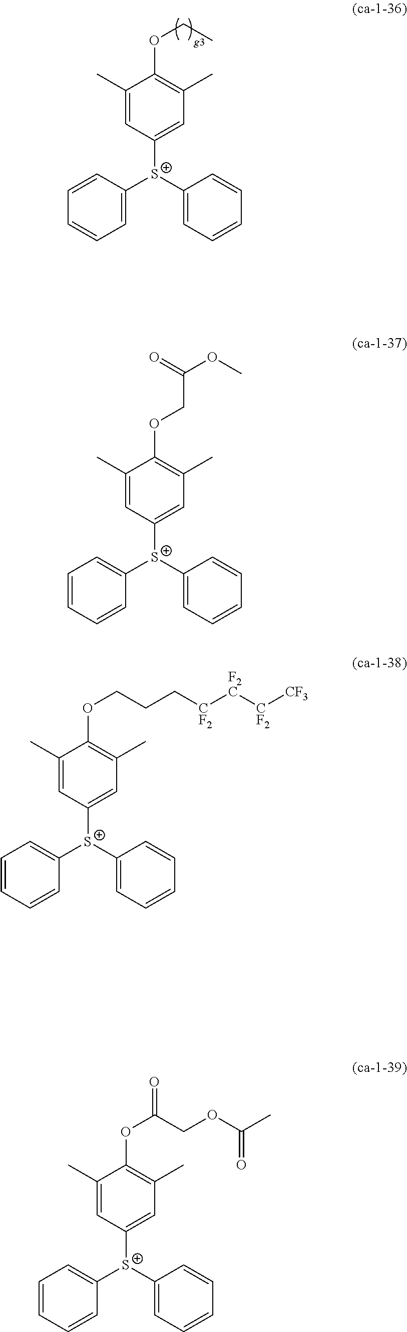

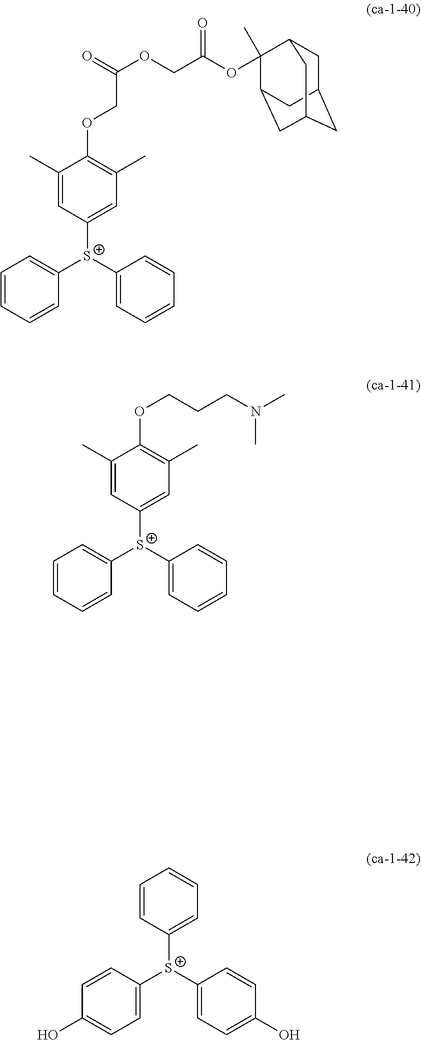 [SMILES: Cc1cc([S+](c2ccccc2)c2ccccc2)cc(C)c1OCC(=O)OCC(=O)OC1(C)C2CC3CC(C2)CC1C3 ; Cc1cc([S+](c2ccccc2)c2ccccc2)cc(C)c1OCCCN(C)C ; Oc1ccc([S+](c2ccccc2)c2ccc(O)cc2)cc1]

Anionic Moiety

In Formula (b2), Z⁻ represents a counter anion. The description of the counter anion represented by Z⁻ is the same as the description of the counter anion represented by X⁻ in Formula (b1).

The compound (b2) may be used alone or in combination of two or more kinds thereof.

The content of the compound (b2) is typically in a range of 1.0 to 10.0 parts by mass with respect to 100 parts by mass of the component (A).

In the compound (B), the ratio (mass ratio) of the blending amount between the compound (b1) and the compound (b2) ((b1):(b2)) is preferably in a range of 1:1 to 1:9, more preferably in a range of 1:1 to 1:6, and still more preferably in a range of 1:2 to 1:6.

The content of the component (B) in the resist composition according to the present invention is preferably in a range of 0.5 to 60 parts by mass, more preferably in a range of 1 to 50 parts by mass, and still more preferably in a range of 1 to 40 parts by mass with respect to 100 parts by mass of the component (A). In a case where the content of the component (B) is in the above-described range, pattern formation can be satisfactorily performed. Further, it is preferable that the content thereof be in the above-described range because a uniform solution is easily obtained at the time of dissolving each component of the resist composition in an organic solvent, and the storage stability of the resist composition becomes excellent.

As a combination of the compound (b1) and the compound (b2) in the acid generator component (B), a combination of the compound (b1) having a cationic moiety represented by Formula (b1)-1 and a compound (b2) having a cationic moiety represented by any of Formulae (ca-1-1) to (ca-1-7), (ca-1-27) to (ca-1-32), and (ca-1-42) is preferable.

<<Basic Compound Component; Component (D)>>

The resist composition of the present invention may further contain an acid diffusion control agent component (hereinafter, referred to as a “component (D)”) in addition to the component (A) and the component (B).

The component (D) acts as a quencher (an acid diffusion control agent) which traps the acid generated from the component (B) or the like upon exposure.

The component (D) according to the present invention may be a photodecomposable base (D1) (hereinafter, referred to as “component (D1)”) which is decomposed upon exposure and then loses the acid diffusion controllability or a nitrogen-containing organic compound (D2) (hereinafter, referred to as “component (D2)”) which does not correspond to the component (D1).

[Component (D1)]

In a case where a resist composition containing the component (D1) is obtained, the contrast between exposed portions and unexposed portions can be improved at the time of formation of a resist pattern.

The component (D1) is not particularly limited as long as decomposition is made upon exposure so that the acid diffusion controllability is lost, and one or more compounds selected from the group consisting of a compound represented by Formula (d1-1) (hereinafter, referred to as a “component (d1-1)”), a compound represented by Formula (d1-2) (hereinafter, referred to as “component (d1-2)”), and a compound represented by Formula (d1-3) (hereinafter, referred to as “component (d1-3)”) are preferable.

At exposed portions of the resist film, the components (d1-1) to (d1-3) are decomposed and then lose the acid diffusion controllability (basicity), and therefore the components (d1-1) to (d1-3) cannot function as a quencher, whereas at unexposed portions, the components (d1-1) to (d1-3) acts as a quencher.

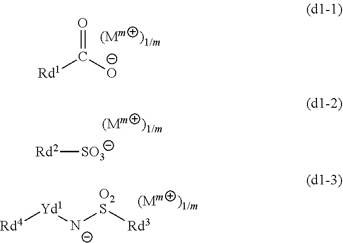

[In the formulae, Rd¹ to Rd⁴ represent a cyclic group which may have a substituent, a chain-like alkyl group which may have a substituent, or a chain-like alkenyl group which may have a substituent. Here, two or more fluorine atoms are not bonded to the carbon atom adjacent to the S atom as the Rd² in Formula (d1-2). Yd¹ represents a single bond or a divalent linking group. Each M^{m+} independently represents an m-valent organic cation.]

{Component (d1-1)}

Anionic Moiety

In Formula (d1-1), Rd¹ represents a cyclic group which may have a substituent, a chain-like alkyl group which may have a substituent or a chain-like alkenyl group which may have a substituent, and examples thereof are the same as those described above as R¹⁰¹.

Among these, as the group as Rd¹, an aromatic hydrocarbon group which may have a substituent, an aliphatic cyclic group which may have a substituent and a chain-like hydrocarbon group which may have a substituent are preferable. Examples of the substituent which may be included in these groups include a hydroxyl group, a fluorine atom, and a fluorinated alkyl group.

The aromatic hydrocarbon group is preferably a phenyl group or a naphthyl group.

Examples of the aliphatic cyclic group include groups in which one or more hydrogen atoms have been removed from a polycycloalkane such as adamantane, norbomane, isobomane, tricyclodecane or tetracyclododecane.

As the chain-like hydrocarbon group, a chain-like alkyl group is preferable. The number of carbon atoms in the chain-like alkyl group is preferably 1 to 10, and specific examples thereof include a linear alkyl group such as a methyl group, an ethyl group, a propyl group, a butyl group, a pentyl group, a hexyl group, a heptyl group, an octyl group, a nonyl group, or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group is a fluorinated alkyl group having a fluorine atom or a fluorinated alkyl group as a substituent, the fluorinated alkyl group preferably has 1 to 11 carbon atoms, more preferably 1 to 8 carbon atoms, and still more preferably 1 to 4 carbon atoms. The fluorinated alkyl group may contain an atom other than the fluorine atom. Examples of the atom other than the fluorine atom include an oxygen atom, a carbon atom, a hydrogen atom, a sulfur atom, and a nitrogen atom.

As Rd¹, a fluorinated alkyl group in which some or all hydrogen atoms constituting a linear alkyl group have been substituted with fluorine atom(s) is preferable, and a fluorinated alkyl group in which all of the hydrogen atoms constituting a linear alkyl group have been substituted with fluorine atoms (a linear perfluoroalkyl group) is preferable.

Specific preferred examples of the anionic moiety in the component (d1-1) are shown below.

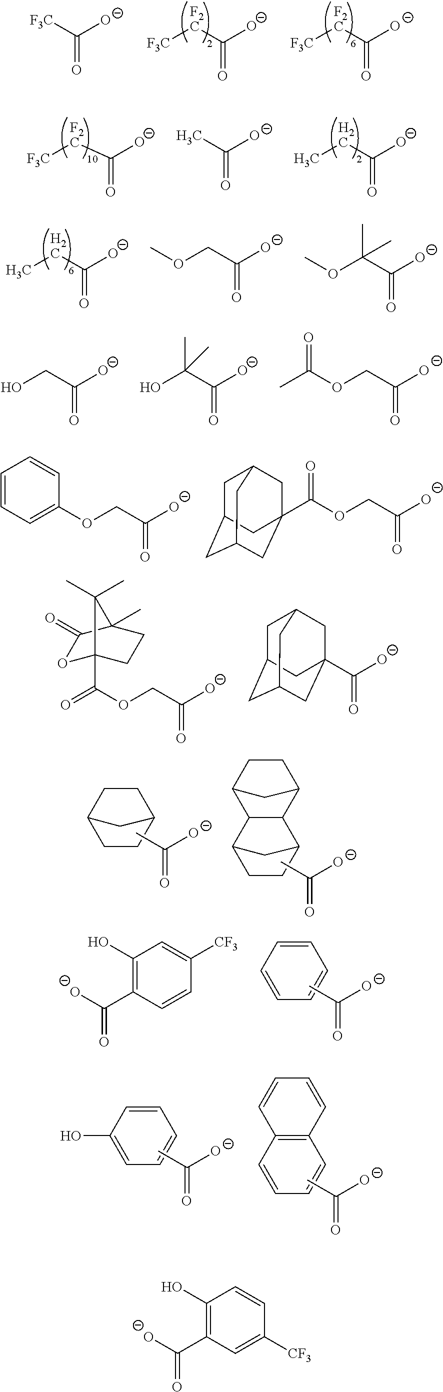

Cationic Moiety

In Formula (d1-1), M^{m+} represents an m-valent organic cation.

The organic cation as M^{m+} is not particularly limited, and examples thereof include the same cationic moieties of the compound (b2) represented by Formula (b2) as described above. Among these, cations represented by Formulae (ca-1-1) to (ca-1-42) are preferable.

The component (d1-1) may be used alone or in combination of two or more kinds thereof.

{Component (d1-2)}

Anionic Moiety

In Formula (d1-2), Rd² represents a cyclic group which may have a substituent, a chain-like alkyl group which may have a substituent, or a chain-like alkenyl group which may have a substituent, and the same groups as those described above as R¹⁰¹ are exemplified.

Here, two or more fluorine atoms are not bonded to the carbon atom adjacent to the S atom in Rd² (the carbon atom adjacent to the sulfur atom in Rd² is not substituted with fluorine atoms). As a result, the anion of the component (d1-2) becomes an appropriately weak acid anion, thereby improving the quenching ability of the component (D).

As Rd², an aliphatic cyclic group which may have a substituent is preferable. As the aliphatic cyclic group, a group in which one or more hydrogen atoms have been removed from adamantane, norbornane, isobomane, tricyclodecane, or tetracyclododecane (which may have a substituent) and a group in which one or more hydrogen atoms have been removed from camphor are more preferable.

The hydrocarbon group as Rd² may have a substituent. As the substituent, the same groups as the substituents which may be included in the hydrocarbon group (such as an aromatic hydrocarbon group or an aliphatic hydrocarbon group) as Rd¹ in Formula (d1-1) can be exemplified.

Specific preferred examples of the anionic moiety in the component (d1-2) are shown below.

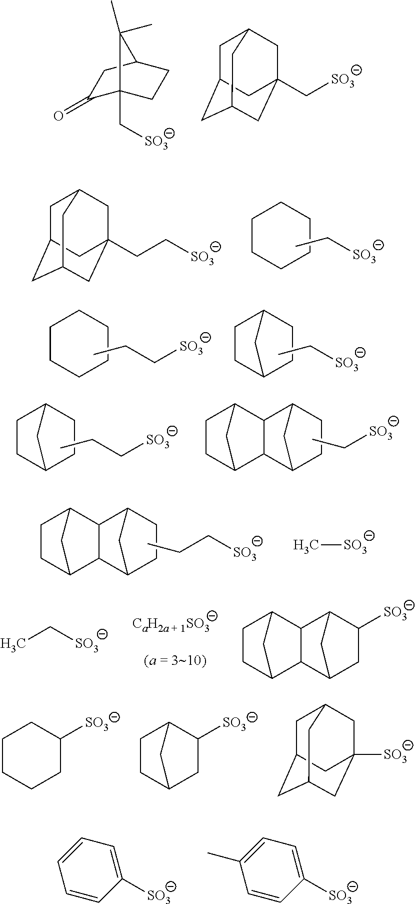

Cationic Moiety

In Formula (d1-2), M^{m+} represents an m-valent organic cation, and has the same definition as that for M^{m+} in the above-described Formula (d1-1).

The component (d1-2) may be used alone or in combination of two or more kinds thereof.

{Component (d1-3)}

Anionic Moiety

In Formula (d1-3), Rd³ represents a cyclic group which may have a substituent, a chain-like alkyl group which may have a substituent, or a chain-like alkenyl group which may have a substituent, and the same groups as those described above as R¹⁰¹ are exemplified, and a cyclic group containing a fluorine atom, a chain-like alkyl group, or a chain-like alkenyl group is preferable. Among these, a fluorinated alkyl group is preferable, and the same fluorinated alkyl groups as those described above as Rd¹ are more preferable.

In Formula (d1-3), Rd⁴ represents a cyclic group which may have a substituent, a chain-like alkyl group which may have a substituent or a chain-like alkenyl group which may have a substituent, and the same groups as those described above as R¹⁰¹ are exemplified.

Among these, an alkyl group which may have substituent, an alkoxy group which may have substituent, an alkenyl group which may have substituent, or a cyclic group which may have substituent is preferable.

The alkyl group as Rd⁴ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. Some hydrogen atoms in the alkyl group as Rd⁴ may be substituted with a hydroxyl group, a cyano group, or the like.

The alkoxy group as Rd⁴ is preferably an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among these, a methoxy group and an ethoxy group are preferable.

As the alkenyl group as Rd⁴, the same groups as those described above as R¹⁰¹ can be exemplified, and a vinyl group, a propenyl group (an allyl group), a 1-methylpropenyl group, and a 2-methylpropenyl group are preferable. These groups may have an alkyl group having 1 to 5 carbon atoms or a halogenated alkyl group having 1 to 5 carbon atoms as a substituent.

As the cyclic group as Rd⁴, the same groups as those described above as R¹⁰¹ in Formula (b-1) can be exemplified. Among these, as the cyclic group, an alicyclic group in which one or more hydrogen atoms have been removed from a cycloalkane such as cyclopentane, cyclohexane, adamantane, norbornane, isobomane, tricyclodecane or tetracyclododecane or an aromatic group such as a phenyl group or a naphthyl group is preferable. In a case where Rd⁴ represents an alicyclic group, the resist composition can be satisfactorily dissolved in an organic solvent, thereby improving the lithography characteristics. Further, in a case where Rd⁴ represents an aromatic group, the resist composition exhibits an excellent photoabsorption efficiency in a lithography process using EUV or the like as the exposure light source, thereby resulting in the improvement of the sensitivity and the lithography characteristics.

In Formula (d1-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent and a divalent linking group containing a heteroatom. Examples of the divalent linking groups are the same as those described in the section of the divalent linking groups as Ya²¹ in Formula (a2-1).

As Yd¹, a carbonyl group, an ester bond, an amide bond, an alkylene group, or a combination of these is preferable. As the alkylene group, a linear or branched alkylene group is more preferable, and a methylene group or an ethylene group is still more preferable.

Specific preferred examples of the anionic moiety in the component (d1-3) are shown below.

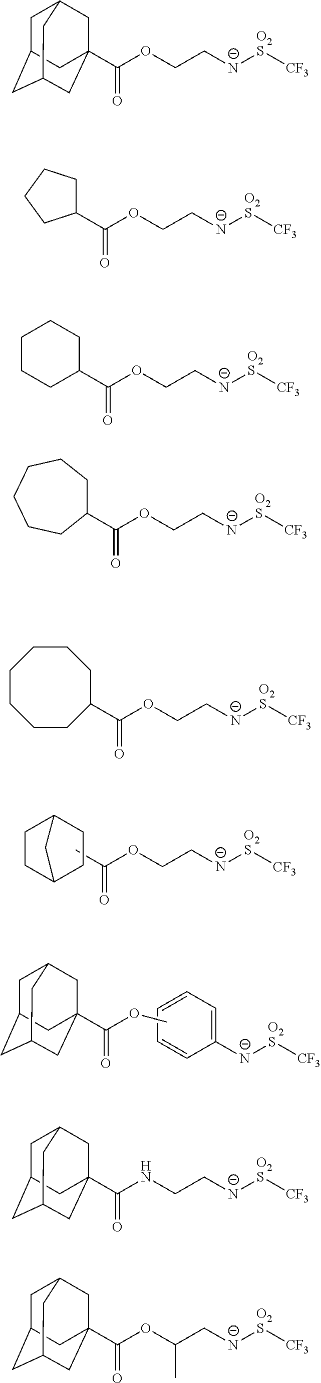

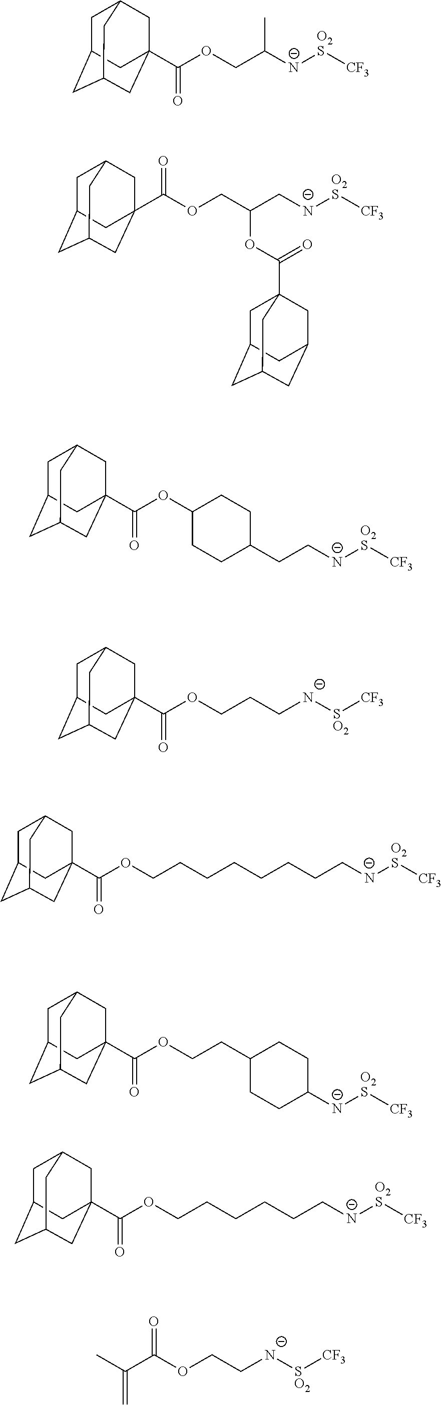

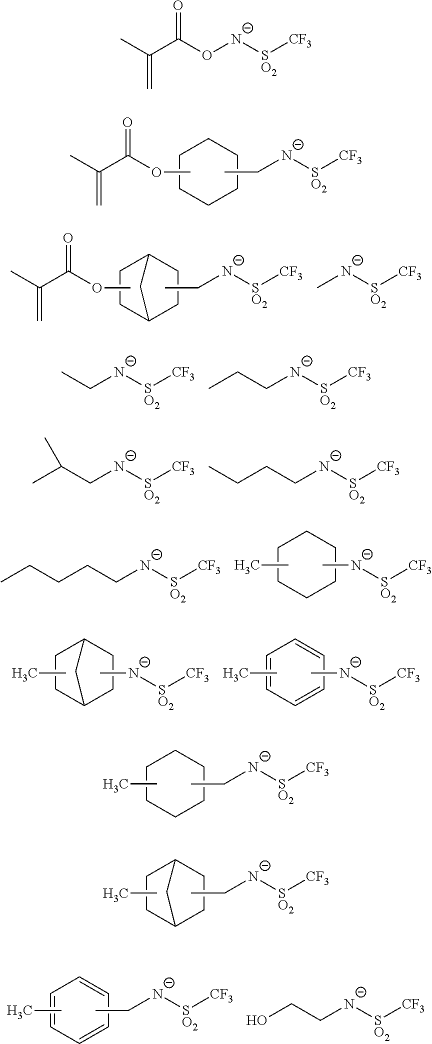

Cationic Moiety

In Formula (d1-3), M^{m+} represents an m-valent organic cation, and has the same definition as that for M^{m+} in Formula (d1-1).

The component (d1-3) may be used alone or in combination of two or more kinds thereof.

As the component (D1), only one of the above-described components (d1-1) to (d1-3) or a combination of two or more kinds thereof may be used.

The content of the component (D1) is preferably in a range of 0.5 to 10 parts by mass, more preferably in a range of 0.5 to 8 parts by mass, and still more preferably in a range of 1 to 8 parts by mass with respect to 100 parts by mass of the component (A).

In a case where the content of the component (D1) is greater than or equal to the lower limit of the above-described preferable range, excellent lithography characteristics and an excellent resist pattern shape can be more reliably obtained. Further, in a case where the content thereof is less than or equal to the upper limit of the above-described preferable range, the sensitivity can be maintained satisfactorily, and through-put also becomes excellent.

The production methods of the components (d1-1) and (d1-2) are not particularly limited, and the components (d1-1) and (d1-2) can be produced by known methods.

[Component (D2)]

The component (D) may contain a nitrogen-containing organic compound component (hereinafter, referred to as a “component (D2)”) that does not correspond to the component (D1).

The component (D2) is not particularly limited, as long as it functions as an acid diffusion control agent and does not correspond to the component (D1). As the component (D2), any of known compounds may be optionally used. Among these, an aliphatic amine is preferable, and a secondary aliphatic amine or tertiary aliphatic amine is particularly preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group having 12 or less carbon atoms (alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine and tri-n-octylamine are particularly preferable.

Examples of the cyclic amine include heterocyclic compounds containing a nitrogen atom as a heteroatom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanolamine triacetate, and triethanolamine triacetate is preferable.

Further, as the component (D2), an aromatic amine may be used.

Examples of aromatic amines include aniline, pyridine, 4-dimethylaminopyridine, pyrrole, indole, pyrazole, imidazole, and derivatives of these as well as diphenylamine, triphenylamine, tribenzylamine, 2,6-diisopropylaniline and N-tert-butoxycarbonylpyrrolidine.

The component (D2) may be used alone or in combination of two or more kinds thereof.

The content of the component (D2) is typically in a range of 0.01 to 5.0 parts by mass with respect to 100 parts by mass of the component (A). In a case where the content thereof is in the above-described range, the shape of the resist pattern and the post-exposure temporal stability are improved.

The component (D) may be used alone or in combination of two or more kinds thereof.

In a case where the resist composition of the present invention contains the component (D), the content of the component (D) is preferably in a range of 0.1 to 15 parts by mass, more preferably in a range of 0.3 to 12 parts by mass, and still more preferably in a range of 0.5 to 12 parts by mass with respect to 100 parts by mass of the component (A). In a case where the content thereof is greater than or equal to the above-described lower limit, the lithography characteristics such as LWR are further improved at the time of formation of the resist composition. Further, an excellent resist pattern shape can be obtained. In a case where the content thereof is less than or equal to the above-described upper limit, the sensitivity can be satisfactorily maintained, and the throughput is also excellent.

<<Specific Compound (E)>>

For the purpose of preventing any deterioration in sensitivity, and improving the resist pattern shape and the post-exposure temporal stability, the resist composition of the present embodiment may contain, as an optional component, at least one compound (E) (hereinafter referred to as the component (E)) selected from the group consisting of an organic carboxylic acid, or a phosphorus oxo acid and a derivative thereof.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid, and phosphinic acid. Among these, phosphonic acid is particularly preferable.

Examples of phosphorus oxo acid derivatives include esters in which a hydrogen atom in the above-described oxo acids is substituted with a hydrocarbon group. Examples of the hydrocarbon group include an alkyl group having 1 to 5 carbon atoms and an aryl group having 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate, and dibenzyl phosphonate.

Examples of phosphinic acid derivatives include phosphinic acid esters and phenylphosphinic acid.

The component (E) may be used alone or in combination of two or more kinds thereof.

The content of the component (E) is typically in a range of 0.01 to 5.0 parts by mass with respect to 100 parts by mass of the component (A).

<<Component (F)>>

In the present embodiment, the resist composition may further include a fluorine additive (hereinafter, referred to as “component (F)”) for imparting water repellency to the resist film.

As the component (F), a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be exemplified.

Specific examples of the component (F) include polymers having a constitutional unit (f1) represented by Formula (f1-1) shown below. As the polymer, a polymer (homopolymer) formed of only a constitutional unit (f1) represented by Formula (f1-1); a copolymer of the constitutional unit (f1) represented by Formula (f1-1) and the constitutional unit (a1); and a copolymer of the constitutional unit (f1) represented by Formula (f1-1), a constitutional unit derived from acrylic acid or methacrylic acid, and the above-described constitutional unit (a1) are preferable. Examples of the constitutional unit (a1) to be copolymerized with the constitutional unit (f1) represented by Formula (f1-1) include a constitutional unit derived from 1-ethyl-1-cyclooctyl (meth)acrylate and a constitutional unit represented by Formula (a1-2-01).

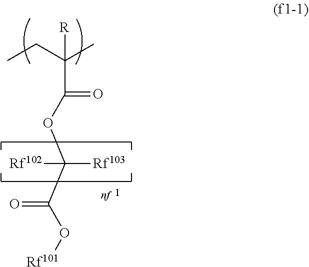

[In Formula (f1-1), R represents a hydrogen atom, an alkyl group having 1 to 5 carbon atoms, or a halogenated alkyl group having 1 to 5 carbon atoms; Rf¹⁰² and Rf¹⁰³ each independently represents a hydrogen atom, a halogen atom, an alkyl group having 1 to 5 carbon atoms, or a halogenated alkyl group having 1 to 5 carbon atoms. Rf¹⁰² and Rf¹⁰³ may be the same as or different from each other. nf¹ represents an integer of 1 to 5, and Rf¹⁰¹ represents an organic group containing a fluorine atom.]

In Formula (f1-1), R has the same definition as that described above. R bonded to the carbon atom at the α-position has the same definition as described above. As R, a hydrogen atom or a methyl group is preferable.

In Formula (f1-1), examples of the halogen atom as Rf¹⁰² and Rf¹⁰³ include a fluorine atom, a chlorine atom, a bromine atom, and an iodine atom, and a fluorine atom is particularly preferable. Examples of the alkyl group having 1 to 5 carbon atoms as Rf¹⁰² and Rf¹⁰³ include those described above as the alkyl group having 1 to 5 carbon atoms as R, and a methyl group or an ethyl group is preferable. Specific examples of the halogenated alkyl group having 1 to 5 carbon atoms as Rf¹⁰² and Rf¹⁰³ include groups in which some or all hydrogen atoms of the above-described alkyl groups of 1 to 5 carbon atoms have been substituted with halogen atoms.

Examples of the halogen atom include a fluorine atom, a chlorine atom, a bromine atom, and an iodine atom, and a fluorine atom is particularly preferable. Among these examples, as Rf¹⁰² and Rf¹⁰³, a hydrogen atom, a fluorine atom, or an alkyl group having 1 to 5 carbon atoms is preferable, and a hydrogen atom, a fluorine atom, a methyl group, or an ethyl group is more preferable.

In Formula (f1-1), nf¹ represents an integer of 1 to 5, preferably an integer of 1 to 3, and more preferably an integer of 1 or 2.

In Formula (f1-1), Rf¹⁰¹ represents an organic group containing a fluorine atom, and is preferably a hydrocarbon group containing a fluorine atom.

The hydrocarbon group containing a fluorine atom may be linear, branched, or cyclic, and preferably has 1 to 20 carbon atoms, more preferably 1 to 15 carbon atoms, and particularly preferably 1 to 10 carbon atoms.

Further, in the hydrocarbon group having fluorine atoms, it is preferable that 25% or more hydrogen atoms in the hydrocarbon group be fluorinated, more preferable that 50% or more hydrogen atoms therein be fluorinated, and particularly preferable that 60% or more hydrogen atoms therein be fluorinated from the viewpoint of improving the hydrophobicity of the resist film during immersion exposure.

Among these, as Rf¹⁰¹, a fluorinated hydrocarbon group having 1 to 5 carbon atoms is preferable, and a trifluoromethyl group, and —CF₃, —CH₂—CF₃, —CH₂—CF₂—CF₃, —CH(CF₃)₂, —CH₂—CH₂—CF₃, —CH₂—CH₂—CF₂—CF₂—CF₂—CF₃ are most preferable.

The weight-average molecular weight (Mw) (in terms of polystyrene determined by gel permeation chromatography) of the component (F) is preferably in a range of 1,000 to 50,000, more preferably in a range of 5,000 to 40,000, and most preferably in a range of 10,000 to 30,000. In a case where the weight-average molecular weight thereof is less than or equal to the upper limit of the above-described range, the resist composition exhibits the solubility in a resist solvent enough to be used as a resist. Further, in a case where the weight-average molecular weight is greater than or equal to the lower limit of the above-described range, dry etching resistance and the cross-sectional shape of the resist pattern become excellent.

Further, the dispersity (Mw/Mn) of the component (F) is preferably in a range of 1.0 to 5.0, more preferably in a range of 1.0 to 3.0, and most preferably in a range of 1.2 to 2.5.

The component (F) may be used alone or in combination of two or more kinds thereof.

In a case where the resist composition contains the component (F), the content of the component (F) is typically in a range of 0.5 to 10 parts by mass, with respect to 100 parts by mass of the component (A).

In the present embodiment, as desired, miscible additives such as additive resins, dissolution inhibitors, plasticizers, stabilizers, colorants, halation prevention agents, and dyes for improving the performance of the resist film can be added to the resist composition.

<<Component (S)>>

In the present embodiment, the resist composition can be produced by dissolving the materials in an organic solvent (hereinafter, referred to as a “component (S)”).

The component (S) may be any organic solvent which can dissolve the respective components to be used to obtain a uniform solution, and one or two or more optional organic solvents can be appropriately selected from those which have been known as solvents for a chemically amplified resist composition and then used.

Examples thereof include lactones such as γ-butyrolactone; ketones such as acetone, methyl ethyl ketone (MEK), cyclohexanone, methyl-n-pentyl ketone (2-heptanone), and methyl isopentyl ketone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (such as monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and dimethylsulfoxide (DMSO).

These organic solvents may be used alone or in the form of a mixed solvent of two or more kinds thereof.

Among these, PGMEA, PGME, γ-butyrolactone, and EL are preferable.

Further, among the mixed solvents, a mixed solvent obtained by mixing PGMEA with a polar solvent is preferable. The mixing ratio (mass ratio) of the mixed solvent can be appropriately determined, taking into consideration the compatibility of the PGMEA with the polar solvent, but is preferably in the range of 1:9 to 9:1 and more preferably in a range of 2:8 to 8:2.

More specifically, in a case where EL or cyclohexanone is mixed as the polar solvent, the PGMEA:EL or cyclohexanone mass ratio is preferably in a range of 1:9 to 9:1 and more preferably in a range of 2:8 to 8:2. Alternatively, in a case where PGME is mixed as the polar solvent, the PGMEA:PGME mass ratio is preferably in a range of 1:9 to 9:1, more preferably in a range of 2:8 to 8:2, and still more preferably in a range of 3:7 to 7:3.

Further, as the component (S), a mixed solvent of at least one of PGMEA and EL with γ-butyrolactone is also preferable. The mass ratio (former:latter) of such a mixed solvent is preferably in a range of 70:30 to 95:5.

The amount of the component (S) to be used is not particularly limited and is appropriately set depending on the thickness of the coated film at a concentration adjusted such that a substrate or the like can be coated. Typically, the component (S) is used in an amount such that the solid content of the resist composition becomes in the range of 1% to 20% by mass and preferably in a range of 2% to 15% by mass.

The resist composition of the present embodiment contains an acid generator containing the compound (b1) and the compound (b2).

The compound (b1) has a high solubility in a developing solution and is capable of improving the lithography characteristics. However, the compound (b1) tends to have a low photoresponsivity. On the contrary, the compound (b2) has a high photoresponsivity. Therefore, the reaction occurs in the compound (b2) due to even weak light so that an acid can be generated.

A resist pattern is formed by exposing the resist film formed on the substrate using the resist composition and developing the exposed resist film. In the exposure step of forming a resist pattern, the intensity of light to be radiated is not uniform, and a place where the light intensity is high and a place where the light intensity is low are generated.

Even though the resist composition of the present embodiment has a low photoresponsivity, the resist composition contains the compound (b1) having a high solubility in a developing solution and the compound (b2) having a high photoresponsivity. Accordingly, the compound (b1) and the compound (b2) can act to generate an acid in the place where the light intensity is high and mainly the compound (b2) can act to generate an acid in the place where the light intensity is low. In other words, it is assumed that in a case where the resist pattern is formed using the resist composition of the present embodiment, a sufficient amount of acids for forming the resist pattern can be generated even though the light intensity during the exposure is uneven. Further, since the solubility of the compound (b1) in a developing solution is high as described above, the lithography characteristics such as the sensitivity can be improved.

<Resist Pattern Forming Method>

In the present invention, the resist pattern forming method includes a step of forming a resist film on a support using the resist composition described above; a step of exposing the resist film; and a step of developing the resist film to form a resist pattern.

For example, the resist pattern forming method can be carried out in the following manner.

First, a support is coated with the above-described resist composition using a spinner or the like, and a bake treatment (post apply bake (PAB)) is performed at a temperature of 80 to 150° C. for 40 to 120 seconds and preferably 60 to 90 seconds, to form a resist film.

Next, the resist film was exposed through a mask (mask pattern) on which a predetermined pattern is formed or selectively exposed to electron beams in a manner of direct irradiation with the electron beams for drawing without using a mask pattern, using an exposure device such as an ArF exposure device, an electron beam drawing device, or an EUV exposure device. Thereafter, a bake (post-exposure bake (PEB)) treatment is performed under a temperature condition of 80 to 150° C. for 40 to 120 seconds and preferably 60 to 90 seconds.

Next, the resist film is subjected to a development treatment.

The development treatment is performed using an alkali developing solution in a case of an alkali development process, and a developing solution containing an organic solvent (organic developing solution) in a case of a solvent development process.

After the development treatment, it is preferable to perform a rinse treatment. The rinse treatment is preferably performed using pure water in a case of an alkali development process, and a rinse solution containing an organic solvent in a case of a solvent development process.

In a case of a solvent development process, after the development treatment or the rinse treatment, a treatment of removing the developing solution or the rinse liquid remaining on the pattern using a supercritical fluid may be performed.

After the development treatment or the rinse treatment, drying is performed. Depending on the circumstances, the bake treatment (post bake) can be performed after the development treatment. In this manner, a resist pattern can be obtained.

The development treatment of the present invention may be an alkali development process or a solvent development process.

The support is not specifically limited and a known support of the related art can be used. For example, substrates for electronic components, and such substrates having wiring patterns formed thereon can be used. Specific examples of the material of the substrate include metals such as silicon wafer, copper, chromium, iron, and aluminum; and glass. Suitable materials for the wiring pattern include copper, aluminum, nickel, and gold.

Further, as the support, any one of the above-described supports provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to perform patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be performed using radiation such as an ArF excimer laser, a KrF excimer laser, an F2 excimer laser, extreme ultraviolet rays (EUV), vacuum ultraviolet rays (VUV), electron beams (EB), X-rays, and soft X-rays. The resist composition of the present invention is useful for a KrF excimer laser, an ArF excimer laser, EB, and EUV.

The exposure of the resist film can be a general exposure (dry exposure) performed in air or an inert gas such as nitrogen, or immersion exposure (liquid immersion lithography).

In immersion lithography, the region between the resist film and the lens at the lowermost point of the exposure device is pre-filled with a solvent (immersion medium) that has a larger refractive index than the refractive index of air, and the exposure (immersion exposure) is performed in this state.

The immersion medium preferably exhibits a refractive index larger than the refractive index of air but smaller than the refractive index of the resist film to be exposed. The refractive index of the immersion medium is not particularly limited as long as it satisfies the above-described requirements.

Examples of this immersion medium which exhibits a refractive index that is larger than the refractive index of air but smaller than the refractive index of the resist film include water, fluorine-based inert liquids, silicon-based solvents, and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, and the boiling point is preferably in a range of 70° to 180° C. and more preferably in a range of 80° to 160° C. A fluorine-based inert liquid having a boiling point in the above-described range is advantageous in that the removal of the immersion medium after the exposure can be performed by a simple method.

As a fluorine-based inert liquid, a perfluoroalkyl compound in which all of the hydrogen atoms of the alkyl group are substituted with fluorine atoms is particularly preferable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point of 102° C.), and an example of a suitable perfluoroalkylamine compound is perfluorotributylamine (boiling point of 174° C.).

As the immersion medium, water is preferable in terms of cost, safety, environment and versatility.

As an example of the alkali developing solution used in the development treatment of the alkali development process, a 0.1 to 10 mass % tetramethylammonium hydroxide (TMAH) aqueous solution can be exemplified.

As the organic solvent contained in the organic developing solution used in the development treatment of the solvent development process, a solvent which is capable of dissolving the component (A) (the component (A) before being exposed) may be used and can be appropriately selected from known organic solvents. Specific examples of the organic solvent include polar solvents such as ketone solvents, ester solvents, alcohol solvents, amide solvents, and ether solvents, and hydrocarbon solvents.

As necessary, known additives can be blended into the organic developing solution. Examples of the additive include surfactants. The surfactant is not particularly limited, and for example, an ionic or non-ionic fluorine and/or silicon surfactant can be used.

In a case where a surfactant is blended, the amount thereof to be blended is typically in a range of 0.001% to 5% by mass, preferably in a range of 0.005% to 2% by mass, and more preferably in a range of 0.01% to 0.5% by mass with respect to the total amount of the organic developing solution.

The development treatment can be performed by a known developing method. Examples thereof include a method in which a support is immersed in a developing solution for a predetermined time (a dip method), a method in which a developing solution is cast up on the surface of a support by surface tension and maintained for a predetermined period (a puddle method), a method in which a developing solution is sprayed onto the surface of a support (spray method), and a method in which a developing solution is continuously ejected from a developing solution ejecting nozzle while scanning at a constant rate to apply the developing solution to a support while rotating the support at a constant rate (dynamic dispense method).

The rinse treatment using a rinse liquid (washing treatment) can be performed by a known rinse method. Examples of the rinse method include a method of continuously ejecting the rinse liquid to a support rotating at a constant rate (rotational coating method), a method of immersing a support in the rinse liquid for a predetermined time (dip method), and a method of spraying the rinse liquid onto the surface of a support (spray method).

### EXAMPLES

Hereinafter, the present invention will be described in detail based on examples, but the present invention is not limited to the following examples.

[Preparation of Resist Composition]

Respective components listed in Tables 1 and 2 were mixed to prepare resist compositions of Examples 1 to 12 and Comparative Examples 1 to 3.

TABLE 1

| | | Component (B) | | Component | Component | Component | Component (S) | |
|---|---|---|---|---|---|---|---|---|
| | Component (A) | (B1) | (B2) | (D) | (E) | (F) | (S)-1 | (S)-2 |
| Example 1 | (A)-1 | (B1)-1 | (B2)-1 | (D)-1 | (E)-1 | (F)-1 | (S)-1 | (S)-2 |
| | [100] | [1] | [6] | [5] | [0.2] | [3] | [3800] | [100] |
| Example 2 | (A)-1 | (B1)-1 | (B2)-1 | (D)-1 | (E)-1 | (F)-1 | (S)-1 | (S)-2 |
| | [100] | [1.5] | [6] | [5] | [0.2] | [3] | [3800] | [100] |
| Example 3 | (A)-1 | (B1)-1 | (B2)-1 | (D)-1 | (E)-1 | (F)-1 | (S)-1 | (S)-2 |
| | [100] | [3] | [6] | [5] | [0.2] | [3] | [3800] | [100] |
| Example 4 | (A)-1 | (B1)-1 | (B2)-1 | (D)-1 | (E)-1 | (F)-1 | (S)-1 | (S)-2 |
| | [100] | [6] | [6] | [5] | [0.2] | [3] | [3800] | [100] |
| Example 5 | (A)-1 | (B1)-1 | (B2)-2 | (D)-1 | (E)-1 | (F)-1 | (S)-1 | (S)-2 |
| | [100] | [3] | [6] | [5] | [0.2] | [3] | [3800] | [100] |
| Example 6 | (A)-1 | (B1)-1 | (B2)-3 | (D)-1 | (E)-1 | (F)-1 | (S)-1 | (S)-2 |
| | [100] | [3] | [6] | [5] | [0.2] | [3] | [3800] | [100] |
| Example 7 | (A)-1 | (B1)-1 | (B2)-4 | (D)-1 | (E)-1 | (F)-1 | (S)-1 | (S)-2 |
| | [100] | [3] | [6] | [5] | [0.2] | [3] | [3800] | [100] |
| Example 8 | (A)-1 | (B1)-1 | (B2)-5 | (D)-1 | (E)-1 | (F)-1 | (S)-1 | (S)-2 |
| | [100] | [3] | [6] | [5] | [0.2] | [3] | [3800] | [100] |
| Example 9 | (A)-1 | (B1)-1 | (B2)-6 | (D)-1 | (E)-1 | (F)-1 | (S)-1 | (S)-2 |
| | [100] | [3] | [6] | [5] | [0.2] | [3] | [3800] | [100] |
| Example 10 | (A)-1 | (B1)-2 | (B2)-1 | (D)-1 | (E)-1 | (F)-1 | (S)-1 | (S)-2 |
| | [100] | [3] | [6] | [5] | [0.2] | [3] | [3800] | [100] |
| Example 11 | (A)-1 | (B1)-3 | (B2)-1 | (D)-1 | (E)-1 | (F)-1 | (S)-1 | (S)-2 |
| | [100] | [3] | [6] | [5] | [0.2] | [3] | [3800] | [100] |
| Example 12 | (A)-1 | (B1)-4 | (B2)-1 | (D)-1 | (E)-1 | (F)-1 | (S)-1 | (S)-2 |
| | [100] | [3] | [6] | [5] | [0.2] | [3] | [3800] | [100] |

TABLE 2

| | | Component (B) | | Component | Component | Component | Component (S) | |
|---|---|---|---|---|---|---|---|---|
| | Component ( A) | (B1) | (B2) | (D) | (E) | (F) | (S)-1 | (S)-2 |
| Comparative | (A)-1 | (B1)-1 | — | (D)-1 | (E)-1 | (F)-1 | (S)-1 | (S)-2 |
| Example 1 | [100] | [6] | | [5] | [0.2] | [3] | [3800] | [100] |
| Comparative | (A)-1 | (B2)-1 | (B2)-2 | (D)-1 | (E)-1 | (F)-1 | (S)-1 | (S)-2 |
| Example 2 | [100] | [3] | [6] | [5] | [0.2] | [3] | [3800] | [100] |
| Comparative | (A)-1 | (B1)-5 | (B2)-7 | (D)-1 | (E)-1 | (F)-1 | (S)-1 | (S)-2 |
| Example 3 | [100] | [3] | [6] | [5] | [0.2] | [3] | [3800] | [100] |

In Tables 1 and 2, each symbol indicates the following material. The numerical values in the parentheses are blending amounts (parts by mass).
(A)-1: the following polymer compound (A)-1, Mw: 9000, Mw/Mn: 1.64
(B1)-1 to (B1)-5: the following compounds (B1)-1 to (B1)-5
(B2)-1 to (B2)-7: the following compounds (B2)-1 to (B2)-7
(E)-1: salicylic acid
(F)-1: the following polymer compound (F)-1, (molar ratio: 1/m=77/23), Mw: 23100, Mw/Mn: 1.78
(S)-1: mixed solvent containing PGMEA, PGME, and cyclohexanone (mass ratio of 45/30/25)
(S)-2: γ-butyrolactone

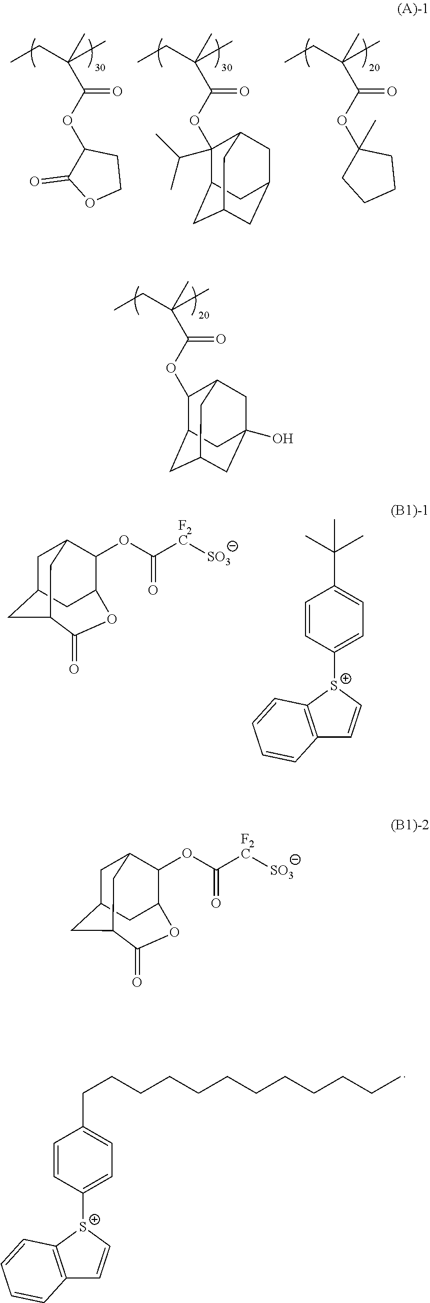

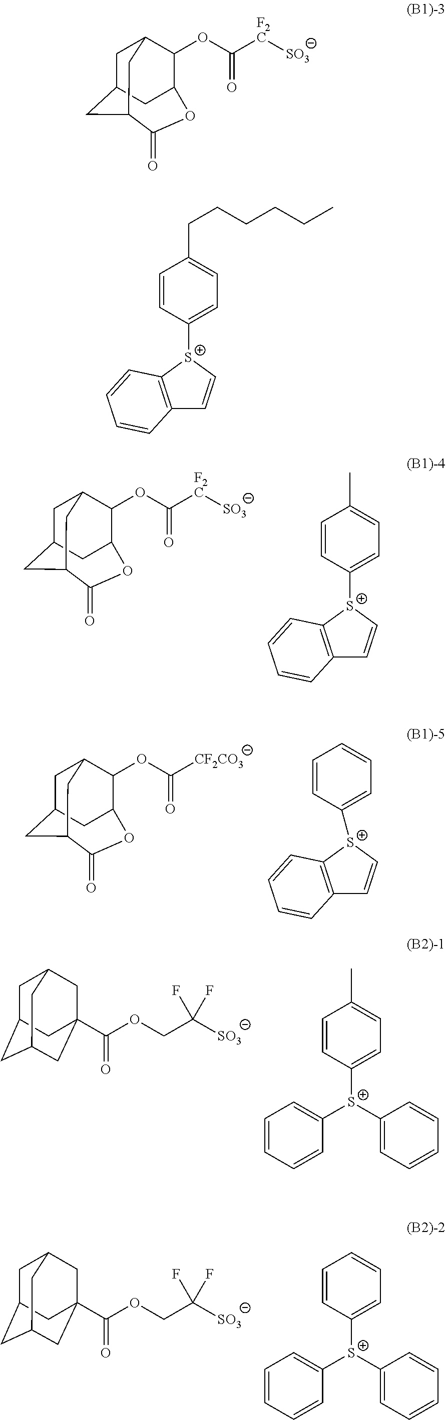

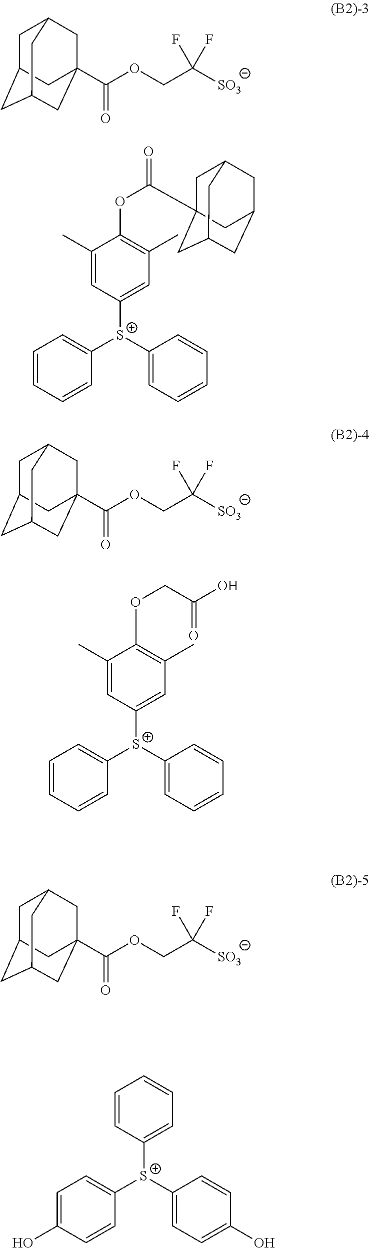

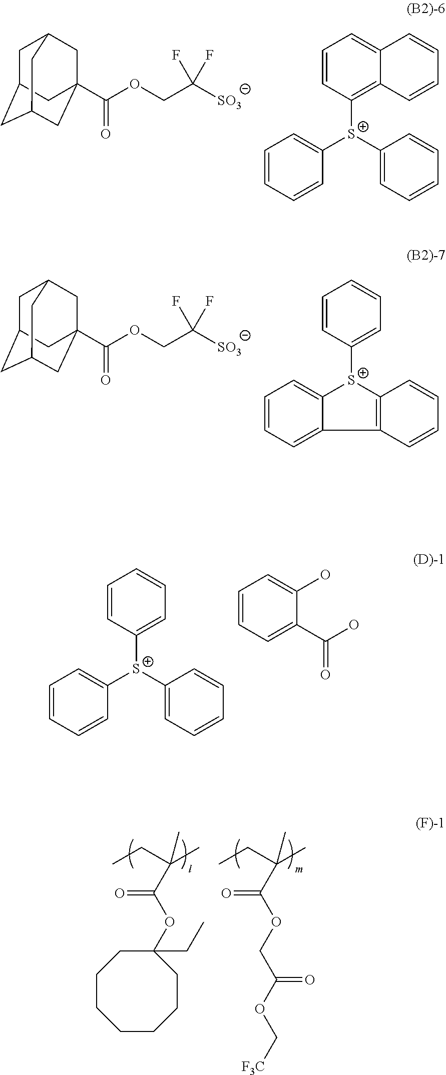

[Formation of Resist Pattern]

A 12-inch silicon wafer was coated with an organic antireflection film composition “ARC95” (trade name, manufactured by Brewer Science, Inc.) using a spinner, baked at 205° C. for 60 seconds on a hot plate, and dried, thereby forming an organic antireflection film having a film thickness of 90 nm.

Next, the organic antireflection film was coated with each of the resist compositions of Examples 1 to 12 and Comparative Examples 1 to 3 using a spinner, a prebake (PAB) treatment was performed on the hot plate under conditions of a temperature of 110° C. for 60 seconds, and the film was dried, thereby forming a resist film having a film thickness of 120 nm.

Next, the resist film was selectively exposed to an ArF excimer laser (193 nm) through a mask pattern (6% halftone) using an exposure device NSR-S609B (manufactured by Nikon Corporation, NA=1.07, annular, 0.78/0.97, w/o P).

Thereafter, the resist film was subjected to a post-exposure bake (PEB (° C.)) treatment at 85° C. for 60 seconds.

Next, solvent development was performed for 13 seconds using butyl acetate.

As the result, a contact hole pattern (hereinafter, referred to as a “CH pattern”) was formed.

CH pattern: a pitch of 110 nm, a hole diameter of 50 nm, and a mask size of 55 nm

[Evaluation of Resist Pattern]

(Evaluation of Optimum Exposure Amount (Eop))

An optimum exposure amount Eop (μC/cm²) at which a CH pattern with a target size was formed was acquired according to the resist pattern forming method described above. The results are listed in Table 3 in the columns of “Eop (μC/cm²)”.

(Evaluation of in-Plane Uniformity of Pattern Dimension (CDU))

The in-plane uniformity (CDU) of the pattern dimension of the formed hole pattern was evaluated.

100 holes in the hole pattern were observed from above the CH pattern using a length measurement SEM (scanning electron microscope, acceleration voltage of 300 V, trade name: S-9380, manufactured by Hitachi High-Technologies Corporation), and the hole diameter (CD; nm) of each hole was measured. Three times (3σ) (unit: nm) the standard deviation (a) calculated from the measurement results was acquired. The results thereof are listed in Table 3 in the columns of “CDU (nm)”.

As the value of 3a acquired in the above-described manner is decreased, this indicates that dimension (CD) uniformity in the plurality of holes formed in the resist film is high.

TABLE 3

| | Eop | CDU |
|---|---|---|
| | (μC/cm²) | (nm) |
| Example 1 | 18 | 4.8 |
| Example 2 | 20 | 4.6 |
| Example 3 | 23 | 4.5 |
| Example 4 | 27 | 4.9 |
| Example 5 | 21 | 4.7 |
| Example 6 | 25 | 5.1 |
| Example 7 | 27 | 5.2 |
| Example 8 | 31 | 5.0 |
| Example 9 | 30 | 4.9 |
| Example 10 | 22 | 4.6 |
| Example 11 | 21 | 4.8 |
| Example 12 | 21 | 5.2 |
| Comparative | 63 | 4.6 |
| Example 1 | | |
| Comparative | 18 | 6.2 |
| Example 2 | | |
| Comparative | 51 | 5.8 |
| Example 3 | | |

Based on the results listed in Table 3, it was confirmed that the resist patterns formed using the resist compositions of Examples 1 to 12 had a smaller Eop value, excellent sensitivity, and hole patterns formed with a uniform dimension, compared to a case where the resist compositions of Comparative Examples 1 to 3 were used.

1. A resist composition which generates an acid upon exposure, whose solubility in a developing solution is changed due to an action of the acid, the resist composition comprising:
a base material component (A) whose solubility in the developing solution is changed due to the action of the acid; and
an acid generator component (B) which generates the acid upon exposure,
wherein the acid generator component (B) contains a compound represented by Formula (b1) and a compound represented by Formula (b2), 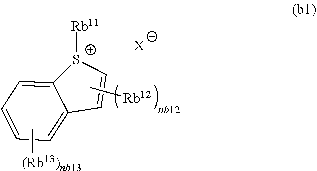
wherein, Rb¹¹ represents an aryl group having a substituent; Rb¹² and Rb¹³ each independently represents an alkyl group having 1 to 10 carbon atoms which may have a substituent, an acetyl group, an alkoxy group having 1 to 10 carbon atoms, a carboxy group, or a hydroxyl group; nb12 represents an integer of 0 to 2; nb13 represents an integer of 0 to 4; and X⁻ represents a counter anion, 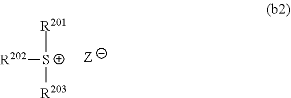
wherein R²⁰¹ to R²⁰³ each independently represents an aryl group which may have a substituent; and Z⁻ represents a counter anion.

2. The resist composition according to claim 1,
wherein the counter anion represented by X⁻ in Formula (b1) is an anion represented by any of Formulae (b-1) to (b-3) 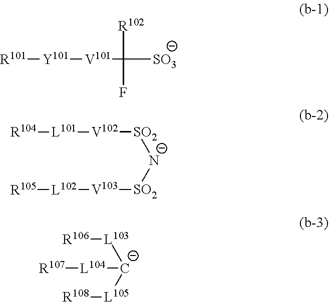
wherein R¹⁰¹ and R¹⁰⁴ to R¹⁰⁸ each independently represents a cyclic group which may have a substituent, a chain-like alkyl group which may have a substituent, or a chain-like alkenyl group which may have a substituent, provided that R¹⁰⁴ and R¹⁰⁵ may be bonded to each other to form a ring, and any two of R¹⁰⁶ to R¹⁰⁸ may be bonded to each other to form a ring; R¹⁰² represents a fluorine atom or a fluorinated alkyl group having 1 to 5 carbon atoms; Y¹⁰¹ represents a single bond or a divalent linking group having an oxygen atom; V¹⁰¹ to V¹⁰³ each independently represents a single bond, an alkylene group, or a fluorinated alkylene group; L¹⁰¹ and L¹⁰² each independently represents a single bond or an oxygen atom; and L¹⁰³ to L¹⁰⁵ each independently represents a single bond, —CO—, or —SO₂—.

3. The resist composition according to claim 1,
wherein the counter anion represented by Z⁻ in Formula (b2) is an anion represented by any of Formulae (b-1) to (b-3) 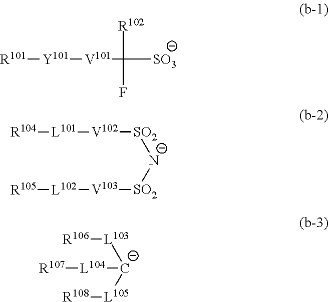
wherein R¹⁰¹ and R¹⁰⁴ to R¹⁰⁸ each independently represents a cyclic group which may have a substituent, a chain-like alkyl group which may have a substituent, or a chain-like alkenyl group which may have a substituent, provided that R¹⁰⁴ and R¹⁰⁵ may be bonded to each other to form a ring, and any two of R¹⁰⁶ to R¹⁰⁸ may be bonded to each other to form a ring; R¹⁰² represents a fluorine atom or a fluorinated alkyl group having 1 to 5 carbon atoms; Y¹⁰¹ represents a single bond or a divalent linking group having an oxygen atom; V¹⁰¹ to V¹⁰³ each independently represents a single bond, an alkylene group, or a fluorinated alkylene group; L¹⁰¹ and L¹⁰² each independently represents a single bond or an oxygen atom; and L¹⁰³ to L¹⁰⁵ each independently represents a single bond, —CO—, or —SO₂—.

4. A resist pattern forming method, comprising:
forming a resist film on a support using the resist composition according to any one of claim 1;
exposing the resist film; and
developing the exposed resist film to form a resist pattern.
